(19) United States
(12) Patent Application Publication
(10) Pub. No.: US 2025/0344614 A1
(43) Pub. Date: Nov. 6, 2025

(54) Modular Quantum Processor Configurations and Module Integration Plate with Inter-Module Connections for Same

(71) Applicant: Rigetti & Co., LLC, Berkeley, CA (US)

(72) Inventors: Andrew Joseph Bestwick, Berkeley, CA (US); Ganesh Ramachandran, Campbell, CA (US); Biswajit Sur, San Jose, CA (US); Valentin Kosenko, Mountain View, CA (US); Feyza Oruc, Fremont, CA (US); Chad Tyler Rigetti, Walnut Creek, CA (US)

(73) Assignee: Rigetti & Co., LLC, Berkeley, CA (US)

(21) Appl. No.: 18/798,045

(22) Filed: Aug. 8, 2024

Related U.S. Application Data
(63) Continuation of application No. PCT/US2023/016163, filed on Mar. 23, 2023.
(60) Provisional application No. 63/313,164, filed on Feb. 23, 2022.
(60) Provisional application No. 63/343,453, filed on May 18, 2022.

(51) Int. Cl. H10N 69/00; G06N 10/40; H01L 23/49; H01L 23/538

(52) U.S. Cl. CPC H10N 69/00; G06N 10/40; H01L 23/49; H01L 23/5386

(57) ABSTRACT

In a general aspect, modular quantum processor configurations and methods, including integrating superconducting circuit quantum processor chips with a module integration plate that includes inter-module connections to form modular quantum processors are presented. In some cases, a quantum processing unit includes quantum processor chips, a module integration plate, and one or more caps. Each quantum processor chip includes a plurality of qubit devices. The quantum processor chips are disposed between the module integration plate and the one or more caps. The module integration plate includes recesses that house respective subsets of the quantum processor chips; and inter-module coupler devices that provide communication between the subsets of quantum processor chips housed in distinct recesses. The one or more cap wafers each includes signal lines that provide communication between at least one of the quantum processor chips and a control system.

### CROSS-REFERENCE TO RELATED APPLICATIONS

This application claims priority to U.S. Provisional Patent Application No. 63/313,164, filed Feb. 23, 2022, entitled “Multi-chip Quantum Processor Configurations;” and to U.S. Provisional Patent Application No. 63/343,453, filed May 18, 2022, entitled “Module Integration Plate with Inter-Module Connections for Modular Quantum Processor Configurations.” The above-referenced priority documents are incorporated herein by reference in their entireties.

### TECHNICAL FIELD

The following description relates to modular quantum processor configurations and methods, including integrating superconducting circuit quantum processor chips with a module integration plate that includes inter-module connections to form modular quantum processors.

### BACKGROUND

Quantum computers can perform computational tasks by storing and processing information within quantum states of quantum systems. For example, qubits (i.e., quantum bits) can be stored in, and represented by, an effective two-level sub-manifold of a quantum coherent physical system. A variety of physical systems have been proposed for quantum computing applications. Examples include superconducting circuits, trapped ions, spin systems and others.

### BRIEF DESCRIPTION OF THE DRAWINGS

FIG. 1 is a block diagram of an example computing environment.

FIG. 2 is a schematic diagram of a cross-sectional view of an example quantum processor module.

FIG. 3A is a schematic diagram of an exploded view of an example quantum processor module.

FIG. 3B is a schematic diagram of a perspective view of an example quantum processor module.

FIGS. 4A-4B are schematic diagrams of a top view and a cross-sectional view of an example quantum processor module.

FIG. 5 is a schematic diagram of a top view of an example cap wafer.

FIG. 6A is a schematic diagram of a cross-sectional view of an example quantum processor module.

FIG. 6B is a schematic diagram of a cross-sectional view of an example quantum processor module.

FIG. 6C is a schematic diagram of an exploded view of an example quantum processor module.

FIG. 7A are schematic diagrams of a perspective view and a cross-sectional view of an example cap wafer.

FIG. 7B are schematic diagrams of a perspective view and a cross-sectional view of an example quantum processor chip.

FIG. 7C are schematic diagrams of a perspective view and cross-sectional views of an example quantum processor module.

FIG. 8 is a flow chart showing aspects of an example fabrication process.

FIG. 9A is a flow chart showing aspects of an example fabrication process of assembling a modular quantum processing unit with a single cap wafer for multiple quantum processor chips.

FIG. 9B is a schematic cross-sectional diagram showing aspects of the example modular quantum processing unit of FIG. 9A.

FIG. 10A is a flow chart showing aspects of an example fabrication process of assembling a modular quantum processing unit with one cap wafer for each of quantum processor chips.

FIG. 10B is a cross-sectional schematic diagram showing aspects of the example modular quantum processing unit of FIG. 10A.

FIG. 11 is a flow chart showing aspects of an example manufacturing process of inter-module coupler devices on a substrate.

FIG. 12 is a flow chart showing aspects of an example fabrication process of assembling a modular quantum processing unit.

FIG. 13 is a schematic diagram showing aspects of an example modular quantum processing unit.

FIG. 14 is a schematic diagram showing aspects of an example modular quantum processing unit.

FIG. 15 is a schematic diagram showing aspects of an example module integration plate.

FIG. 16A is a flow chart showing aspects of an example process of manufacturing a module integration plate.

FIG. 16B is a flow chart showing aspects of an example process of manufacturing a module integration plate.

FIG. 17 shows perspective view and cross-section view (A-A′) of an example module integration plate.

FIG. 18A shows exploded-view and assembled-view of an example modular quantum processing unit.

FIG. 18B is a schematic diagram showing a perspective view of the example assembly of module integration plate, interposer, and thermalization substrate shown in FIG. 18A.

FIGS. 19A-19B includes top-view schematic diagrams showing layouts of quantum processor modules in example modular quantum processing units.

### DETAILED DESCRIPTION

In a general aspect, a modular quantum processing unit (QPU) includes one or more cap wafers and a plurality of quantum processor chips that are connected to each other. The QPU may also include a module integration plate that includes inter-module coupling between the quantum processor chips.

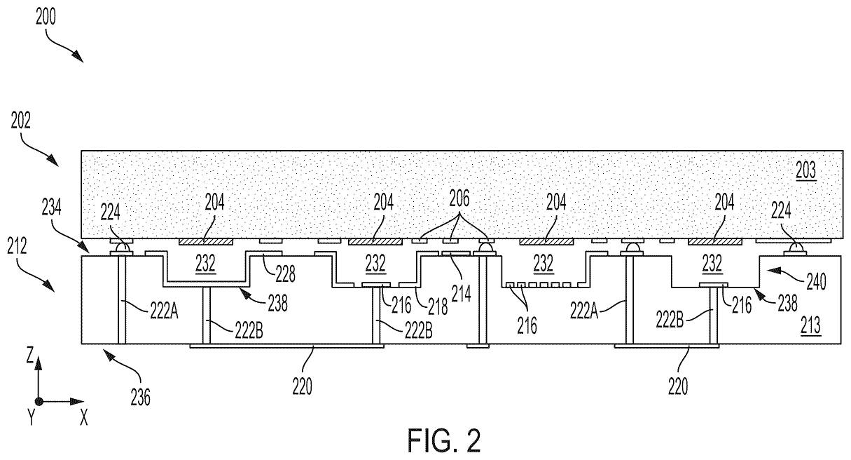

In some aspects of what is described here, a quantum processing unit includes a device wafer with quantum circuit devices based on, for example, superconducting devices, and other superconducting circuitry. The quantum processing unit further includes a cap wafer bonded with the device wafer. A cap wafer includes recesses, each of which is defined by a recessed surface and sidewalls. Recesses on the cap wafer form respective enclosures that house the respective quantum circuit devices on the device wafer. The cap wafer may include various superconducting circuitry (e.g., the circuitry 214, 216, 218, 220 of FIG. 2) on various surfaces (e.g., the first surface 234, the second surface 236, the recessed surface 238, and the sidewalls 240 of FIG. 2) of the cap wafer, for example, to provide various types of functionality, which can improve performance of a quantum processing unit or provide other advantages. Further, the cap wafer may include other features, such as, for example, electrically conductive vias (e.g., the conductive vias 222A, 222B of FIG. 2) that can be used to galvanically couple circuitry on various surfaces.

In some implementations, recesses in the cap wafer can provide technical advantages and improvements. In some instances, a participation ratio of electric fields around a quantum circuit device can be tuned to improve QPU performance attributes, such as coherence times, flux crosstalk, gate fidelity, or another performance parameter. For example, a participation ratio can be tuned by controlling a depth of a recess and thus the distance between a ground plane disposed on a recessed surface of the recess and a respective quantum circuit device enclosed by the recess.

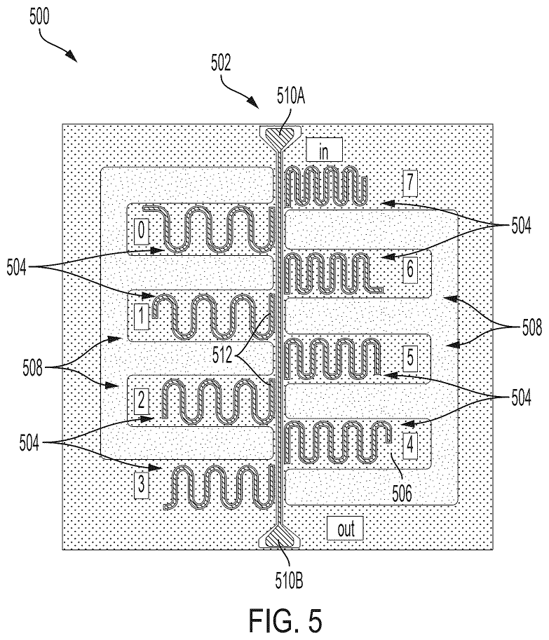

In some implementations, various circuitry on a cap wafer may include a variety of circuit elements to control or readout quantum circuit devices on a device wafer. For example, circuitry on a cap wafer may include flux bias lines that can be inductively coupled to quantum circuit devices on a device wafer to provide magnetic flux locally, for example, to tune their frequencies. Circuitry on a cap wafer may also include microwave lines which can be capacitively coupled to quantum circuit devices, for example, to control qubits. In some examples, circuitry on a cap wafer includes microwave resonator devices which can be capacitively coupled to quantum circuit devices; for example, to the readout resonator devices 500 shown in FIG. 5. In certain instances, other circuit elements, such as filters, isolators, circulators, or amplifiers, which would otherwise be deployed in an external module or package, can be integrated on the cap wafer.

In some instances, control signals can be supplied to quantum circuit devices on a device wafer (e.g., galvanically, capacitively, or inductively) through circuitry, electrically conductive vias, and/or bonding bumps on a cap wafer. Therefore, the methods and techniques presented here can free up space on a device wafer allowing for more dense quantum circuits and reduce the number of interconnections. In some instances, a cap wafer can provide opportunities to simplify the circuit design and improve the yield of a quantum integrated circuit (QuIC) on a device wafer.

In some instances, ground planes can be included on a cap wafer, which may allow better isolations of quantum circuit devices on a device wafer. Ground planes on a cap wafer can be used to guide, disperse, and remove supercurrents away from quantum circuit devices. Consequently, unpredictable non-localized interactions, flux crosstalk, and coherent error caused by the propagation of the supercurrents can be reduced.

In some implementations, the systems and techniques described here can provide improved protection for quantum circuit devices on a device wafer. For example, a conductive layer can be formed on a recessed surface and sidewalls of a recess on a cap wafer, which, when being arranged around a quantum circuit device of a device wafer, can effectively form a Faraday cage that reduces electrical noise. For another example, a superconducting layer can be formed on a recessed surface and sidewalls of a recess, which, when being arranged around a quantum circuit device, can be used as a magnetic shield to reduce the impact of stray magnetic fields on the quantum circuit device. In some instances, a cap wafer could provide protection to quantum circuit devices from other sources of interference and noise, including electromagnetic pulse damage, electrostatic discharge, ionizing radiation, and/or thermal radiation. For example, a cap wafer could also improve the performance of Radio Frequency Monolithic Microwave Integrated Circuit (RF MMIC) chips by reducing interference, either from the MMIC itself or from neighboring RF circuitry. For instance, a cap wafer can include a barrier layer for reflecting thermal radiation to reduce heat load on quantum circuit devices. In addition, a cap wafer may include thermal pathways to improve heatsinking. In some instances, an antenna or an array of antennas may be included on a cap wafer for the RF-MMIC chips on a device wafer, where dimensions of the antenna and the RF-MMIC chip become comparable.

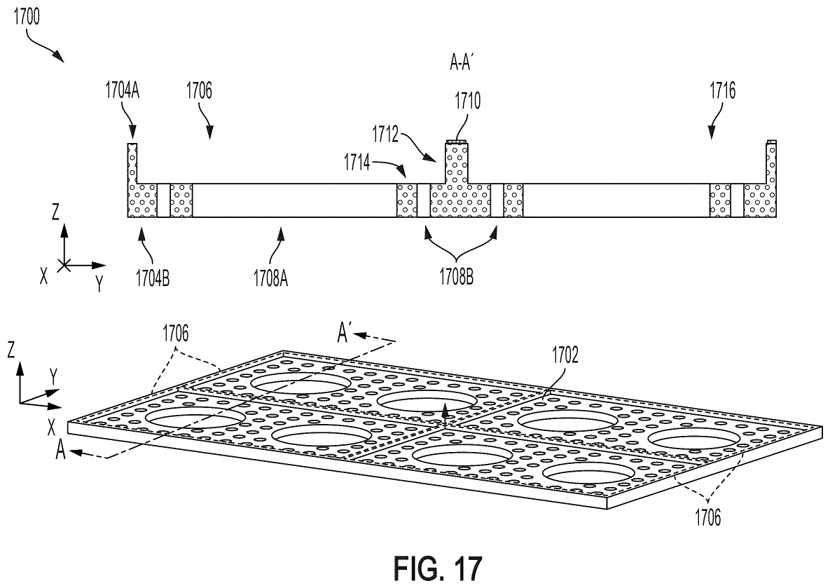

In some implementations, a modular quantum processing unit includes one or more quantum processor modules and one or more module integration plates that include inter-module coupler devices. A module integration plate may provide spatial alignment of the quantum processor modules in an array, and functional connectivity between, quantum processor modules; as such, a module integration plate may serve as an inter-module coupler structure and may also serve other functions. Each of the quantum processor modules includes a first plurality of quantum processor chips and a second plurality of cap wafers. Each of the one or more module integration plates includes recesses and inter-module coupler devices. Each of the recesses can be configured to house quantum processor chips; and each of the inter-module coupler devices can be configured to communicably couple quantum processor chips housed in distinct recesses. In some implementations, each of the module integration plates includes through-hole vias and cavities which allows integration with other components of the modular quantum processing unit, e.g., an interposer and a thermalization substrate. Each of the recesses can be configured to house one or more quantum processor chips. FIG. 17 shows an example of a module integration plate which includes four recesses, and each recess is configured to house two quantum processor chips attached to the same cap wafer.

In some implementations, the systems and techniques described here can provide advantages. For example, the module integration plate can be implemented as a monolithic solid unit which can simplify processing steps to interconnect multiple quantum processor chips. A module integration plate, an interposer and a thermalization substrate may improve the tolerance in mechanical variations (e.g., curvature, thickness, etc.) during the assembling process. An interposer with spring-loaded pin connections can also reduce or avoid formation of a chip-mode resonance and mitigate unwanted modes (e.g., coupled slotline mode, parallel-plate waveguide modes, or resonant patch mode). The thermalization substrate can effectively dissipate heat generated from the quantum processor chips to regulate the operation temperature of the quantum processor chips. In some cases, a combination of these and potentially other advantages and improvements may be obtained.

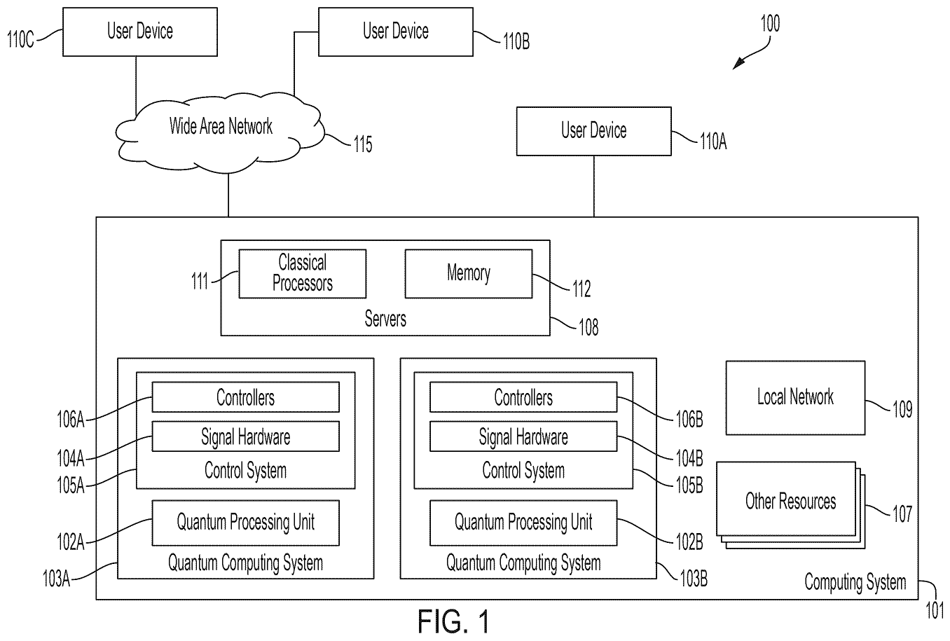

FIG. 1 is a block diagram of an example computing environment 100. The example computing environment 100 shown in FIG. 1 includes a computing system 101 and user devices 110A, 110B, 110C. A computing environment may include additional or different features, and the components of a computing environment may operate as described with respect to FIG. 1 or in another manner.

The example computing system 101 includes classical and quantum computing resources and exposes their functionality to the user devices 110A, 110B, 110C (referred to collectively as “user devices 110”). The computing system 101 shown in FIG. 1 includes one or more servers 108, quantum computing systems 103A, 103B, a local network 109 and other resources 107. The computing system 101 may also include one or more user devices (e.g., the user device 110A) as well as other features and components. A computing system may include additional or different features, and the components of a computing system may operate as described with respect to FIG. 1 or in another manner.

The example computing system 101 can provide services to the user devices 110, for example, as a cloud-based or remote-accessed computer system, as a distributed computing resource, as a supercomputer or another type of high-performance computing resource, or in another manner. The computing system 101 or the user devices 110 may also have access to one or more other quantum computing systems (e.g., quantum computing resources that are accessible through the wide area network 115, the local network 109, or otherwise).

The user devices 110 shown in FIG. 1 may include one or more classical processors, memory, user interfaces, communication interfaces, and other components. For instance, the user devices 110 may be implemented as laptop computers, desktop computers, smartphones, tablets, or other types of computer devices. In the example shown in FIG. 1, to access computing resources of the computing system 101, the user devices 110 send information (e.g., programs, instructions, commands, requests, input data, etc.) to the servers 108; and in response, the user devices 110 receive information (e.g., application data, output data, prompts, alerts, notifications, results, etc.) from the servers 108. The user devices 110 may access services of the computing system 101 in another manner, and the computing system 101 may expose computing resources in another manner.

In the example shown in FIG. 1, the local user device 110A operates in a local environment with the servers 108 and other elements of the computing system 101. For instance, the user device 110A may be co-located with (e.g., located within 0.5 to 1 km of) the servers 108 and possibly other elements of the computing system 101. As shown in FIG. 1, the user device 110A communicates with the servers 108 through a local data connection.

The local data connection in FIG. 1 is provided by the local network 109. For example, some or all of the servers 108, the user device 110A, the quantum computing systems 103A, 103B and the other resources 107 may communicate with each other through the local network 109. In some implementations, the local network 109 operates as a communication channel that provides one or more low-latency communication pathways from the server 108 to the quantum computer systems 103A, 103B (or to one or more of the elements of the quantum computer systems 103A, 103B). The local network 109 can be implemented, for instance, as a wired or wireless Local Area Network, an Ethernet connection, or another type of wired or wireless connection. The local network 109 may include one or more wired or wireless routers, wireless access points (WAPs), wireless mesh nodes, switches, high-speed cables, or a combination of these and other types of local network hardware elements. In some cases, the local network 109 includes a software-defined network that provides communication among virtual resources, for example, among an array of virtual machines operating on the server 108 and possibly elsewhere.

In the example shown in FIG. 1, the remote user devices 110B, 110C operate remotely from the servers 108 and other elements of the computing system 101. For instance, the user devices 110B, 110C may be located at a remote distance (e.g., more than 1 km, 10 km, 100 km, 1,000 km, 10,000 km, or farther) from the servers 108 and possibly other elements of the computing system 101. As shown in FIG. 1, each of the user devices 110B, 110C communicates with the servers 108 through a remote data connection.

The remote data connection in FIG. 1 is provided by a wide area network 115, which may include, for example, the Internet or another type of wide area communication network. In some cases, remote user devices use another type of remote data connection (e.g., satellite-based connections, a cellular network, a virtual private network, etc.) to access the servers 108. The wide area network 115 may include one or more internet servers, firewalls, service hubs, base stations, or a combination of these and other types of remote networking elements. Generally, the computing environment 100 can be accessible to any number of remote user devices.

The example servers 108 shown in FIG. 1 can manage interaction with the user devices 110 and utilization of the quantum and classical computing resources in the computing system 101. For example, based on information from the user devices 110, the servers 108 may delegate computational tasks to the quantum computing systems 103A, 103B and the other resources 107; the servers 108 can then send information to the user devices 110 based on output data from the computational tasks performed by the quantum computing systems 103A, 103B and the other resources 107.

As shown in FIG. 1, the servers 108 are classical computing resources that include classical processors 111 and memory 112. The servers 108 may also include one or more communication interfaces that allow the servers to communicate via the local network 109, the wide area network 115, and possibly other channels. In some implementations, the servers 108 may include a host server, an application server, a virtual server, or a combination of these and other types of servers. The servers 108 may include additional or different features and may operate as described with respect to FIG. 1 or in another manner.

The classical processors 111 can include various kinds of apparatus, devices, and machines for processing data, including, by way of example, a microprocessor, a central processing unit (CPU), a graphics processing unit (GPU), an FPGA (field programmable gate array), an ASIC (application specific integrated circuit), or combinations of these. The memory 112 can include, for example, a random-access memory (RAM), a storage device (e.g., a writable read-only memory (ROM) or others), a hard disk, or another type of storage medium. The memory 112 can include various forms of volatile or non-volatile memory, media and memory devices, etc.

Each of the example quantum computing systems 103A, 103B operates as a quantum computing resource in the computing system 101. The other resources 107 may include additional quantum computing resources (e.g., quantum computing systems, quantum virtual machines (QVMs) or quantum simulators) as well as classical (non-quantum) computing resources such as, for example, digital microprocessors, specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), etc., or combinations of these and other types of computing modules.

In some implementations, the servers 108 generate programs, identify appropriate computing resources (e.g., a QPU or QVM) in the computing system 101 to execute the programs, and send the programs to the identified resources for execution. For example, the servers 108 may send programs to the quantum computing system 103A, the quantum computing system 103B, or any of the other resources 107. The programs may include classical programs, quantum programs, hybrid classical/quantum programs, and may include any type of function, code, data, instruction set, etc.

In some instances, programs can be formatted as source code that can be rendered in human-readable form (e.g., as text) and can be compiled, for example, by a compiler running on the servers 108, on the quantum computing systems 103, or elsewhere. In some instances, programs can be formatted as compiled code, such as, for example, binary code (e.g., machine-level instructions) that can be executed directly by a computing resource. Each program may include instructions corresponding to computational tasks that, when performed by an appropriate computing resource, generate output data based on input data. For example, a program can include instructions formatted for a quantum computer system, a quantum virtual machine, a digital microprocessor, co-processor or other classical data processing apparatus, or another type of computing resource.

In some cases, a program may be expressed in a hardware-independent format. For example, quantum machine instructions may be provided in a quantum instruction language such as Quil, described in the publication “A Practical Quantum Instruction Set Architecture,” arXiv:1608.03355v2, dated Feb. 17, 2017, or another quantum instruction language. For instance, the quantum machine instructions may be written in a format that can be executed by a broad range of quantum processing units or quantum virtual machines. In some cases, a program may be expressed in high-level terms of quantum logic gates or quantum algorithms, in lower-level terms of fundamental qubit rotations and controlled rotations, or in another form. In some cases, a program may be expressed in terms of control signals (e.g., pulse sequences, delays, etc.) and parameters for the control signals (e.g., frequencies, phases, durations, channels, etc.). In some cases, a program may be expressed in another form or format.

In some implementations, the servers 108 include one or more compilers that convert programs between formats. For example, the servers 108 may include a compiler that converts hardware-independent instructions to binary programs for execution by the quantum computing systems 103A, 103B. In some cases, a compiler can compile a program to a format that targets a specific quantum resource in the computer system 101. For example, a compiler may generate a different binary program (e.g., from the same source code) depending on whether the program is to be executed by the quantum computing system 103A or the quantum computing system 103B.

In some cases, a compiler generates a partial binary program that can be updated, for example, based on specific parameters. For instance, if a quantum program is to be executed iteratively on a quantum computing system with varying parameters on each iteration, the compiler may generate the binary program in a format that can be updated with specific parameter values at runtime (e.g., based on feedback from a prior iteration, or otherwise). In some cases, a compiler generates a full binary program that does not need to be updated or otherwise modified for execution.

In some implementations, the servers 108 generate a schedule for executing programs, allocate computing resources in the computing system 101 according to the schedule, and delegate the programs to the allocated computing resources. The servers 108 can receive, from each computing resource, output data from the execution of each program. Based on the output data, the servers 108 may generate additional programs that are then added to the schedule, output data that is provided back to a user device 110 or perform another type of action.

In some implementations, all or part of the computing environment operates as a cloud-based quantum computing (QC) environment, and the servers 108 operate as a host system for the cloud-based QC environment. The cloud-based QC environment may include software elements that operate on both the user devices 110 and the computer system 101 and interact with each other over the wide area network 115. For example, the cloud-based QC environment may provide a remote user interface, for example, through a browser or another type of application on the user devices 110. The remote user interface may include, for example, a graphical user interface or another type of user interface that obtains input provided by a user of the cloud-based QC environment. In some cases, the remote user interface includes, or has access to, one or more application programming interfaces (APIs), command line interfaces, graphical user interfaces, or other elements that expose the services of the computer system 101 to the user devices 110.

In some cases, the cloud-based QC environment may be deployed in a “serverless” computing architecture. For instance, the cloud-based QC environment may provide on-demand access to a shared pool of configurable computing resources (e.g., networks, servers, storage, applications, services, quantum computing resources, classical computing resources, etc.) that can be provisioned for requests from user devices 110. Moreover, the cloud-based computing systems 104 may include or utilize other types of computing resources, such as, for example, edge computing, fog computing, etc.

In an example implementation of a cloud-based QC environment, the servers 108 may operate as a cloud provider that dynamically manages the allocation and provisioning of physical computing resources (e.g., GPUs, CPUs, QPUs, etc.). Accordingly, the servers 108 may provide services by defining virtualized resources for each user account. For instance, the virtualized resources may be formatted as virtual machine images, virtual machines, containers, or virtualized resources that can be provisioned for a user account and configured by a user. In some cases, the cloud-based QC environment is implemented using a resource such as, for example, OPENSTACK®. OPENSTACK® is an example of a software platform for cloud-based computing, which can be used to provide virtual servers and other virtual computing resources for users.

In some cases, the server 108 stores quantum machine images (QMI) for each user account. A quantum machine image may operate as a virtual computing resource for users of the cloud-based QC environment. For example, a QMI can provide a virtualized development and execution environment to develop and run programs (e.g., quantum programs or hybrid classical/quantum programs). When a QMI operates on the server 108, the QMI may engage either of the quantum processing units 102A, 102B, and interact with a remote user device (110B or 110C) to provide a user programming environment. The QMI may operate in close physical proximity to and have a low-latency communication link with the quantum computing systems 103A, 103B. In some implementations, remote user devices connect with QMIs operating on the servers 108 through secure shell (SSH) or other protocols over the wide area network 115.

In some implementations, all or part of the computing system 101 operates as a hybrid computing environment. For example, quantum programs can be formatted as hybrid classical/quantum programs that include instructions for execution by one or more quantum computing resources and instructions for execution by one or more classical resources. The servers 108 can allocate quantum and classical computing resources in the hybrid computing environment, and delegate programs to the allocated computing resources for execution. The quantum computing resources in the hybrid environment may include, for example, one or more quantum processing units (QPUs), one or more quantum virtual machines (QVMs), one or more quantum simulators, or possibly other types of quantum resources. The classical computing resources in the hybrid environment may include, for example, one or more digital microprocessors, one or more specialized co-processor units (e.g., graphics processing units (GPUs), cryptographic co-processors, etc.), special purpose logic circuitry (e.g., field programmable gate arrays (FPGAs), application-specific integrated circuits (ASICs), etc.), systems-on-chips (SoCs), or other types of computing modules.

In some cases, the servers 108 can select the type of computing resource (e.g., quantum or classical) to execute an individual program, or part of a program, in the computing system 101. For example, the servers 108 may select a particular quantum processing unit (QPU) or other computing resource based on availability of the resource, speed of the resource, information or state capacity of the resource, a performance metric (e.g., process fidelity) of the resource, or based on a combination of these and other factors. In some cases, the servers 108 can perform load balancing, resource testing and calibration, and other types of operations to improve or optimize computing performance.

Each of the example quantum computing systems 103A, 103B shown in FIG. 1 can perform quantum computational tasks by executing quantum machine instructions (e.g., a binary program compiled for the quantum computing system). In some implementations, a quantum computing system can perform quantum computation by storing and manipulating information within quantum states of a composite quantum system. For example, qubits (i.e., quantum bits) can be stored in, and represented by, an effective two-level sub-manifold of a quantum coherent physical system. In some instances, quantum logic can be executed in a manner that allows large-scale entanglement within the quantum system. Control signals can manipulate the quantum states of individual qubits and the joint states of multiple qubits. In some instances, information can be read out from the composite quantum system by measuring the quantum states of the qubits. In some implementations, the quantum states of the qubits are read out by measuring the transmitted or reflected signal from auxiliary quantum devices that are coupled to individual qubits.

In some implementations, a quantum computing system can operate using gate-based models for quantum computing. For example, the qubits can be initialized in an initial state, and a quantum logic circuit comprised of a series of quantum logic gates can be applied to transform the qubits and extract measurements representing the output of the quantum computation. Individual qubits may be controlled by single-qubit quantum logic gates, and pairs of qubits may be controlled by two-qubit quantum logic gates (e.g., entangling gates that are capable of generating entanglement between the pair of qubits). In some implementations, a quantum computing system can operate using adiabatic or annealing models for quantum computing. For instance, the qubits can be initialized in an initial state, and the controlling Hamiltonian can be transformed adiabatically by adjusting control parameters to another state that can be measured to obtain an output of the quantum computation.

In some models, fault-tolerance can be achieved by applying a set of high-fidelity control and measurement operations to the qubits. For example, quantum error correcting schemes can be deployed to achieve fault-tolerant quantum computation. Other computational regimes may be used; for example, quantum computing systems may operate in non-fault-tolerant regimes. In some implementations, a quantum computing system is constructed and operated according to a scalable quantum computing architecture. For example, in some cases, the architecture can be scaled to a large number of qubits to achieve large-scale general purpose coherent quantum computing. Other architectures may be used; for example, quantum computing systems may operate in small-scale or non-scalable architectures.

The example quantum computing system 103A shown in FIG. 1 includes a quantum processing unit 102A and a control system 105A, which controls the operation of the quantum processing unit 102A. Similarly, the example quantum computing system 103B includes a quantum processing unit 102B and a control system 105B, which controls the operation of a quantum processing unit 102B. A quantum computing system may include additional or different features, and the components of a quantum computing system may operate as described with respect to FIG. 1 or in another manner.

In some instances, all or part of the quantum processing unit 102A functions as a quantum processor, a quantum memory, or another type of subsystem. In some examples, the quantum processing unit 102A includes a quantum circuit system. The quantum circuit system may include qubit devices, readout devices, and possibly other devices that are used to store and process quantum information. In some cases, the quantum processing unit 102A includes a superconducting circuit, and the qubit devices are implemented as circuit devices that include Josephson junctions, for example, in superconducting quantum interference device (SQUID) loops or other arrangements, and are controlled by radio-frequency signals, microwave signals, and bias signals delivered to the quantum processing unit 102A. In some cases, the quantum processing unit 102A includes an ion trap system, and the qubit devices are implemented as trapped ions controlled by optical signals delivered to the quantum processing unit 102A. In some cases, the quantum processing unit 102A includes a spin system, and the qubit devices are implemented as nuclear, or electron spins controlled by microwave or radio-frequency signals delivered to the quantum processing unit 102A. The quantum processing unit 102A may be implemented based on another physical modality of quantum computing.

The quantum processing unit 102A may include, or may be deployed within, a controlled environment. The controlled environment can be provided, for example, by shielding equipment, cryogenic equipment, and other types of environmental control systems. In some examples, the components in the quantum processing unit 102A operate in a cryogenic temperature regime and are subject to very low electromagnetic and thermal noise. For example, magnetic shielding can be used to shield the system components from stray magnetic fields, optical shielding can be used to shield the system components from optical noise, thermal shielding and cryogenic equipment can be used to maintain the system components at controlled temperature, etc.

In some implementations, the example quantum processing unit 102A can process quantum information by applying control signals to the qubits in the quantum processing unit 102A. The control signals can be configured to encode information in the qubits, to process the information by performing quantum logic gates or other types of operations, or to extract information from the qubits. In some examples, the operations can be expressed as single-qubit quantum logic gates, two-qubit quantum logic gates, or other types of quantum logic gates that operate on one or more qubits. A quantum logic circuit, which includes a sequence of quantum logic operations, can be applied to the qubits to perform a quantum algorithm. The quantum algorithm may correspond to a computational task, a hardware test, a quantum error correction procedure, a quantum state distillation procedure, or a combination of these and other types of operations.

The quantum processing unit 102A may include a device wafer and a cap wafer that are bonded together, for example, using bonding bumps or in another manner. In some instances, the device wafer contains a superconducting circuit with one or more quantum circuit devices. In some instances, the cap wafer contains one or more recesses, each defined by a recessed surface and sidewalls. The cap wafer may also contain various superconducting circuitry disposed at various locations, for example, on the recessed surface of the recess, the sidewalls, the front and back surfaces. The various superconducting circuitry of the cap wafer can provide various functionality. For example, a cap wafer may include circuitry for inductively, capacitively, or galvanically coupling two or more quantum circuit devices on one or more device wafers. Circuitry may include a variety of circuit elements to control or readout quantum circuit devices (e.g., qubit devices). For instance, circuitry on a cap wafer may include coupling lines, microwave lines, microwave feedlines, flux bias lines, combined flux bias and microwave lines, tunable-frequency coupler devices, resonator devices, filters, isolators, circulators, amplifiers, or other circuit elements. In some instances, circuitry at different positions of a cap wafer may be connected through conductive pathways on one or more sidewalls of recesses or through conductive vias through the substrate of the cap wafer. In some implementations, the device wafer and the cap wafer may be implemented as any one of the example device wafers 202, 302A, 302B, 302C, 322A, 322B, 322C, 322D, 402, 602, 632, 672, or 730 and example cap wafers 212, 304, 324, 404, 500, 604, 634, 674, or 718 as shown in FIGS. 2, 3A-3B, 4A-4B, 5, 6A-6C, or 7A-7C. In some instances, a cap wafer may be communicably coupled to the control system 105A, e.g., to receive control signals or transmit readout signals.

In some implementations, the example quantum processing unit 102 is a modular quantum processing unit that includes multiple quantum processor chips. For example, the quantum processing unit 102 may include a two-dimensional or three-dimensional array of quantum processor chips, and each quantum processor chip may include an array of quantum circuit devices. In some cases, the quantum processor chips are supported on a common substrate, and they are interconnected through circuitry (e.g., superconducting circuitry) on the common substrate.

In some instances, each of the quantum processor chips can include a superconducting quantum integrated circuit (QuIC) that includes one or more quantum circuit devices and superconductive lines that connect the one or more quantum circuit devices. For instance, each quantum processor chip may include qubit devices, readout resonator devices, tunable-frequency coupler devices, capacitive coupler devices, or other quantum circuit devices. Each quantum processor chip may include flux bias control lines, microwave drive lines, readout signal lines, or other types of control lines for providing control signals to respective quantum circuit devices. In some implementations, quantum processor chips can be coupled to each other by inter-module coupler devices in one or more cap wafers. For example, a first qubit device on a first quantum processor chip may be capacitively coupled to a tunable-frequency coupler device, which is capacitively coupled to a second qubit device on a second quantum processor chip. In some implementations, the tunable-frequency coupler device resides on the first quantum processor chip. In this case, the tunable-frequency coupler device is coupled to the second qubit device through a microwave transmission line on a cap wafer. In some implementations, at least a portion of a tunable-frequency coupler device resides on a cap wafer. In certain implementations, a tunable-frequency coupler device includes a lossless resonator structure. For example, a lossless resonator structure of a tunable-frequency coupler device may include a superconducting loop and a shunt capacitor. In some cases, a portion of the shunt capacitor (e.g., one capacitor electrode) in the tunable-frequency coupler device may reside on the cap wafer.

In some implementations, a cap wafer and a quantum processor chip in a modular quantum processing unit 102A are bonded together, for example, by bonding bumps or another type of bond. In some instances, the cap wafer contains one or more recesses, each defined by a recessed surface and sidewalls. When a cap wafer and a quantum processor chip are bonded together, a recess on the cap wafer can house a qubit device on the quantum processor chip. The cap wafer may also contain various superconducting circuitry. Circuitry may include a variety of superconducting circuit elements to control or readout quantum circuit devices (e.g., qubit devices). For instance, circuitry on a cap wafer may include coupling lines, microwave drive lines, microwave feedlines, flux bias lines, tunable-frequency coupler devices, or other circuit elements. In some instances, a cap wafer may be communicably coupled to the control system 105, e.g., to receive control signals or transmit readout signals.

The example control system 105A includes controllers 106A and signal hardware 104A. Similarly, control system 105B includes controllers 106B and signal hardware 104B. All or part of the control systems 105A, 105B can operate in a room-temperature environment or another type of environment, which may be located near the respective quantum processing units 102A, 102B. In some cases, the control systems 105A, 105B include classical computers, signaling equipment (microwave, radio, optical, bias, etc.), electronic systems, vacuum control systems, refrigerant control systems, or other types of control systems that support operation of the quantum processing units 102A, 102B.

The control systems 105A, 105B may be implemented as distinct systems that operate independent of each other. In some cases, the control systems 105A, 105B may include one or more shared elements; for example, the control systems 105A, 105B may operate as a single control system that operates both quantum processing units 102A, 102B. Moreover, a single quantum computer system may include multiple quantum processing units, which may operate in the same controlled (e.g., cryogenic) environment or in separate environments.

The example signal hardware 104A includes components that communicate with the quantum processing unit 102A. The signal hardware 104A may include, for example, waveform generators, amplifiers, digitizers, high-frequency sources, DC sources, AC sources, etc. The signal hardware may include additional or different features and components. In the example shown, components of the signal hardware 104A are adapted to interact with the quantum processing unit 102A. For example, the signal hardware 104A can be configured to operate in a particular frequency range, configured to generate and process signals in a particular format, or the hardware may be adapted in another manner.

In some instances, one or more components of the signal hardware 104A generate control signals, for example, based on control information from the controllers 106A. The control signals can be delivered to the quantum processing unit 102A during operation of the quantum computing system 103A. For instance, the signal hardware 104A may generate signals to implement quantum logic operations, readout operations, or other types of operations. As an example, the signal hardware 104A may include arbitrary waveform generators (AWGs) that generate electromagnetic waveforms (e.g., microwave or radiofrequency) or laser systems that generate optical waveforms. The waveforms or other types of signals generated by the signal hardware 104A can be delivered to devices in the quantum processing unit 102A to operate qubit devices, readout devices, bias devices, coupler devices, or other types of components in the quantum processing unit 102A.

In some instances, the signal hardware 104A receives and processes signals from the quantum processing unit 102A. The received signals can be generated by the execution of a quantum program on the quantum computing system 103A. For instance, the signal hardware 104A may receive signals from the devices in the quantum processing unit 102A in response to readout or other operations performed by the quantum processing unit 102A. Signals received from the quantum processing unit 102A can be mixed, digitized, filtered, or otherwise processed by the signal hardware 104A to extract information, and the information extracted can be provided to the controllers 106A or handled in another manner. In some examples, the signal hardware 104A may include a digitizer that digitizes electromagnetic waveforms (e.g., microwave or radiofrequency) or optical signals, and a digitized waveform can be delivered to the controllers 106A or to other signal hardware components. In some instances, the controllers 106A process the information from the signal hardware 104A and provide feedback to the signal hardware 104A; based on the feedback, the signal hardware 104A can in turn generate new control signals that are delivered to the quantum processing unit 102A.

In some implementations, the signal hardware 104A includes signal delivery hardware that interfaces with the quantum processing unit 102A. For example, the signal hardware 104A may include filters, attenuators, directional couplers, multiplexers, diplexers, bias components, signal channels, isolators, amplifiers, power dividers and other types of components. In some instances, the signal delivery hardware performs preprocessing, signal conditioning, or other operations to the control signals to be delivered to the quantum processing unit 102A. In some instances, signal delivery hardware performs preprocessing, signal conditioning or other operations on readout signals received from the quantum processing unit 102A.

The example controllers 106A communicate with the signal hardware 104A to control operation of the quantum computing system 103A. The controllers 106A may include classical computing hardware that directly interfaces with components of the signal hardware 104A. The example controllers 106A may include classical processors, memory, clocks, digital circuitry, analog circuitry, and other types of systems or subsystems. The classical processors may include one or more single-or multi-core microprocessors, digital electronic controllers, special purpose logic circuitry, e.g., an FPGA (field programmable gate array) or an ASIC (application specific integrated circuit), or other types of data processing apparatus. The memory may include any type of volatile or non-volatile memory, or another type of computer storage medium. The controllers 106A may also include one or more communication interfaces that allow the controllers 106A to communicate via the local network 109 and possibly other channels. The controllers 106A may include additional or different features and components.

In some implementations, the controllers 106A include memory or other components that store quantum state information, for example, based on qubit readout operations performed by the quantum computing system 103A. For instance, the states of one or more qubits in the quantum processing unit 102A can be measured by qubit readout operations, and the measured state information can be stored in a cache or other type of memory system in one or more of the controllers 106A. In some cases, the measured state information is subsequently used in the execution of a quantum program, a quantum error correction procedure, a quantum processing unit (QPU) calibration or testing procedure, or another type of quantum process.

In some implementations, the controllers 106A include memory or other components that store a quantum program containing quantum machine instructions for execution by the quantum computing system 103A. In some instances, the controllers 106A can interpret the quantum machine instructions and perform hardware-specific control operations according to the quantum machine instructions. For example, the controllers 106A may cause the signal hardware 104A to generate control signals that are delivered to the quantum processing unit 102A to execute the quantum machine instructions.

In some instances, the controllers 106A extract qubit state information from qubit readout signals, for example, to identify the quantum states of qubits in the quantum processing unit 102A or for other purposes. For example, the controllers may receive the qubit readout signals (e.g., in the form of analog waveforms) from the signal hardware 104A, digitize the qubit readout signals, and extract qubit state information from the digitized signals. In some cases, the controllers 106A compute measurement statistics based on qubit state information from multiple shots of a quantum program. For example, each shot may produce a bitstring representing qubit state measurements for a single execution of the quantum program, and a collection of bitstrings from multiple shots may be analyzed to compute quantum state probabilities.

In some implementations, the controllers 106A include one or more clocks that control the timing of operations. For example, operations performed by the controllers 106A may be scheduled for execution over a series of clock cycles, and clock signals from one or more clocks can be used to control the relative timing of each operation or groups of operations. In some implementations, the controllers 106A may include classical computer resources that perform some or all of the operations of the servers 108 described above. For example, the controllers 106A may operate a compiler to generate binary programs (e.g., full or partial binary programs) from source code; the controllers 106A may include an optimizer that performs classical computational tasks of a hybrid classical/quantum program; the controllers 106A may update binary programs (e.g., at runtime) to include new parameters based on an output of the optimizer, etc.

The other quantum computer system 103B and its components (e.g., the quantum processing unit 102B, the signal hardware 104B and controllers 106B) can be implemented as described above with respect to the quantum computer system 103A; in some cases, the quantum computer system 103B and its components may be implemented or may operate in another manner.

In some implementations, the quantum computer systems 103A, 103B are disparate systems that provide distinct modalities of quantum computation. For example, the computer system 101 may include both an adiabatic quantum computer system and a gate-based quantum computer system. As another example, the computer system 101 may include a superconducting circuit-based quantum computer system and an ion trap-based quantum computer system. In such cases, the computer system 101 may utilize each quantum computing system according to the type of quantum program that is being executed, according to availability or capacity, or based on other considerations.

FIG. 2 is a schematic diagram of a cross-sectional view of an example quantum processing unit 200. The example quantum processing unit 200 includes a device wafer 202 and a cap wafer 212, which are bonded together by bonding bumps 224. The device wafer 202 contains quantum circuit devices 204 as part of a superconducting circuit 206. The quantum circuit devices 204 can be, for example, qubit devices (e.g., transmon devices, fluxonium devices, or other types of superconducting qubit devices), coupler devices, readout devices or other types of devices that are used for quantum information processing in the quantum processing unit 200. The quantum circuit devices 204 may include one or more Josephson junctions, capacitors, inductors, and other types of circuit elements. The cap wafer 204 includes recesses 232 and various superconducting circuitry (e.g., 214, 216, 218, 220, and 222) disposed at various positions of the cap wafer 204 providing various functionalities. In some implementations, the use of the cap wafer 212 can improve coherence times of quantum circuit devices 204. In some implementations, the example quantum processing unit 200 may include additional and different features or components and components of the example quantum processing unit 200 may be implemented in another manner.

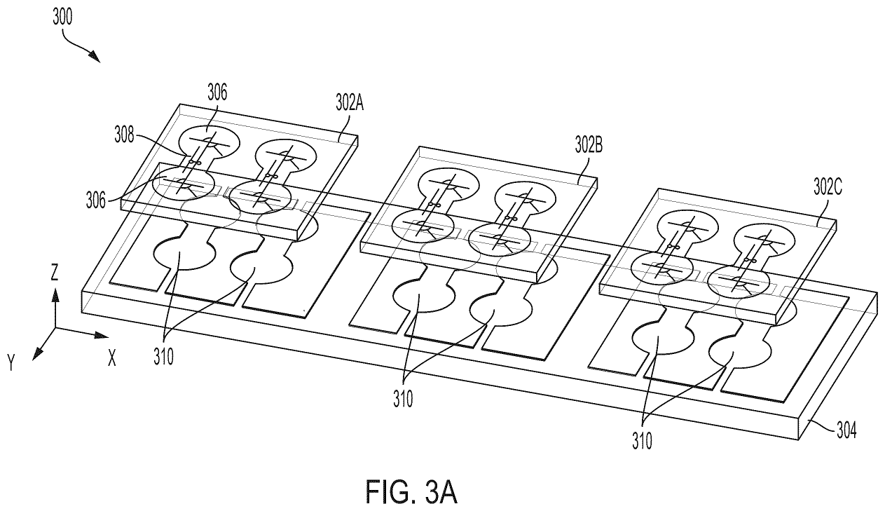

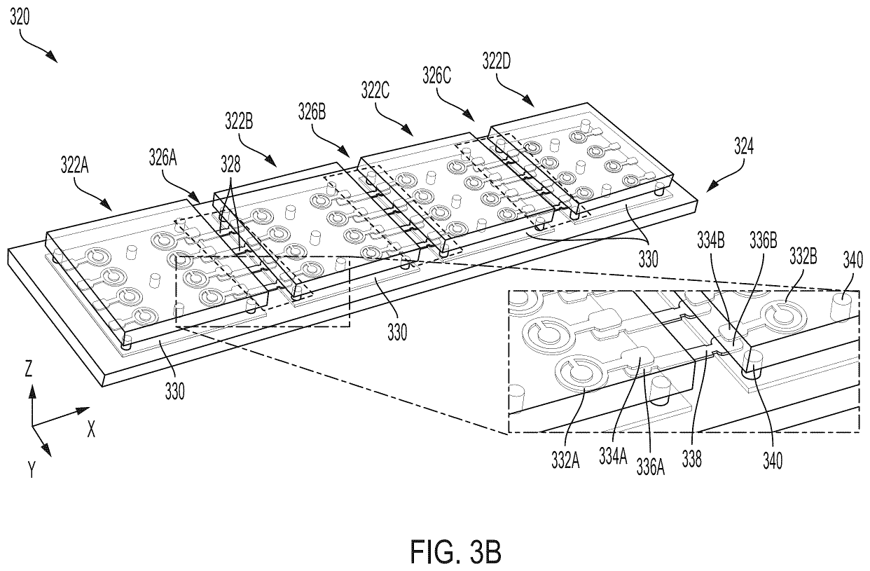

As shown in the example quantum processing unit 200, the device wafer 202 includes a first substrate 203. The first substrate 203, supporting the superconducting circuit 206 and the quantum circuit devices 204, is referred to as the device wafer 202. Similarly, the cap wafer 212 includes a second substrate 213. The second substrate 213 defining the recesses 232 and supporting the various superconducting circuitry (e.g., circuitry portions 214, 216, 218, 220, and 222) is referred to as the cap wafer 212. In some implementations, the quantum circuit devices 204 may include a two-dimensional array of qubit devices (e.g., on the surface along XY plane) and the recesses 232 of the cap wafer 212 may be arranged so as to form encapsulation for respective quantum circuit devices 204 when the cap wafer 212 and the device wafer 202 are bonded together. In some implementations, the example quantum processing unit 200 may include more than one device wafer 202 bonded to the same cap wafer 212 on the same side or on the opposite side. The cap wafer 212 can be used to inductively, capacitively, or galvanically couple multiple quantum circuit devices 204 fabricated on multiple device wafers 202, or multiple dies (e.g., the device dies 302A, 302B, and 302C as shown in FIG. 3A).

In some implementations, the first and second substrates 203, 213 may include a dielectric substrate (e.g., silicon, sapphire, etc.). In certain examples, the first and second substrates 203, 213 may include an elemental semiconductor material such as, for example, silicon (Si), germanium (Ge), selenium (Se), tellurium (Te), or another elemental semiconductor. In some instances, the first and second substrates 203, 213 may also include a compound semiconductor such as silicon germanium (SiGe), silicon carbide (SiC), silicon germanium carbide (SiGeC), aluminum oxide (sapphire), gallium arsenide (GaAs), indium arsenide (InAs), indium phosphide (InP), gallium arsenic phosphide (GaAsP), or gallium indium phosphide (GaInP). In some instances, the first and second substrates 203, 213 may also include a superlattice with elemental or compound semiconductor layers. In some instances, the first and second substrates 203, 213 include an epitaxial layer. In some examples, the first and second substrates 203, 213 may have an epitaxial layer overlying a bulk semiconductor or may include a semiconductor-on-insulator (SOI) structure.

The quantum circuit devices 204 and the superconducting circuit 206 on the device wafer 202 and the various superconducting circuitry (e.g., the circuitry portions 214, 216, 218, 220, and 222) on the cap wafer 212 include superconducting materials. In some implementations, the superconducting materials may be superconducting metals, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example quantum processing unit 200, or another superconducting metal. In some implementations, the superconducting materials may include superconducting metal alloys, such as molybdenum-rhenium (Mo/Re), niobium-tin (Nb/Sn), or another superconducting metal alloy. In some implementations, the superconducting materials may include superconducting compound materials, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting materials may include multilayer superconductor-insulator heterostructures.

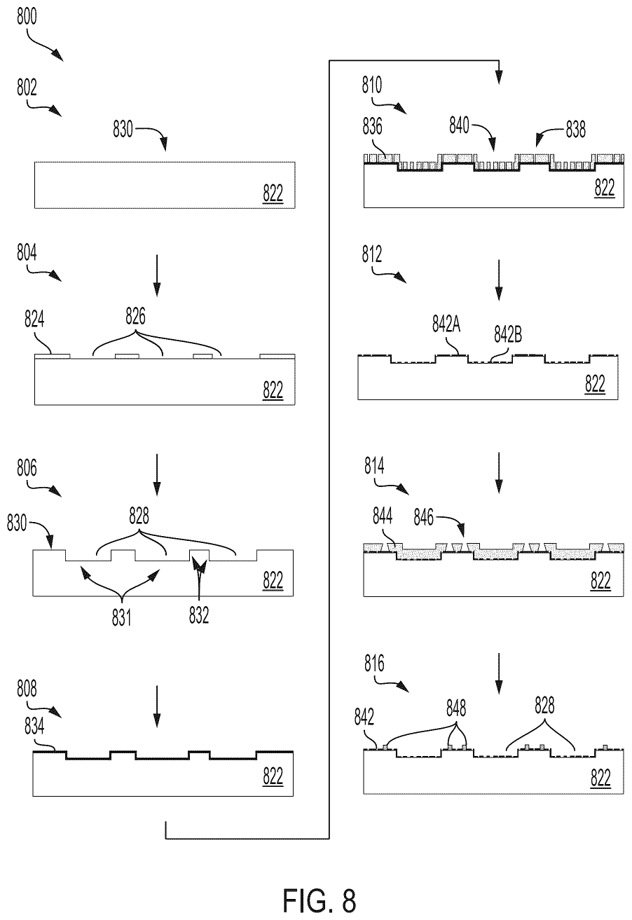

In some implementations, the quantum circuit devices 204 and the superconducting circuit 206 can be formed on a top surface of the first substrate and patterned using a microfabrication process or in another manner. For example, the superconducting circuit 206 and the quantum circuit devices 204 may be formed by performing at least some of the following fabrication steps: using chemical vapor deposition (CVD), physical vapor deposition (PVD), atomic layer deposition (ALD), and/or other suitable techniques to deposit respective superconducting layers on the first substrate; and performing one or more patterning processes (e.g., a lithography process, a dry/wet etching process, a soft/hard baking process, a cleaning process, etc.) to form openings in the respective superconducting layers. For example, a cap wafer may be formed with respect to the example process 800 shown in FIG. 8.

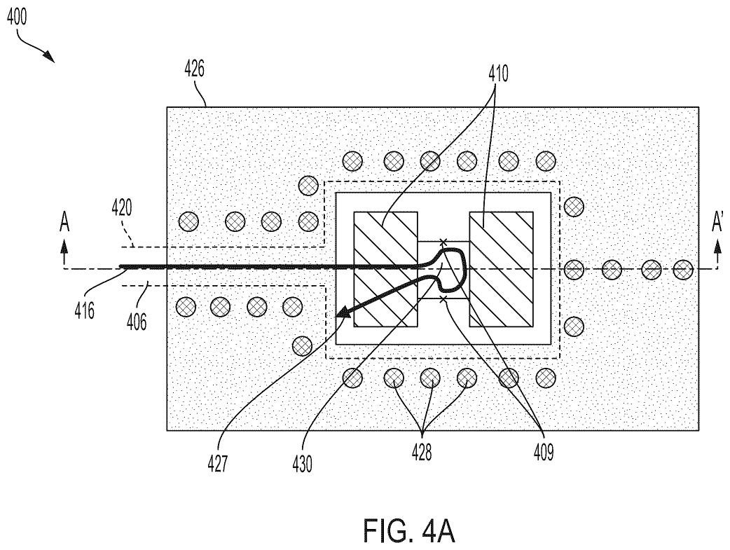

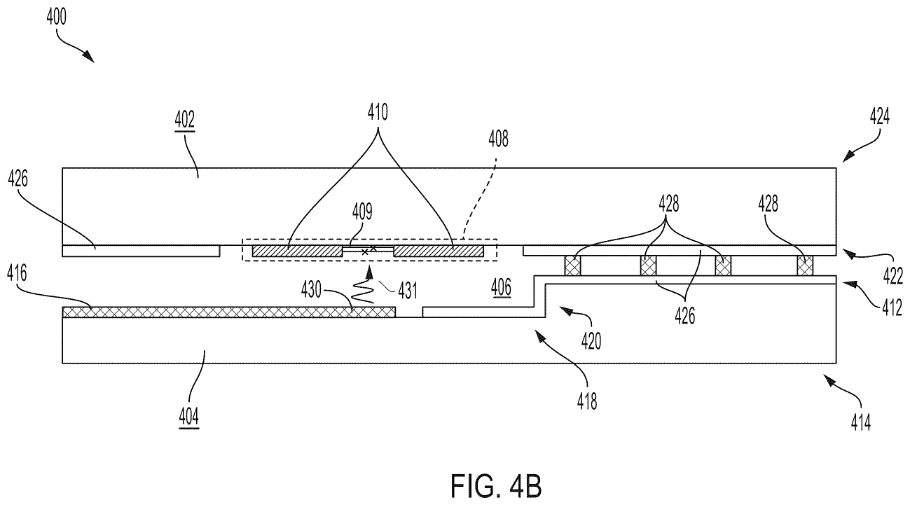

As shown in FIG. 2, the cap wafer 212 includes a first surface 234 and a second, opposite surface 236. Each of the recesses 232 is defined by a recessed surface 238 and sidewalls 240. The recessed surface 238 is located at a depth in the cap wafer 212 relative to the first surface 234. In some implementations, each of the recesses 232 may be a cavity, a shallow trench, a deep trench, or in another form. The dimension and shape of a recess 232 may be determined according to the dimension and shape of the quantum circuit device 204 or the superconducting circuit 206 associated with or enclosed by the recess. For example, a recess 232 in a form of a cavity can be used to form an enclosure to a quantum circuit device 204; and a recess 232 in a form of a shallow trench may be used to form an enclosure to a control line (e.g., the control line 416 as shown in FIGS. 4A-4B). As shown in FIG. 2, each of the recesses 232 has vertical sidewalls 240 along the Z-direction perpendicular to the first and second surfaces 234, 236. In certain implementations, the recesses 232 may include angled or sloped sidewalls 240 between the first surface 234 and the recessed surface 238.

As shown in FIG. 2, the recesses 232 are defined on the first surface 234 of the cap wafer 212 at positions corresponding to the quantum circuit devices 204 or the superconducting circuit 206 disposed on the device wafer 202. In this manner, the device wafer 202 and the cap wafer 212 are arranged such that a recess 232 of the cap wafer 212 forms an enclosure that houses a respective quantum circuit device 204. A depth of the recessed surface 238 relative to the first surface 234 (e.g., a vertical distance between the first surface 234 and the recessed surface 238) of each recess 232 can be in a range of 5-500 μm. A lateral dimension of a recess 232 along the X axis or the Y axis is greater than a respective quantum circuit device 204 enclosed by the recess 232. In some instances, the lateral dimension of a recess 232 may be determined by another design parameter. For example, in order to suppress propagation of electromagnetic waves with a frequency less than a cut off frequency inside a recess 232, the lateral dimension of the recess 232 can be determined as a value which is less than a maximal distance corresponding to the cutoff frequency.

In some implementations, the depth of each recess 232 can determine a participation ratio of the electric fields around the quantum circuit device 204. A participation ratio can be adjusted to tune the coherence time of the quantum circuit device 204. Instead of having the fields mostly in the first substrate which has an RF loss, a ground plane can reside on the recessed surface 238 in the cap wafer 212. In some instances, the distances between the ground plane and the quantum circuit device 204 can be controlled allowing some of the electric field between the ground plane and the quantum circuit device 204 to be confined in the space defined by the recess 232, rather than in the lossy first substrate 203 of the device wafer 202. For example, the participation ratio can be controlled by tuning the depth of the recess 232 of the cap wafer 212 as compared to the thickness of the device wafer 202.

In certain implementations, the depth of each of the recesses 232 can be determined according to a desired coupling between the circuitry on the recessed surface 238 and the quantum circuit device 204 on the surface of the device wafer 202. In some instances, the first and second substrates 203, 213 may have a high permittivity to reduce capacitive crosstalk between the superconducting circuit 206 and the circuitry portions 214, 216 as the electric fields stay localized in the first and second substrates 203, 213, respectively.

As shown in FIG. 2, the cap wafer 212 is bonded to the device wafer 202 using bonding bumps 224. In some implementations, each of the bonding bumps 224 may include conductive or superconductive materials, such as copper or indium bumps. The cap wafer 212 is bonded with the device wafer 202 with the first surface 234 facing the surface of the device wafer 202 on which the quantum circuit devices 204 and the superconducting circuit 206 are disposed. In some implementations, the bonding bumps 224 can provide electrical communication of the superconducting circuit 206 on the device wafer 202 with the various circuitry portions (e.g., 214, 216, 218, and 220) on the cap wafer 212. The gap between the first surface 234 of the cap wafer 212 and the surface where the quantum circuit devices 204 reside on the device wafer 202 is determined by the height of the bonding bumps 224. In some implementations, the height of the bonding bumps can be controlled by the thickness of the bonding bumps initially deposited on the cap wafer 212 and the bonding process. For example, the gap between the cap wafer 212 and the device wafer 202 is equal to or less than 3 μm, or in another range.

In some instances, adjacent quantum circuit devices 204 disposed on the device wafer 202 can be coupled through a coupling line as a part of the superconducting circuit 206 extending along the surface of the device wafer 202 over at least a portion of the distance between the adjacent quantum circuit devices 204. The coupling between the adjacent quantum circuit devices 204 can be capacitive or direct. In some instances, at least a portion of the coupling line can also be encapsulated by a respective recess 232 in the cap wafer 212. In some implementations, multiple quantum circuit devices 204 can form a lattice, in which all or a subset of the quantum circuit devices 204 (e.g., each qubit device) in the lattice are coupled to one or more neighboring quantum circuit devices 204. In some implementations, a lattice may be coupled to one or more neighboring lattices.

In some implementations, the circuitry portions 214, 216, 218, 220 on the cap wafer 212 may include a variety of circuit elements to control or readout the quantum circuit devices 204 on the device wafer 202. For example, the circuitry portion 216 includes flux bias lines which can provide magnetic flux locally to qubit devices to tune their frequencies. In this case, the circuitry portion 216 may be implemented as the circuitry shown in FIGS. 4A, 4B, or in another manner. The circuitry portion 216 may also include tunable-frequency coupler devices, and microwave feedlines. The circuitry portion 216 on the recessed surface 238 may include resonator devices which are capacitively coupled to qubit devices to readout qubits. In some examples, the circuitry portion 216 may include microwave feedlines which are coupled to one or several of the resonator devices to allow microwave excitation of the resonator devices used to readout qubits. In this case, the circuitry portion 216 may be implemented as the planar resonators 504 shown in FIG. 5. The circuitry portion 214 on the first surface 234 of the cap wafer 212 may include microwave lines which are capacitively coupled to qubit devices to drive qubits. The circuitry portion 220 on the second surface 236 or the circuitry portion 214 on the first surface 234 of the cap wafer 212 may further include filters, isolators, circulators, amplifiers, or other circuit elements.

In some implementations, the circuitry portion 216 on the recessed surface 238 may be coupled to the circuitry portion 214 on the first surface 234 and the circuitry portion 220 on the second surface 236 through conductive pathways. For example, the circuitry portion 216 can be galvanically coupled to the circuitry portion 214 through conductive lines 218 disposed or patterned on sidewalls 240 of the recess 232. In some instances, each of the conductive lines 218 includes a patterned metal coating that covers a portion of the sidewalls 240 extending from the recessed surface 238 to the first surface 234. In certain examples, each of the conductive lines 218 includes an unpatterned metal coating that covers the entire sidewalls 240. For another example, the circuitry portion 216 may be electrically coupled to the circuitry portion 214 through the conductive vias 222A, 222B and the circuitry portion 220 on the second surface 236. In some instances, the circuitry portion 216 and the circuitry portion 214 may be coupled in another manner. In some instances, the circuitry portion 214 on the first surface 234 of the cap wafer 212 can be capacitively and/or inductively coupled to the circuitry portion 216 on the recessed surface 238 of the cap wafer, for example, using an interdigitated capacitive coupler device. In other instances, the circuitry portions 214 and 216 may be inductively coupled. For example, the circuitry portions 214 and 216 including coplanar waveguides may be arranged next to each other so as to be inductively coupled. For example, the circuitry portion 216 may include a bias tee or a diplexer circuit containing capacitive and/or inductive coupling components which is used to combine a high-frequency XY qubit control signal with a low-frequency flux bias control signal received from the circuitry portion 214.

In some instances, the circuitry portions 214 and 216 can be coupled through one or more electrically conductive vias 222. For example, the circuitry portion 214 may be connected to an electrically conductive via 222A to the circuitry portion 220 on the second surface 236, which is further connected to the circuitry portion 216 through another electrically conductive via 222B. A capacitance coupling between the two circuitry portions 214, 216 can be achieved by introducing a thin dielectric layer along the radial or the axial direction in one of the electrically conductive vias 222A or 222B. When the thin dielectric layer is disposed along the radial direction of the electrically conductive via, the thin dielectric layer can be sandwiched between top and bottom sections of the conductor in a via hole. In some instances, the thin dielectric layer may reside on one end of the electrically conductive via 222A or 222B. When the thin dielectric layer is disposed along the axial direction of the electrically conductive via, (e.g., a coaxially filled via hole), the thin dielectric layer may be sandwiched between an outer cylinder-shaped conductor and an inner cylinder-shaped conductor.

As shown in FIG. 2, a circuitry portion 228 is formed on the recessed surface 238 and the sidewalls 240. In some implementations, the circuitry portion 228 can be used as a Faraday cage, which can prevent stray electric fields from reaching the quantum circuit device 204. In some implementations, when the circuitry portion 228 contains superconducting materials, the circuitry portion 228 may also be used to exclude stray magnetic fields from reaching the quantum circuit device 204.

In some implementations, the circuitry portions on the cap wafer 212 may be formed in one or more electrically conductive layers on the first surface 234, the second surface 236, or the recessed surface 238. In some instances, the one or more electrically conductive layers may cover at least a portion of sidewalls 240 of each of the recesses 232. In other implementations, each of the one or more electrically conductive layers may include a material that has normal conductance at the operating temperature of the example quantum processing unit 200. In some implementations, the example quantum processing unit 200 can be operated at cryogenic temperatures (e.g., cooled using liquid helium) and each of the one or more electrically conductive layers (or at least a portion) can operate as a superconducting layer at that temperature. In addition, during operation of the example quantum processing unit 200, at least a portion of the one or more electrically conductive layers in the various superconducting circuitry of the cap wafer 212 can be grounded.

As shown in FIG. 2, the cap wafer 212 includes electrically conductive vias 222 (e.g., via holes filled with conductive materials) each extending through the second substrate 213. A first length of the electrically conductive vias 222A along the Z axis corresponds to a thickness of the second substrate 213, which can be in the range of 1 μm to 2 mm. A second length of the electrically conductive vias 222B along the Z axis corresponds to a difference between the thickness of the second substrate 213 and the depth of the recess 232. In some implementations, the electrically conductive vias 222A, 222B include a material (e.g., Al, In, Ti, Pn, Sn, etc.) that is superconducting at an operating temperature of the example quantum processing unit 200.

As shown in FIG. 2, the electrically conductive via 222A provides an electrical connection between the circuitry portion 214 on the first surface 234 and the circuitry portion 220 on the second surface 236. In some implementations, this enables both outside connections to land on the second surface 236 (e.g., unbonded side) of the cap wafer 212 and then connect to the first surface 234 (e.g., bonded side) and from there down to the superconducting circuit 206 and further to the quantum circuit devices 204, for example, through the bonding bumps 224. The electrically conductive via 222B provides an electrical connection between the circuitry portion 220 on the second surface 236 and the circuitry portion 216 on the recessed surface 238. In some implementations, the electrically conductive vias 222A, 222B can be used to form a continuous ground plane through the example quantum processing unit 200, such that a solidly connected ground plane can be maintained across both the device wafer 202 and the cap wafer 212. Multiple electrically conductive vias 222A, 222B connected to the ground planes located on the first and second surfaces 234, 236 of the cap wafer 212, and the recessed surface 238 may be arranged in a regular array to avoid a formation of a chip-mode resonance and to mitigate unwanted modes (e.g., coupled slotline mode, parallel-plate waveguide modes, or resonant patch mode). For example, such a regular array of electrically conductive vias connected to the ground planes can push dielectric chip modes with the cap wafer 212 to higher frequencies.

In some instances, quantum circuit devices 204 may be coupled via alternative signal routing levels provided by the circuitry portions 214, 216, 220, the conductive lines 218, and the electrically conductive vias 222A, 222B on the cap wafer 212. For example, non-neighboring quantum circuit devices 204 without qubit-to-qubit connections (e.g., direct coupling lines on the device wafer 202) may be provided by the cap wafer 212. In some implementations, the circuitry portion 214 may be coupled to the superconducting circuit 206 using capacitive, inductive, or galvanic connections. In some instances, the circuitry portions 214, 216, 220 may include planar transmission lines, for example coplanar waveguides, substrate integrated waveguides, or another type of planar transmission line.

In some implementations, a subset of the one or more electrically conductive vias 222 are electrically coupled with control lines to supply control signals to or are coupled with other signal lines to retrieve readout signals from, the quantum circuit devices 204 of the quantum processing unit 200. For example, the control signals can be provided to the device wafer 202 from a signal delivery system (e.g., the signal delivery system 106 of the quantum computing system 100) or the readout signals can be retrieved from the quantum circuit devices 204 to the signal delivery system. In some implementations, a subset of the one or more electrically conductive vias 222A, 222B may be grounded to provide ground to electrically coupled circuitry portions. In some instances, the one or more electrically conductive vias 222A, 222B may include another subset that can be used for thermalization. In this case, the cap wafer 212 allows better heatsinking of the quantum circuit devices 204 to the refrigeration system using the one or more electrically conductive vias 222A, 222B as thermal paths for heat dissipation. The methods and techniques presented here can reduce losses in the quantum circuit devices 204.

In some instances, the second surface 236 of the cap wafer 212 can be coated with a material with a low thermal emissivity, which can reduce the heat load on the quantum circuit devices 204 by reflecting infra-red thermal radiation emitted by the surrounding components. For example, the ground plane on the second surface 236 of the cap wafer 212 can be coated with, or otherwise include the material with a low thermal emissivity. The material with a low thermal emissivity may include a thin layer of superconductive or non-superconductive metal, e.g., gold (Au), palladium (Pd), platinum (Pt), Al, and Ti.

FIG. 3A is a schematic diagram of an exploded view of an example quantum processing unit 300. The example quantum processing unit 300 includes multiple device dies 302 (e.g., 302A, 302B, and 302C) and a cap wafer 304. The cap wafer 304 includes multiple recesses 310 and each of the device dies 302 includes four qubit devices 306 and two tunable-frequency coupler devices 308. As shown in FIG. 3A, two neighboring qubit devices 306 are coupled together through a tunable-frequency coupler device 308. The qubit device 306 can be capacitively coupled to the tunable-frequency coupler 308 through a capacitor. As shown in the example quantum processing unit, the device dies 302 and the cap wafer 304 are arranged such that recesses 310 of the cap wafer 304, when the device dies 302 and the cap wafer 304 are bonded together, form enclosures that house the qubit devices 306 and the tunable-frequency coupler device 308 of the device dies 302. In some implementations, the example quantum processing unit 300 may include additional and different features or components and components of the example quantum processing unit 300 may be implemented in another manner.

In some implementations, the tunable-frequency coupler device 308 may be implemented as a tunable-frequency transmon qubit device. For example, the tunable-frequency coupler device 308 includes two Josephson junctions connected in parallel with each other to form a circuit loop, which resides adjacent to a control line. The tunable-frequency coupler device 308 may also include other circuit components. A control line can receive control signals, for example, from an external control system (e.g., the control system 105 of FIG. 1). In some instances, the control line can include, for example, a flux bias device that is configured to apply an offset magnetic field to the tunable-frequency coupler device 308. For instance, the flux bias device may include an inductor that has a mutual inductance with the circuit loop of the tunable-frequency coupler device 308. The control line may be located at a recessed surface of the recesses 310 on the cap wafer 304. In some implementations, the effective coupling between the two qubit devices 306 can be controlled or actuated by tuning a magnetic field applied to the tunable-frequency coupler device 308. For example, a control signal (e.g., a DC or an AC current) can be applied to a control line to tune the magnetic flux threading to the circuit loop of the tunable-frequency coupler device 308 to turn on or off the coupling.

In some examples, the qubit device 306 may be implemented as a fixed-frequency transmon qubit device. For example, a qubit device 306 may include a Josephson junction and a capacitor which are connected in parallel. In some instances, the qubit device 306 may be implemented as a tunable-frequency qubit device. In this case, the qubit device 306 may include one or more tunable transmon qubit devices or tunable fluxonium qubit devices. In some implementations, the qubit device 306 may include another type of tunable-frequency qubit device. When the qubit device 306 is a tunable-frequency qubit device, the transition frequency of the tunable-frequency qubit device can be controlled by a magnetic flux provided by a separate control line on the cap wafer 304. In some instances, the transition frequency may be controlled in another manner, for instance, by another type of control signal. In some implementations, the control line may be coupled (e.g., conductively, capacitively, or inductively) to a control port to receive control signals.

FIG. 3B is a schematic diagram of a perspective view of an example quantum processing unit 320. The example quantum processing unit 320 includes multiple device dies 322 and a cap wafer 324. The cap wafer 324 includes multiple recesses 330 and each of the device dies 322 includes eight qubit devices 332. Each of the qubit devices 332 is conductively connected to a respective electrode 334. For example, as shown in FIG. 3B, a first qubit device 332A in the device die 322A is galvanically connected to a first electrode 334A and a second qubit device 332B in the device die 322B is galvanically connected to a second electrode 334B. As shown in the example quantum processing unit 320, the device dies 322 and the cap wafer 324 are arranged such that recesses 330 of the cap wafer 324, when the device dies 322 and the cap wafer 324 are bonded together, form enclosures that house the qubit devices 332 of the device dies 322. In some implementations, the example quantum processing unit 320 may include additional and different features or components and components of the example quantum processing unit 320 may be implemented in another manner.

As shown, the cap wafer 324 includes multiple inter-chip coupler arrays 326 (e.g., 326A, 326B, and 326C), which, when the device dies 322 and the cap wafer 324 are bonded together, are configured to provide inter-chip coupling. The inter-chip coupler arrays 326 may be configured as shown in FIG. 3B or in another manner. Each of the inter-chip coupler arrays 326 is configured to provide coupling between qubit devices 306 on different device dies 322. As shown in FIG. 3B, the inter-chip coupler array 326A is configured to communicably couple the qubit devices 332 on the device die 322A and on the device die 322B; the inter-chip coupler array 326B is configured to communicably couple the qubit devices 332 on the device die 322B and on the device die 322C; and the inter-chip coupler array 326C is configured to communicably couple the qubit devices 332 on the device die 322C and on the device die 322D.

In some instances, the inter-chip coupler array 326 may be configured to communicably couple qubit devices 332 of device dies 322 that are not adjacent to each other. For example, an inter-chip coupler array 326 may include one or more inter-chip coupler devices 328 that can extend or be routed across the cap wafer 324 to provide coupling between qubit devices 332 on the device die 322A and 322C or 322D. In this case, an inter-chip coupler device 328 may be routed on a surface of the cap wafer 324, recessed surfaces and/or sidewalls of the recesses 330 of the cap wafer 324.

As shown in the example quantum processing unit 320, each of the inter-chip coupler devices 328 includes a conductive line 338 and two electrodes 336A, 336B. The device dies 322 and the cap wafer 324 are arranged such that each of the two electrodes 336A, 336B of the inter-chip coupler device 328 form a coupling with respective electrodes 334 of respective qubit devices 332. For example, the coupling can be capacitive through a gap separating the two respective electrodes (e.g., 334A of the qubit device 332A and 336A of the inter-chip coupler device 328). For example, the coupling can be conductive through one or more bonding bumps 340 galvanically connecting the two respective electrodes (e.g., 334A of the qubit device 332A and 336A of the inter-chip coupler device 328). In some instances, the coupling between the inter-chip coupler 328 and the qubit device 332 is inductive. For example, the electrodes 336 of the inter-chip coupler 328 may be configured as an inductor that has a mutual inductance with a circuit loop in a qubit device 332A of a device die 322. In some instances, the inter-chip coupler device 328 may be implemented as the control line 416 and the planar loop 430 of the control line 416 shown in FIGS. 4A-4B or in another manner.

FIGS. 4A-4B are schematic diagrams of top view and cross-sectional view of an example quantum processing unit 400. The example quantum processing unit 400 includes a device wafer 402 and a cap wafer 404. As shown in FIGS. 4A-4B, the cap wafer 404 includes a first surface 412 and a second surface 414; and the device wafer 402 includes a first surface 422 and a second surface 424. The first surface 412 of the cap wafer 404 and the first surface 422 of the device wafer 402 face each other and are bonded together by bonding bumps 428. The device wafer 402 includes a quantum circuit device 408 residing on the first surface 422. The cap wafer 404 includes a planar loop 430 as part of a control line 416. The planar loop 430 interacts with the quantum circuit device 408 on the device wafer 402 (e.g., the SQUID loop 409 of the quantum circuit device 408) to generate and control a local magnetic flux threading the SQUID loop 406. In some instances, the planar loop 430 of the control line 416 may be implemented as a single-turn loop, a multi-turn loop, or in another form. The control line 416 is disposed in a recess 406, which is defined by a recessed surface 418 and sidewalls 420. One end 427 of the control line 416 (as indicated by the arrow at one end of the control line 416) is galvanically connected to ground plane 426 on the cap wafer 404. The cap wafer 404 may further include various superconducting circuitry disposed at various surfaces of the cap wafer 404. For example, the device wafer 402 and the cap wafer 404 may be implemented as the device wafer 202 and the cap wafer 212 in FIG. 2. In some implementations, the example quantum processing unit 400 may include additional and different features or components and components of the example quantum processing unit 400 may be implemented in another manner.

The methods and techniques disclosed here can reduce unpredictable, non-localized interactions between different elements of a superconducting circuit, which are caused by a propagation of superconducting currents (e.g., supercurrents) in thin films. Supercurrents run along edges of thin films due to the Meissner effect which can cause flux crosstalk between qubit devices at different locations. For example, when a current signal is applied on a flux bias line at a first location, a supercurrent can generate a small bias flux at a second, distinct location. The methods and techniques presented here can effectively sink and remove supercurrents that are circulating around quantum circuit devices, reduce unwanted flux crosstalk, and reduce the coherent error, for example in two-qubit gates of superconducting quantum computers.

As shown in FIGS. 4A-4B, ground planes 426 on the first surface 422 of the device wafer 402 and the first surface 412 of the cap wafer 404 are bonded together by the bonding bumps 428. In some implementations, the cap wafer 404 can reduce flux crosstalk by guiding the supercurrents from the ground planes 426 on the device wafer 402 to the bonding bumps 428, which supercurrents can be collected by and dispersed at the ground plane 426 on the cap wafer 404. In other words, the ground plane 426 on the cap wafer 404 along with the selective placement of the bonding bumps 428 provides an opportunity to segment the ground plane. In some instances, segments of ground planes created can be kept at an equipotential.

In some implementations, the quantum circuit device 408 disposed on the first surface 422 of the device wafer 402 may be implemented as the quantum circuit device 204 as shown in FIG. 2 including qubit devices, or another type of quantum circuit device. As shown in FIGS. 4A-4B, the quantum circuit device 408 is configured as a tunable transmon qubit device with qubit electrodes 410 and two Josephson junctions forming a Superconducting Quantum Interface Device (SQUID) loop 409. The qubit electrodes 410 are configured to form a shunt capacitor in parallel with the two Josephson junctions. In some instances, the qubit electrodes 410 of the quantum circuit device 408 may be configured to capacitively couple to other circuit components in the cap wafer 404 and the device wafer 402, for example, the planar loop 430 of the control line 416 on the cap wafer 404 and the ground plane 426 on the device wafer 402. The SQUID loop 409 and the qubit electrodes 410 containing superconducting materials are surrounded by the ground planes 426 on the first surface 422 of the device wafer 402.

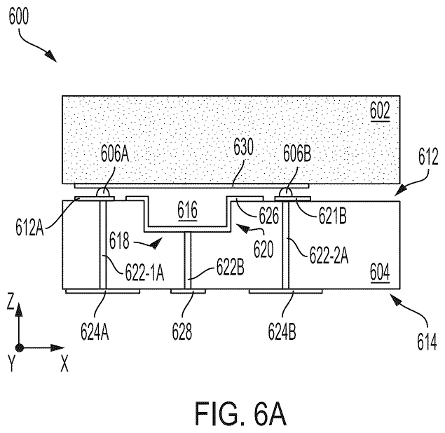

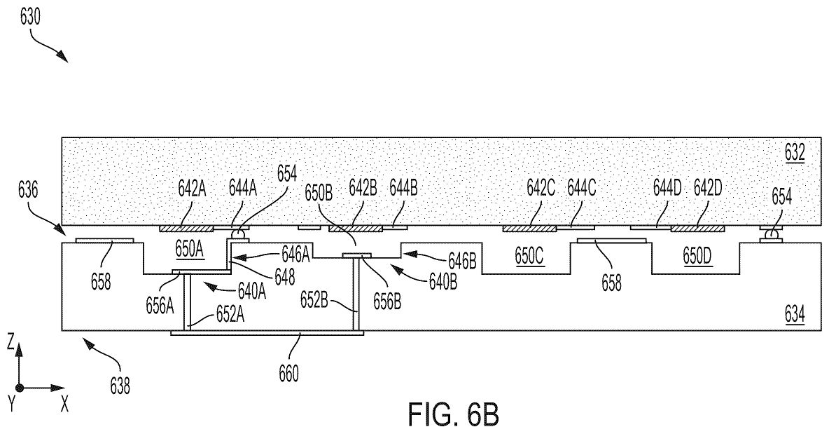

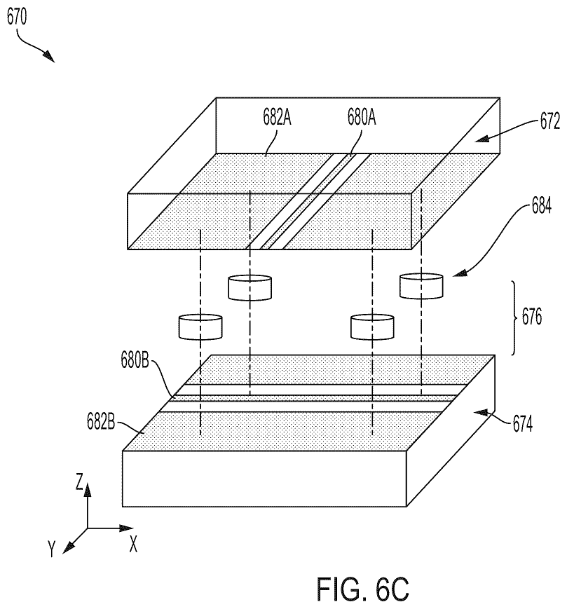

In some implementations, the control line 416 on the recessed surface 418 of the recess 406 on the cap wafer 404 includes conductor metal that carries a control signal to and from the quantum circuit device 408 or other quantum circuit devices on the device wafer 402. In some instances, the control line 416 is a planar transmission line (e.g., coplanar waveguides, substrate integrated waveguides, or another type of planar transmission line). For example, the control line 416 may be implemented as the coplanar waveguides shown in FIG. 6C.

In some examples, the control line 416 is a flux bias line. In this case, the planar loop 430 is inductively coupled to the SQUID loop 409, the frequency of the quantum circuit device 408 can be tuned by applying a magnetic field 431 through the SQUID loop 409. The magnetic field 431 can be generated by the flux bias line. The desired mutual inductance can be achieved by adjusting the distance between the flux bias line and the SQUID loop 409. In some cases, the distance between the flux bias line and the SQUID loop 409 is defined by the depth of the recess 406 and the height of the bonding bumps 428. For example, the distance is in a range of 10-20 μm, or may be in another range. In some instances, the value of the mutual inductance is in a range of 400-800 femto Henry (fH), or in another range.

In some examples, the control line 416 is a microwave line. In this case, the control line 416 is capacitively coupled to the quantum circuit device 408 on the device wafer 402, for example through the qubit electrodes 410. The capacitive coupling between the quantum circuit device 408 and the control line 416 can be set by the relative positions and distance of the cap wafer 404 and the device wafer 402. The state of the quantum circuit device 408 can be manipulated by sending microwave pulses along the control line 416. In some instances, the distance between the control line 416 and the quantum circuit device 408 is equal to or greater than a threshold distance, e.g., around 50-200 μm. In some instances, the capacitive coupling is in a range of 0.1-0.5 femto Farad (fF), or in another range.

In some instances, the control line 416 which is capacitively and inductively coupled to the quantum circuit device 408 can simultaneously serve as a flux bias line and a microwave line. In this case, the control signal on the control line 416 can include a low-frequency component (e.g., typically with a highest frequency value up to ˜500 MHz or a different value) and a high-frequency component at or near the qubit frequency (e.g., typically about 4 GHz or a different value). The low-frequency component in the planar loop 430 generates a local magnetic field that interacts with the SQUID loop 409 of the quantum circuit device 408 and tunes the frequency of the quantum circuit device 408. In this case, the low-frequency component of the current bias is a flux bias signal. The high-frequency component interacts capacitively with the qubit electrodes 410 of the quantum circuit device 408 and causes the wavefunction in the qubit to change in a controlled fashion. The high-frequency component of the current bias is a microwave drive signal.

The methods and devices presented here can allow independent tuning of both the capacitive and magnetic coupling, both of which have to be correctly targeted to get correct operation. The ability to tune both capacitive and magnetic coupling independently allows combined flux bias and microwave lines to be integrated into the cap wafer 404. In some implementations, by moving these circuit elements from the device wafer 402 to the cap wafer 404, the capacitive coupling is significantly reduced since the planar loop 430 of the control line 416 to the quantum circuit device 408 are separated by vacuum with a lower permittivity relative to that of a substrate of the device wafer 402 (e.g., a silicon substrate).

FIG. 5 is a schematic diagram of a top view of an example cap wafer 500. The example cap wafer 500 includes multiple planar resonators 504 coupled to a feedline 502. As shown in FIG. 5, the multiple planar resonators 504 and the feedline 502 have a coplanar waveguide structure, which includes a central conductive line and a ground plane. In some instances, the feedline 502 and the planar resonators 504 may include another type of planar transmission line, for example, a microstrip transmission line or a substrate integrated waveguide. Each of the planar resonators 504 is inductively coupled to the central conductive line of the feedline 502. In some implementations, the feedline 502 allows multiplexing the multiple planar resonators 504 on the cap wafer 500. In some implementations, the cap wafer 500 may include additional and different features or components and components of the example cap wafer 500 may be implemented in another manner.

As shown in FIG. 5, each of the planar resonators 504 and the feedline 502 resides on recessed surfaces 506 of respective recesses 508 of a substrate. In some instances, the planar resonators 504 and the feedline 502 on the recessed surface 506 may be implemented as part of the circuitry portion 216 on the recessed surface 238 of the cap wafer 212 shown in FIG. 2 or in another manner. In some implementations, the planar resonators 504 and the feedline 502 are superconducting microwave devices operating in the microwave frequency domain in a cryogenic environment. In some implementations, the feedline 502 and the planar resonators 504 may be used as a readout resonator for receiving a readout signal from a qubit device on a device wafer. As shown, the feedline 502 includes two ports 510A, 510B. For example, a readout signal can be received on the port 510A and an output signal can be obtained at the port 510B.

As shown in the example cap wafer 500, the central conductive lines of the planar resonators 504 are shaped in a meander-like structure. Each of the planar resonators 504 is inductively coupled to the feedline 502 via a respective arm 512 which is adjacent and parallel to the central conductive line of the feedline 502. Each of the planar resonators 504 includes parallel segments forming intra-line capacitors.

In some implementations, the recesses 508 may be implemented as the recesses 232 shown in FIG. 2 and formed by performing the operations 802, 804, and 806 in the example process 800 shown in FIG. 8 or in another manner. In some implementations, the central conductive line and the ground planes of the feedline 502 and the planar resonators 504 include superconductive materials. For example, the feedline 502 and the planar resonator 504 may be formed on the recessed surfaces 506 as part of the second circuitry portion 842B by performing the operations 808, 810, and 812 of the example process 800 shown in FIG. 8. In some instances, the feedline 502 and the planar resonators 504 may be formed in another manner.

In certain examples, the internal resonator property of each of the planar resonators 504, such as the resonant frequency, loss, signal-to-noise ratio, quality factor, are determined by physical parameters of the planar resonators 504. In some implementations, the central conductive lines of the planar resonators 504 may have different physical dimensions, e.g., total length, width, thickness and number of turns of the central conductive lines of the planar resonators 504, length of parallel segments of the planar resonators 504, distance between the central conductive line and the ground plane, length of the arm 512 for inductively coupling with the feedline, dielectric properties of the substrate, and depth of the recesses 508. In some implementations, each of the planar resonators 504 can be designed and optimized individually with different internal resonator properties. In some instances, the external quality factor depends on characteristics of the planar resonator 504, the coupling strength between the planar resonator 504 and the feedline 502, and impedance of the two ports 510A, 510B.

FIG. 6A is a schematic diagram of a cross-sectional view of an example quantum processing unit 600. The example quantum processing unit 600 includes a device wafer 602 and a cap wafer 604. As shown in FIG. 6A, the cap wafer 604 includes a first surface 612 and a second surface 614. The device wafer 602 and the cap wafer 604 are bonded together using bonding bumps 606A, 606B. The cap wafer 604 shown in FIG. 6A further includes a recess 616, which is defined by a recessed surface 618 and sidewalls 620.

In some implementations, the cap wafer 604 may include circuitry portions on the first, second surfaces 612, 614 and the recessed surface 618 providing different functionalities. In some instances, the first and second surfaces 612, 614 of the cap wafer 604 may be implemented as the first and second surfaces 234, 236 of the cap wafer 212 shown in FIG. 2 or in another manner. In the example shown in FIG. 6A, the first surface 612 includes circuitry portions 621A, 621B; and the second surface 614 includes circuitry portions 624A, 624B and 628. As shown in FIG. 6A, the circuitry portion 626 that resides on the cap wafer 614 covers a portion of the first surface 612, the recessed surface 618, and the sidewalls 620.

In some implementations, the circuitry portions on different surfaces can be electrically connected and routed to feed control signals to, or transfer readout signals from, the device wafer 602. As shown in the example quantum processing unit 600, the circuitry portions 624A, 624B on the second surface 614 of the cap wafer 604 are electrically coupled to the circuitry portions 621A and 621B on the first surface 612 of the cap wafer 604 through respective conductive vias 622-1A, 622-2A. The circuitry portions 621A, 621B on the first surface 612 are electrically coupled to a superconducting circuit 630 on a surface of the device wafer 602 using respective bonding bumps 606A, 606B. The circuitry portion 628 on the second surface 614 of the cap wafer 604 is electrically coupled to the circuitry portion 626 through the conductive vias 622B. In some implementations, the circuitry portions 628 and 626 can be grounded.

In some instances, the conductive vias 622-1A and 622-2A may be implemented as the conductive vias 222A shown in FIG. 2 or in another manner. In some instances, the conductive vias 622B may be implemented as the conductive vias 222B shown in FIG. 2 or in another manner. In certain instances, the bonding bumps 606A, 606B may be implemented as the bonding bumps 224 shown in FIG. 2 or in another manner.

In some implementations, during operation, the circuitry portion 624A on the second surface 614 of the cap wafer 604 may receive control signals from a control system (e.g., the control system 105 of the computing system 101 shown in FIG. 1). The control signal can be then directed across the conductive via 622-1A to the circuitry portion 621A on the first surface 612. The control signal can be then directed to the superconducting circuit 630 on the device wafer 602 through the bonding bump 606A. Similarly, a readout signal from the superconducting circuit 630 on the device wafer 602 can be directed to the circuitry portion 621B on the first surface 612 of the cap wafer 604 using the bonding bump 606B. The readout signal can be then directed across the conductive via 622-2A to the circuitry portion 624B on the second surface 614 and eventually received by the control system.

FIG. 6B is a schematic diagram of a cross-sectional view of an example quantum processing unit 630. The example quantum processing unit 630 includes a device wafer 632 and a cap wafer 634. In some implementations, the device wafer 632 and the cap wafer 634 may be implemented as the device and cap wafers 202, 204 shown in FIG. 2 or in another manner. As shown in FIG. 6B, the device wafer 632 and the cap wafer 634 are bonded together using bonding bumps 654.

As shown in FIG. 6B, the device wafer 632 includes four quantum circuit devices 642A, 642B, 642C and 642D disposed on the surface of the device wafer 632. Each of the quantum circuit devices 642A, 642B, 642C and 642D may be electrically coupled to a respective portion of a superconducting circuit 644A, 644B, 644C or 644D. Specifically, a first quantum circuit device 642A is electrically coupled to a first portion of a superconducting circuit 644A; a second quantum circuit device 642B is electrically coupled to a second portion of a superconducting circuit 644B; a third quantum circuit device 642C is electrically coupled to a third portion of a superconducting circuit 644C; and a fourth quantum circuit device 642D is electrically coupled to a fourth portion of a superconducting circuit 644D. In some implementations, the quantum circuit devices 642 and the superconducting circuit 644 may be implemented as the quantum circuit device 204 and the superconducting circuit 206 shown in FIG. 2 or in another manner.

As shown in FIG. 6B, the cap wafer 634 includes a first surface 636 and a second surface 638. The cap wafer 634 includes four recesses 650A, 650B, 650C and 650D. In some implementations, each of the four recesses 650A, 650B, 650C and 650D can be implemented as the recess 232 shown in FIG. 2 or in another manner. As shown in example quantum processing unit 642A, 642B, 642C and 642D, each of the four recesses 650A, 650B, 650C and 650D on the cap wafer 634 encloses a respective quantum circuit device 642A, 642B, 642C or 642D on the device wafer 632.

In the example shown in FIG. 6B, a first recess 650A is defined by a first recessed surface 640A and sidewalls 646A; and a second recess 650B is defined by a second recessed surface 640B and sidewalls 646B. As shown in FIG. 6B, the first recessed surface 640A resides at a first depth in the cap wafer 634 relative to the first surface 636 and the second recessed surface 640B resides at a second depth in the cap wafer 634 relative to the first surface 636. The first depth is greater than the second depth. In certain instances, the first and second depths may have another relationship.

In some implementations, the cap wafer 634 includes circuitry portions on its first, second, and recessed surfaces 636, 638 and 640. In the example quantum processing unit 630, the cap wafer 634 includes a first circuitry portion 658 disposed on the first surface 636, a second circuitry portion 660 disposed on the second surface 638, a third circuitry portion 656A on the first recessed surface 640A, and a fourth circuitry portion 656B on the second recessed surface 640B. In some instances, the first and second circuitry portions 658, 660 may be implemented as the circuitry portions 214 and 220 shown in FIG. 2, or in another manner.

In certain implementations, the circuitry portions disposed at different surfaces of the cap wafer 634 may be galvanically coupled through conductive vias 652 or conductive lines 648 on the sidewalls 646 of the recesses 650. In some implementations, the conductive vias 652 and the conductive lines 648 may be implemented as the respective components 218 and 222 shown in FIG. 2 or in another manner. For example, the third circuitry portion 656A is routed from the first recessed surface 640A through the conductive lines 648 across at least a portion of the sidewalls 646A to the first surface 636, which is galvanically coupled to the first quantum circuit device 642A via the bonding bump 654 and the superconducting circuit 644A. Further, the third circuitry portion 656A is electrically coupled to the second circuitry portion 660 through a first conductive via 652A. Similarly, the fourth circuitry portion 656B is electrically coupled to the second circuitry portion 660 through a second conductive via 652B. As shown in FIG. 6B, the first conductive via 652A extends from the first recessed surface 640A to the second surface 638 of the cap wafer 634; and the second conductive via 652B extends from the second recessed surface 640B to the second surface 638 of the cap wafer 634.

In some implementations, the fourth circuitry portion 656B at the second recessed surface 640B of the second recess 650B may be capacitively coupled to the second quantum circuit device 642B. In some implementations, the capacitive coupling between the second quantum circuit device 642B and the fourth circuitry portion 656B is determined by the distance between the quantum circuit device 642B and the fourth circuitry portion 656B. In some instances, the distance is determined by the height of the bonding bump 654 and the second depth of the second recess 650B. In this case, the first and second quantum circuit devices 642A, 642B, which are not directly coupled, may be coupled together through the first portion of the superconducting circuit 644A, the bonding bump 654, the conductive line 648 on the sidewalls 646A, the third circuitry portion 656A, the conductive via 652A, the second circuitry portion 660, the conductive via 652B, and the fourth circuitry portion 656B. In certain examples, the first and second quantum circuit devices 642A, 642B may be coupled in another manner.

In some implementations, the first circuitry portion 658 on the first surface 636 are capacitively coupled to the superconducting circuit 644 on the device wafer 632. As shown in FIG. 6B, each of the third and fourth portions 644C and 644D of the superconducting circuit are capacitively coupled to the first circuitry portion 658 on the first surface 636 of the cap wafer 634. In this case, the third and fourth quantum circuit device 642C and 642D are coupled through the third portion 644C of the superconducting circuit, the first circuitry portion 658 on the first surface 636 of the cap wafer 634, and the fourth portion 644D of the superconducting circuit. In some implementations, the systems and methods presented here can be used to provide alternative pathways to couple non-neighboring quantum circuit devices 642 on the device wafer 632.

FIG. 6C is a schematic diagram of an exploded view of an example quantum processing unit 670. The example quantum processing unit 670 includes a device wafer 672 and a cap wafer 674. Each of the device wafer 672 and the cap wafer 674 includes a coplanar waveguide. The coplanar waveguide includes a central conductive line and ground planes. In the example quantum processing unit 670, the coplanar waveguide on the device wafer 672 includes a central conductive line 680A and ground planes 682A; and the coplanar waveguide on the cap wafer 674 includes a central conductive line 680B and ground planes 682B.

As shown in the example quantum processing unit 670, each of the device wafer 672 and the cap wafer 674 includes a dielectric substrate with a high permittivity. In some instances, the dielectric substrate may be implemented as the substrate 822 shown in FIG. 8 or in another manner. For example, the dielectric substrate may be a silicon substrate with a relative permittivity of 11.68. As shown in FIG. 6C, the coplanar waveguides on the device wafer 672 and the cap wafer 674 extend along the XY plane perpendicular to each other. In some instances, the coplanar waveguides may be arranged in another manner. The ground planes 682A, 682B are galvanically connected using bonding bumps 684. The central conductive lines 680A, 680B are separated by a gap 676 and the thickness of the gap is defined by the height of the bonding bumps 684 or any other additional etched structure in the device wafer 672 and the cap wafer 674. In some implementations, the gap 676 is filled with a low-permittivity material during operation of the quantum processing unit, e.g., vacuum with a relative permittivity of 1, or another type of insulating material with a low permittivity to reduce the coupling (e.g., cross-talk) between the two coplanar waveguides. In some instances, the coupling between the two coplanar waveguides can be further controlled by controlling the gap separating the two coplanar waveguides. For example, the coplanar waveguide on the cap wafer 674 may reside on a recessed surface in a recess.

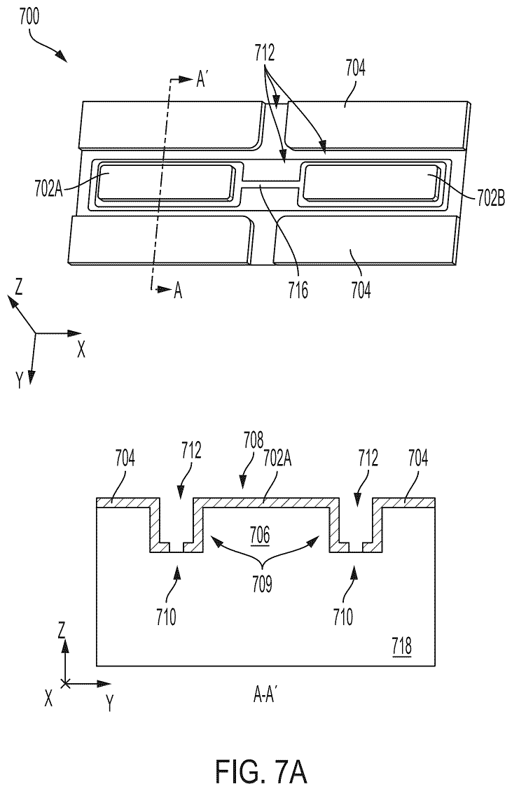

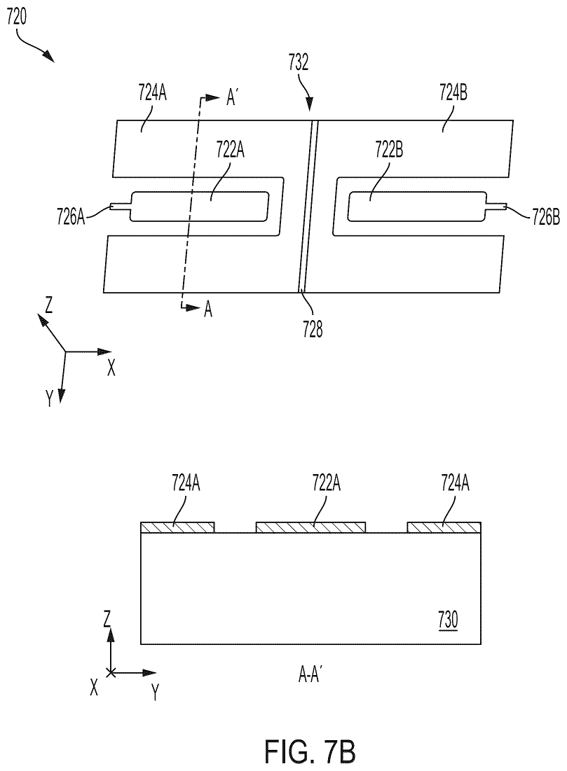

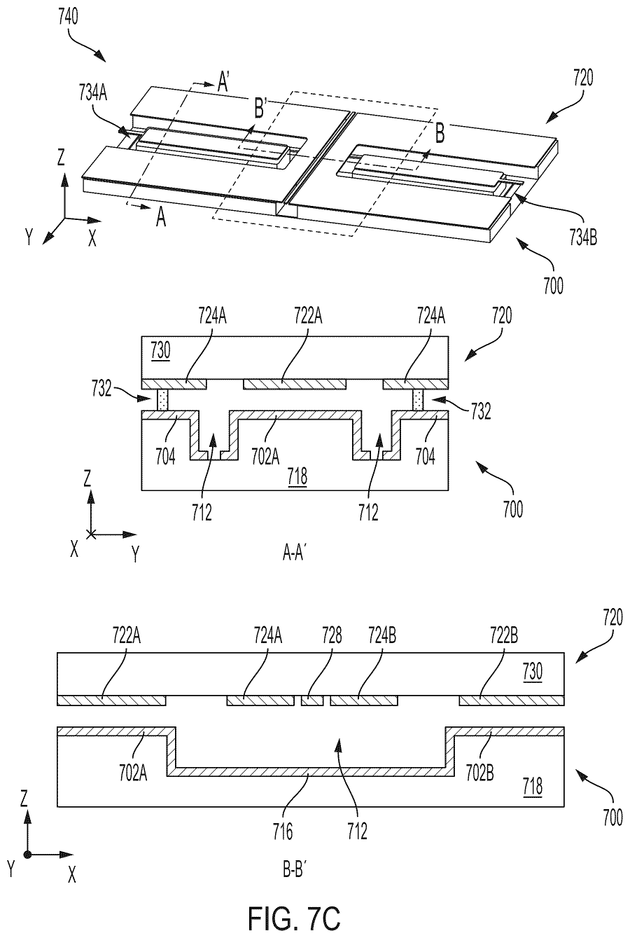

FIG. 7A are schematic diagrams of a perspective view and a cross-sectional view of an example cap wafer 700. The example cap wafer 700 includes two electrodes 702A, 702B, a ground plane 704, and recesses 712, which are formed on a substrate 718. The recesses 712 are defined by recessed surfaces 710 and sidewalls 709. In some instances, the recesses 712 on the substrate 718 may be implemented as the recesses 232 on the substrate 212 shown in FIG. 2 or in another manner. As shown in the example cap wafer 700, the two electrodes 702A, 702B reside on two respective pedestals 706 defined by the surrounding recesses 712.

In some implementations, each of the two electrodes 702A, 702B includes a first portion covering at least a portion of the top surface 708 of the substrate 718, a second portion covering at least a portion of the sidewalls 709 of the recesses 712 around the pedestal 706, and a third portion covering at least a portion of the recessed surfaces 710 of the recesses 712 surrounding the pedestal 706. As shown in FIG. 7A, each of the electrodes 702A, 702B is disposed on the substrate 718 covering the entire top surface 708 of the pedestal 706, and the entire sidewalls 709 of the surrounding recesses 712.

In the example cap wafer 700, the two electrodes 702A, 702B are galvanically connected together via a connection 716 forming a continuous, conductive pathway between the two electrodes 702A, 702B. As shown in FIG. 7A, the connection 716 between the two electrodes 702A, 702B resides on the recessed surface 710 between the two pedestals 706. The two electrodes 702A, 702B are surrounded by a continuous ground plane 704. As shown in FIG. 7A, the ground plane 704 resides on the substrate 718 covering at least a portion of the recessed surface 710, the top surface 708, and the sidewalls 709.

In some implementations, the two electrodes 702A, 702B may be implemented as the circuitry portions on the cap wafer 212 as shown in FIG. 2, or in another manner. In some implementations, the two coupling electrodes 702A, 702B, the pedestals 706, and the recesses 710 may be fabricated according to the example process 800 shown in FIG. 8 or in another manner.

FIG. 7B are schematic diagrams of a perspective view and a cross-sectional view of an example device wafer 720. The example device wafer 720 includes two electrodes 722A, 722B on a substrate 730. As shown in FIG. 7B, the two electrodes 722A, 722B may be connected to two respective quantum circuit devices (e.g., the quantum circuit device 204 in FIG. 2) via respective connections 726A, 726B. In some instances, the two electrodes 722A, 722B and the respective connections 726A, 726B may be implemented as the third and fourth portions 644C and 644D of the superconducting circuit as shown in FIG. 6B. The two respective quantum circuit devices are not directly connected or coupled through a coupling line on the device wafer 720. In some implementations, the example device wafer 720 may include another circuit component.

In some aspects, the techniques disclosed here enable additional signal routing pathways. For example as shown in FIG. 7B, the device wafer 720 includes a coplanar waveguide with a central conductive stripe 728 extending along the y-axis between two ground planes 724A, 724B. The coplanar waveguide separating the two electrodes 722A, 722B and thus the two respective quantum circuit devices on the device wafer 720 may be used, for example, propagating coherent signals between other quantum circuit devices (e.g., tunable-frequency coupler device, qubit devices) or other circuit components on the device wafer 720.

FIG. 7C are schematic diagrams of a perspective view and cross-sectional views of an example quantum processing unit 740. The example quantum processing unit 740 includes the example device wafer 720 shown in FIG. 7B and the example cap wafer 700 shown in FIG. 7A. The example quantum processing unit 740 includes two pedestal couplers 734A, 734B. In some implementations, each of the two pedestal couplers 734A, 734B includes a parallel-plate capacitor with one plate on the example cap wafer 700 and the opposite plate on the example device wafer 720. As shown in FIGS. 7A-7C, the example cap wafer 700 and the example device wafer 720 are bonded so that the two electrodes 722A, 722B on the device wafer 720 and the two electrodes 702A, 702B on a cap wafer 700 are aligned with respect to each other. Particularly, the electrodes 702A and 722A form a first pedestal coupler 734A; and the electrodes 702B and 722B form a second pedestal coupler 734B. The two pedestal couplers 734A, 734B are connected in series by the connection 716 on the cap wafer 700.

As shown in FIG. 7C, bonding bumps 732 provide a galvanic connection between the ground planes 724A, 724B on the example device wafer 720 and the ground plane 704 on the cap wafer 700 forming a continuous and uniform ground throughout both the cap wafer 700 and the device wafer 720.

In some implementations, the areas of the first portion of the electrodes 702A, 702B on the cap wafer 700 and the electrodes 722A, 722B on the device wafer 720, and the height of the bonding bumps 732 can be designed and optimized to maximize capacitance and thus the capacitive coupling. In some implementations, the third portion of the coupling electrodes 702A, 702B on the recessed surface 710 and the depth of the recesses 712 can be also designed and optimized to minimize crosstalk and coupling. The methods and techniques presented here can reduce or eliminate needs for the capability to pattern across sidewalls of recesses.

In some implementations, the recess 712 on the cap wafer 700 include trenches, each of which is defined by a recessed trench surface and trench sidewalls. The recessed trench surface resides at a depth relative to the first surface 708 in the cap wafer 700. As shown in FIG. 7C, when the cap wafer 700 and the device wafer 720 are bonded, the trenches form enclosures that house the coplanar waveguide on the device wafer 720.

FIG. 8 is a flow chart showing aspects of an example fabrication process 800. In some implementations, the example process 800 may be used for fabricating a cap wafer with various superconducting circuitry at various positions, for example, the circuitry portion 214, 216, 218, 220, 222, 224 and another component in the cap wafer 212. The example process 800 may include additional or different operations, including operations to fabricate additional or different components, and the operations may be performed in the order shown or in another order. In some cases, operations in the example process 800 can be combined, iterated or otherwise repeated, or performed in another manner.

At 802, a substrate 822 is prepared. In some implementations, the substrate 822 is a float-zone, undoped, single-crystal silicon wafer with a high-resistivity. In some examples, the substrate 822 has a thickness of 320 μm, 670 μm, or another thickness. In some instances, a top surface 830 of the substrate 822 may be cleaned to remove the native oxide. For example, the substrate 822 can be cleaned using an HF etching process and rinsed with deionized (DI) water. In some instances, cleaning of the top surface 830 of the substrate 822 is performed to remove contaminants including organic contaminants and another type of contaminants. In some instances, the substrate 822 may be implemented as the second substrate 213 in FIG. 2 or in another manner.

At 804, a first photoresist layer 824 is patterned. In some implementations, the first photoresist layer 824 may include a negative or positive tone photoresist layer that is patternable in response to a photolithography light source. In some instances, the first photoresist layer 824 may include an e-beam (electron beam) resist layer (e.g., poly methyl methacrylate, methyl methacrylate, or another e-beam resist material) that is patternable in response to an e-beam lithography energy source. In some examples, before patterning, the first photoresist layer 824 is formed directly on the top surface 830 of the substrate 822 using a deposition process such as spin-coating, spray-coating, dip-coating, roller-coating, or another deposition method. After deposition, the first photoresist layer 824 is then patterned using a lithography process that may involve various exposure, developing, baking, stripping, etching, and rinsing processes. As a result, the first photoresist layer 824 is patterned such that openings 826 in the first photoresist layer 824 expose at least a portion of the top surface 830 of the substrate 822. In some implementations, positions of the openings 826 are determined according to the positions and arrangement of quantum circuit devices in one or more device wafers (e.g., the quantum circuit devices 204 in the device wafer 202 shown in FIG. 2) such that the recesses form respective enclosures that house the quantum circuit devices in the device wafer. In some examples, the first photoresist layer 824 has a thickness of 7 um, or another thickness.

At 806, recesses 828 are formed in the substrate 822. In some implementations, the recesses 828 are formed by performing an etching process in the substrate 822 at the openings 826 using the first photoresist layer 824 as a mask. In some instances, recessed surfaces 831 are created at the bottom of the recesses 828 in the body of the substrate 822. Each of the recessed surfaces 831 resides at a depth of a few micrometers to a few tens of micrometers relative to the top surface 830 of the substrate 822. In some instances, the recesses 828 have a uniform depth of 24±1.5 μm or another depth. The recesses 828 are further defined by sidewalls 832, which can be perpendicular to the recessed surfaces 831 or slopped with respect to the recessed surface 831. In some cases, the recesses 828 may be implemented as the recesses 232 shown in FIG. 2, the recesses 406 in FIGS. 4A-4B, and the recesses 616, 650A, 650B, 650C, 650D as shown in FIGS. 6A-6B. In some instances, the recesses 828 may be formed using a dry etching method, for example, a Deep Reactive Ion Etching (DRIE) process, a cryogenic etching process, a gas-phase etching process, or another type of etching process.

After the formation of the recesses 828, the first patterned photoresist layer 824 may be removed. In some instances, the first photoresist layer 824 may be removed by one or more chemical cleaning processes using acetone, 1-Methyl-2-pyrrolidon (NMP), Dimethyl sulfoxide (DMSO), or other suitable removing chemicals. In some examples, the chemicals used may need to be heated to temperatures higher than room temperature to effectively dissolve the first photoresist layer 824. The selection of the remover is determined by the type and chemical structure of the first photoresist layer 824, and the substrate 822 to assure the chemical compatibility of the substrate 822 with the chemical cleaning process. In some implementations, this chemical cleaning process is then followed by a rinsing process using isopropyl alcohol or another chemical, and then using DI water.

At 808, a conductive layer 834 is deposited. In some implementations, the conductive layer 834 may include superconducting metals, superconducting metal alloys, or superconducting compound materials. In some instances, the conductive layer 834 may include multilayer superconductor-insulator heterostructures, stacks of superconducting layers, or another structure. In some examples, an interfacial silicide layer is formed between the conductive layer 834 and the substrate 822 during the deposition of the conductive layer 834 due to an interfacial reaction.

In some implementations, the conductive layer 834 may be deposited on the top surface 830, the recessed surfaces 831, and the sidewalls 832. For example, the conductive layer 834 includes a stack of conductive materials, e.g., Nb/TiW/Nb/MoRe having a total thickness of about 560 nanometers (nm). In some instances, the first conductive layer 834 may be deposited using a Chemical Vapor Deposition (CVD), Physical Vapor Deposition (PVD), or another deposition method.

At 810, a second photoresist layer 836 is patterned. In some instances, the second photoresist layer 836 is patterned on the top surface 830 and the recessed surfaces 831 of the substrate 822. In certain instances, a first portion of the second photoresist layer 836 with openings 838 may be formed on the top surface 830 of the substrate 822 under a first exposure setting and a second portion of the second photoresist layer 836 with openings 840 is formed on the recessed surfaces 831 of the substrate 822 under a second, distinct exposure setting (e.g., a different exposure time, different intensity of the light source, or a different wavelength of the light source). In some instances, the second photoresist layer 836 is deposited and patterned with respect to the operation 804 described above. In certain implementations, the second photoresist layer 836 has a thickness of about 14 um or another thickness.

At 812, circuitry portions 842A, 842B are formed. In some implementations, a first circuitry portion 842A is formed on the top surface 830 of the substrate 822 corresponding to the openings 838 in the first portion of the second photoresist layer 836. A second circuitry portion 842B is formed on the recessed surfaces 831 of the substrate 822 corresponding to the openings 840 in the second portion of the second photoresist layer 836. In some implementations, the circuitry 842A, 842B are formed by performing an etching process to remove the conductive layer 834 exposed at the openings 838, 840 without over-etching the substrate 822. In some instances, the first circuitry portion 842A may be implemented as the circuitry portion 214 in FIG. 2, the ground plane 426 in FIGS. 4A-4B, the circuitry portion 621A, 621B in FIG. 6A, 660 in FIG. 6B, or the coplanar waveguide 680B/682B in FIG. 6C. In some instances, the second circuitry portion 842B may be implemented as the circuitry portion 216 in FIG. 2, the control line 416 or the planar loop 430 of the control line 416 in FIGS. 4A-4B, the planar resonators 504A-504G in FIG. 5, the circuitry portion 626 on the recessed surface 618 in FIG. 6A, and the circuitry portion 656A/656B in FIG. 6B.

At 814, a third photoresist layer 844 is patterned. As shown in FIG. 8, the third photoresist layer 844 after patterning includes openings 846 at the top surface 830 of the substrate 822. In some examples, the third photoresist layer 844 may have a thickness of 18 um or another thickness. In some implementations, the third photoresist layer 844 is deposited and patterned with respect to the operation 804 described above.

At 816, bonding bumps 848 are formed. As shown in FIG. 8, the bonding pumps 848 are formed on the top surface 830 of the substrate 822 corresponding to the openings 846 in the third photoresist layer 844. In some instances, the bonding bumps 848 are formed by depositing a metallization layer on the substrate 822 with the patterned third photoresist layer 844. In some instances, the metallization layer may include indium (In) and another conductive material. In some instances, the metallization layer may have a thickness in a range of 6-7 micrometers (μm). In some implementations, the metallization layer can be deposited using PVD, CVD, electrodeposition, or another method. After depositing the metallization layer, the third photoresist layer 844 can be removed with respect to the operation 806. In some implementations, the height of the bonding bumps 848 after bonding the cap wafer with a device wafer can be less than the thickness of the metallization layer from deposition. For example, a bonding process with a bonding force of a few tens of newton (N) per square millimeter (mm²) can cause a compression to the bonding bumps which defines the gap separating the two respective surfaces of the device wafer and the cap wafer. In some instances, a bonding force is selected to cause a compression of more than 40% the total height of the bonding bumps, resulting the gap in a range of ≤3 μm, or in another range.

In some aspects of what is described here, a modular quantum processing unit includes a first number of quantum processor chips and a second number of cap wafers. The first number may be the same as or different from the second number. Each of the quantum processor chips includes superconducting quantum circuit devices and superconducting circuitry forming a superconducting quantum integrated circuit (QuIC). In some implementations, a cap wafer of the modular quantum processing unit includes inter-module coupler devices, which are configured to bond different quantum processor chips together and to provide inter-module coupling between quantum circuit devices from different quantum processor chips.

In some implementations, using inter-module coupler devices in the cap wafer to interconnect quantum processor chips can provide technical advantages and improvements over other techniques. For example, the methods and techniques presented here may allow dense packing of quantum circuit devices on chips and hence compact structures in quantum computing architectures. In some implementations, inter-module coupler devices reside on a substrate or on inter-module coupler chips.

In some implementations, the methods and techniques described here using multichip modular designs can also be used to improve performance of other superconducting radio frequency electronics modules. In some cases, a combination of these and potentially other advantages and improvements may be obtained. This method can facilitate the scaling of the quantum processing unit. The method can provide greater capital efficiency, e.g., higher certainty of using good chips for cooldowns in large dilution refrigerators. The methods and techniques presented here can reduce wafer usage for producing large QPUs than if either the quantum processor chip or cap wafer is monolithic.

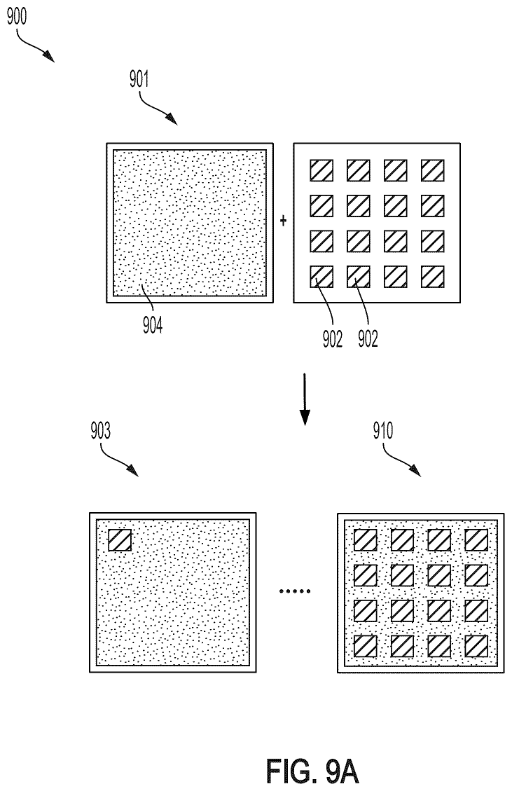

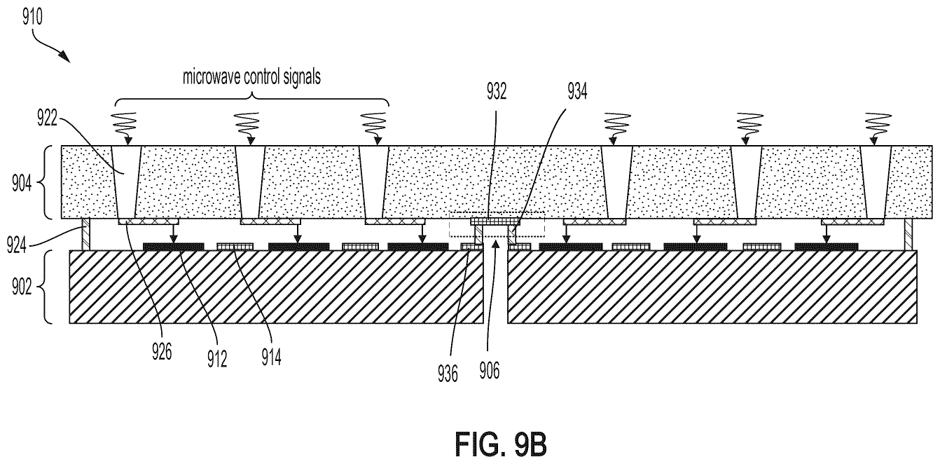

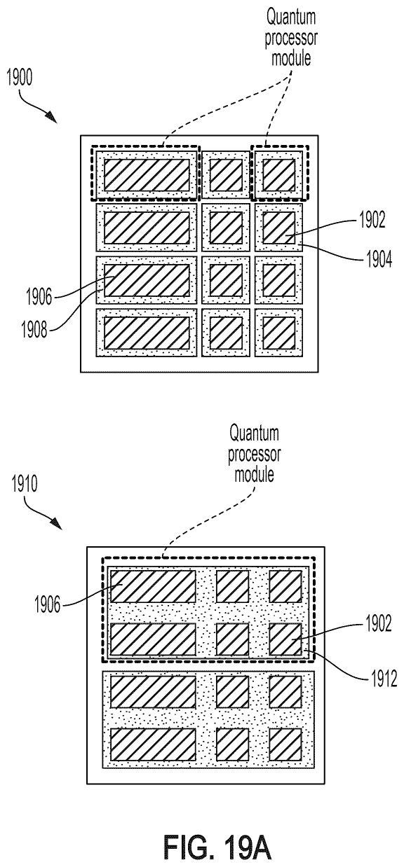

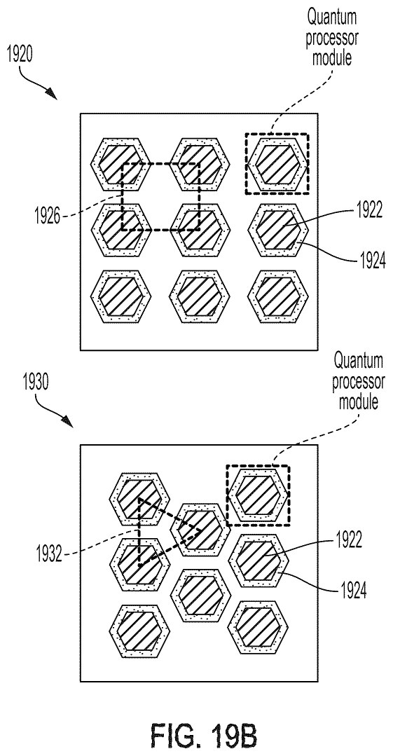

FIG. 9A is a flow chart showing aspects of an example fabrication process 900 of assembling a modular quantum processing unit with a single cap wafer for multiple quantum processor chips. The example process 900 is used to assemble a modular quantum processing unit 910. At 901, a cap wafer 904 and a multiplicity of quantum processor chips 902 are provided. In some implementations, the cap wafer 904 may be implemented as the example cap wafer 212, 304, 324, 404, 500, 604, 634, 674, or 718; and the quantum processor chips 902 may be implemented as the example device wafers 202, 302A, 302B, 302C, 322A, 322B, 322C, 322D, 402, 602, 632, 672, or 730 as shown in FIGS. 2, 3A-3B, 4A-4B, 5, 6A-6C, or 7A-7C. In some instances, all the quantum processor chips 902 do not need to be the same size or same shape, and a quantum processing unit can include quantum processor chips having distinct properties (e.g., distinct sizes, shapes, etc.). The quantum processor chips 902 in the modular quantum processing unit 910 may include one or more quantum processor chips that are square (e.g., the quantum processor chip 1902 in FIG. 19A), rectangular (e.g., the quantum processor chip 1906 in FIG. 19A), hexagonal (e.g., the quantum processor chip 1912 in FIG. 19A), trapezoidal, circular, elliptical, or another shape. In some cases, the shapes of the quantum processing chips are designed or otherwise selected based on what is convenient to process, for example, according to the crystalline orientation of the substrates. In some instances, the quantum processor chip 902 may be arranged in a square lattice (e.g., the square lattice 1926 in FIG. 19B), a triangular lattice (e.g., the triangular lattice 1932 in FIG. 19B), or another shape of lattice. In some instances, the quantum processor chips 902 may be unevenly spaced, distributed, or oriented on the cap wafer 904. For example, the spatial positioning, orientation and density of the quantum processor chips can be regular or irregular (e.g., random). The cap wafer 904 can be designed according to the arrangement of the quantum processor chips 902 on the surface of the cap wafer 904.

At 903, one quantum processor chip 902 is bonded at a time to the cap wafer 904. In some instances, prior to the bonding of the quantum processor chips 902 to the cap wafer 904, each of the quantum processor chips 902 are characterized in a characterization process and selected according to results of the characterization process. At the end of operation 903, all the selected quantum processor chips 902 are bonded to the cap wafer 904 to form the modular quantum processing unit 910.

FIG. 9B is a schematic diagram showing aspects of the example modular quantum processing unit 910 assembled according to the example process 900 in FIG. 9A. The example modular quantum processing unit 910 as shown in FIGS. 9A-9B includes multiple quantum processor chips 902 bonded to a common cap wafer 904. The cap wafer 904 includes inter-chip coupler devices 906 that are configured to provide inter-chip coupling between quantum processor chips 902. The example modular quantum processing unit 910 includes 16 quantum processor chips 902. Each of the quantum processor chips 902 are bonded to a cap wafer 904 so that certain quantum circuit devices on the quantum processor chips 902 can be interconnected by inter-chip coupler devices 906 on the cap wafer 904.

Each of the quantum processor chips 902 includes a superconducting quantum integrated circuit (QuIC). The superconducting QuIC can include quantum circuit devices, for example, qubit devices 912 (e.g., transmon devices, fluxonium devices, or other types of superconducting qubit devices), coupler devices 914 (e.g., capacitive coupler device, tunable-frequency coupler device, or others), readout devices, or other types of quantum circuit devices that are used for quantum information processing in the modular quantum processing unit 910. The superconducting QuIC of each of the quantum processor chips 902 may include one or more Josephson junctions, capacitors, inductors, and other types of circuit elements. In some implementations, the example modular quantum processing unit 910 may include additional and different features or components, and components of the example modular quantum processing unit 910 may be implemented in another manner.

As shown in the example modular quantum processing unit 910, each of the quantum processor chips 902 includes a substrate. The substrate supports the superconducting QuIC of the quantum processor chip 902. In certain examples, the cap wafer 904 includes a substrate which supports the inter-chip coupler devices 906 and other superconducting circuit elements of the cap wafer 904 (e.g., through-silicon vias, control lines, etc.). In some implementations, the example modular quantum processing unit 910 may include more than two quantum processor chips 902 on multiple dies/substrates bonded to the cap wafer 904.

In some implementations, the substrates of the quantum processor chips 902 and the cap wafer 904 may include a dielectric substrate (e.g., silicon, sapphire, etc.). In certain examples, the substrates may include an elemental semiconductor material such as, for example, silicon (Si), germanium (Ge), selenium (Se), tellurium (Te), or another elemental semiconductor. In some instances, the substrates may also include a compound semiconductor such as silicon germanium (SiGe), silicon carbide (SiC), silicon germanium carbide (SiGeC), aluminum oxide (sapphire), gallium arsenide (GaAs), indium arsenide (InAs), indium phosphide (InP), gallium arsenic phosphide (GaAsP), or gallium indium phosphide (GaInP). In some instances, the substrates may also include a superlattice with elemental or compound semiconductor layers. In some instances, the substrates include an epitaxial layer. In some examples, the substrates may have an epitaxial layer overlying a bulk semiconductor or may include a semiconductor-on-insulator (SOI) structure. In some instances, the substrates may comprise low dielectric constant materials, such as silicon oxides including fused silica and crystalline quartz.

The superconducting QuIC on each of the quantum processor chips 902 and the superconducting circuitry on the cap wafer 904 includes superconducting materials. In some implementations, the superconducting materials may be superconducting metals, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example modular quantum processing unit 910, or another superconducting metal. In some implementations, the superconducting materials may include superconducting metal alloys, such as molybdenum-rhenium (Mo/Re), niobium-tin (Nb/Sn), or another superconducting metal alloy. In some implementations, the superconducting materials may include superconducting compound materials, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting materials may include multilayer superconductor-insulator heterostructures.

In some implementations, the superconducting QuIC on each of the quantum processor chips 902 and the superconducting circuitry on the cap wafer 904 (e.g., the inter-chip coupler devices 906) can be formed on surfaces of the substrates and patterned using a microfabrication process or in another manner. For example, the superconducting QuIC on each of the quantum processor chips 902 and the superconducting circuitry (including the inter-chip coupler devices 906) on the cap wafer 904 may be formed by performing at least some of the following fabrication processes: using chemical vapor deposition (CVD), physical vapor deposition (PVD), atomic layer deposition (ALD), and/or other suitable techniques to deposit respective superconducting layers on the substrates; and performing one or more patterning processes (e.g., a lithography process, a dry/wet etching process, a soft/hard baking process, a cleaning process, etc.) to form openings in the respective superconducting layers.

In the example shown in FIG. 9B, the qubit devices 912 in the superconducting QuIC of the quantum processor chips 902 may be arranged in a rectilinear (e.g., rectangular, or square) array that extends in two spatial dimensions (e.g., in the plane of the page). In some implementations, the qubit devices 912 can be arranged in another type of ordered array. In some instances, the rectilinear array of quantum processor chips also extends in a third spatial dimension (e.g., in/out of the page), for example, to form a cubic array or another type of three-dimensional array. In some instances, multiple modular quantum processing units 910 may be bonded or otherwise assembled to form a three-dimensional modular quantum processing unit.

Each of the quantum processor chips 902 of the example modular quantum processing unit 910 includes one or more qubit devices 912. In some examples, the qubit frequency of a qubit device is not tunable by application of an offset field and is independent of magnetic flux experienced by the qubit device. For instance, a fixed-frequency qubit device may have a fixed qubit frequency that is defined by an electronic circuit of the qubit device. As an example, a superconducting fixed-frequency qubit device (e.g., a fixed-frequency transmon qubit device) may be implemented without a SQUID (Superconducting Quantum Interface Device) loop. In some examples, the qubit frequency of a qubit device 912 in a superconducting QuIC of a quantum processor chip 902 is tunable, for example, by application of an offset field. For instance, a superconducting tunable-frequency qubit device may include a superconducting loop (e.g., a SQUID loop), which can receive a magnetic flux that tunes the qubit frequency of the tunable-frequency qubit device. In this case, the cap wafer 904 of the quantum process modules 902 may include flux bias control lines 926 for tuning the magnetic flux through the SQUID loops of the qubit devices 912. In some instances, the superconducting QuIC of the quantum process modules 902 includes drive signal lines that are configured to communicate microwave control signals to the qubit devices 912. The superconducting QuIC of the quantum processor chips 902 may include additional devices, including additional qubit devices, readout resonators, or other quantum circuit devices.

In some instances, the coupler devices 914 in the quantum processor chips may include tunable-frequency coupler devices. In some implementations, a tunable-frequency coupler device 914 resides between two neighboring qubit devices 912 and controls the interaction between the two qubit devices 912. Each of the tunable-frequency coupler devices 914 may be implemented as a tunable-frequency transmon qubit device or another type of tunable-frequency qubit device. In this case, the control lines include coupler flux control lines that can communicate control signals to the tunable-frequency coupler device and tune the flux bias in order to tune the operating frequency of the tunable-frequency coupler devices and thus the coupling between two qubit devices 912. In some implementations, a control signal can be a direct current (DC) signal communicated, for example, from the control system to the individual tunable-frequency coupler device on a quantum processor chip 902. In some implementations, a control signal can be an alternating current (AC) signal communicated to the individual tunable-frequency coupler device. In some cases, the AC signal may be superposed with a direct current (DC) signal. Other types of control signals may be used.

As shown in FIG. 9B, the inter-chip coupler device 906 is configured to provide inter-chip coupling between quantum circuit devices on distinct quantum processor chips 902. In some implementations, each of the inter-chip coupler devices 906 includes a planar microwave transmission line 932, for example coplanar waveguides, substrate integrated waveguides, or another type of planar transmission line structure. Connections between the inter-chip coupler device 906 and quantum circuit devices can be galvanic, for example through superconductive contacts (e.g., indium bumps 934 and contact electrodes 936) or capacitive through parallel capacitor electrodes. Thus, the inter-chip coupler devices 906 are galvanically or capacitively coupled to the quantum processor chips 902 allowing microwave signals to propagate between the two quantum processor chips 902. In some examples, the inter-chip coupler devices 906 include a quantum bus architecture, which can be used to selectively provide inter-module coupling between different qubit devices on different quantum processor chips.

In some implementations, the cap wafer 904 is bonded to the quantum processor chips 902 through superconductive contacts or other types of bonding bumps 924. In some implementations, a cap wafer 904 further includes through-hole conductive vias 922 that connect top and bottom surfaces of the cap wafer 904. In some implementations, the through-hole conductive vias 922 include a material (e.g., Al, In, Ti, Pn, Sn, etc.) that is superconducting at an operating temperature of the example modular quantum processing unit 910. In some implementations, each of the bonding bumps 924 may include conductive or superconductive materials, such as copper or indium bumps. In some implementations, the bonding bumps 924 can provide electrical communication of the superconducting QuIC of the quantum processor chips 902 with the superconducting circuitry on the cap wafer 904. The gap separating the cap wafer 904 and the quantum processor chips 902 is determined by the height of the bonding bumps 924. In some instances, superconducting bonding bumps can be selectively structured between the surface of the cap wafer 904 and the surface of the quantum processor chips 902 to segment the ground plane. Segments of the ground plane, which, for example, can be kept at an equipotential, can control the flow of supercurrent to prevent flux currents from intermingling.

In some instances, the cap wafer 904 may also include other circuit elements. For example, the cap wafer 904 may include resonator devices which are capacitively coupled to qubit devices 912 to readout qubits. In some examples, the cap wafer 904 may include microwave feedlines which are coupled to one or several of the resonator devices to allow microwave excitation of the resonator devices used to readout qubits of qubit devices. The cap wafer 904 may further include filters, isolators, circulators, amplifiers, or other circuit elements. In some instances, through-hole vias 922 can be used as a part of control lines to transmit control signals received from one side of the cap wafer 904 to the other side that faces the quantum processor chips 902.

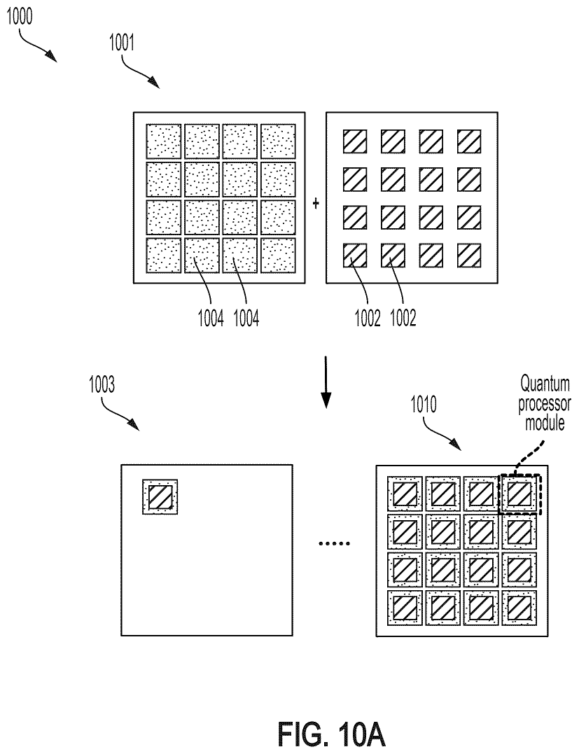

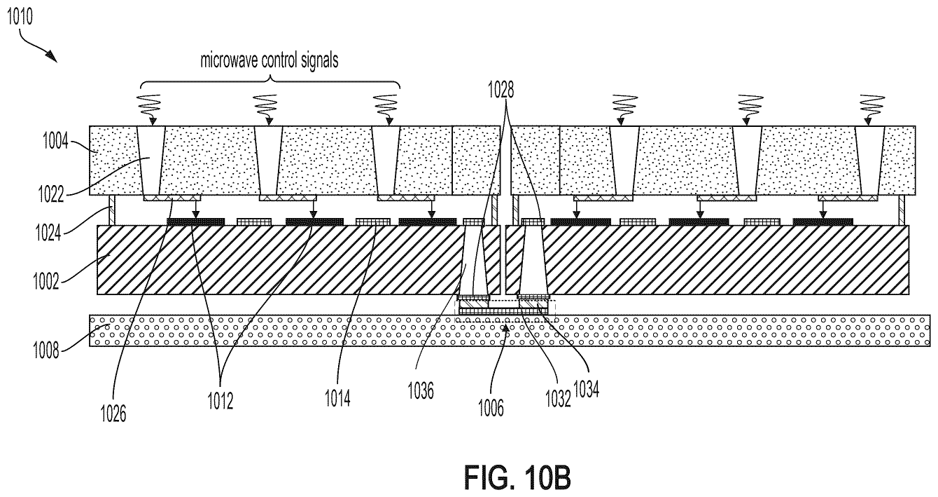

FIG. 10A is a flow chart showing aspects of an example fabrication process 1000 of assembling a modular quantum processing unit with one cap wafer for each of quantum processor chips. The example process 1000 is used for assembling a modular quantum processing unit 1010. At 1001, a multiplicity of cap wafers 1004 and a corresponding multiplicity of quantum processor chips 1002 are provided. In some implementations, the cap wafer 1004 may be implemented as the example cap wafer 212, 304, 324, 404, 500, 604, 634, 674, 718, 904; and the quantum processor chips 1002 may be implemented as the example device wafers 202, 302A, 302B, 302C, 322A, 322B, 322C, 322D, 402, 602, 632, 672, 730, 902 as shown in FIGS. 2, 3A-3B, 4A-4B, 5, 6A-6C, 7A-7C, or 9A-9B. The quantum processor chips 1002 in the modular quantum processing unit 1010 may include quantum processor chips that are square (e.g., the quantum processor chip 1902 in FIG. 19A), rectangular (e.g., the quantum processor chip 1906 in FIG. 19A), hexagonal (e.g., the quantum processor chip 1912 in FIG. 19A), or another shape. In some cases, the shapes of the quantum processing chips are designed or otherwise selected based on what is convenient to process, for example, according to the crystalline orientation of the substrates. In some instances, the example cap wafer 1004 may have the same shape as the respective quantum processor chips 1002. In certain instances, the example cap wafer 1004 may have a shape different from the shape of the respective quantum processor chip 1002. In some instances, the quantum processor modules 1010 may be arranged in a square lattice (e.g., the square lattice 1926 in FIG. 19B), a triangular lattice (e.g., the triangular lattice 1932 in FIG. 19B), or another shape of lattice.

At 1003, one quantum processor chip 1002 is bonded at a time to its corresponding cap wafer 1004 to form a quantum processor module. At the end of operation 1003, all the quantum processor chips 1002 are bonded to the corresponding cap wafers 1004; and a multiplicity of quantum processor modules is formed. In some implementations, all the quantum processor modules are bonded together on a module integration plate 1008 which provides inter-chip couplings between the quantum processor chips 1002 in the quantum processor modules.

FIG. 10B is a schematic diagram showing aspects of the example modular quantum processing unit 1010 assembled according to the example process 1000. The example modular quantum processing unit 1010 includes quantum processor chips 1002 bonded to corresponding cap wafer 1004. As shown in the example modular quantum processing unit 1010, each quantum processor chip 1002 is bonded to a corresponding cap wafer 1004. In other words, each cap wafer 1004 supports only one quantum processor chip 1002. Each pair of quantum processor chip 1002 and cap wafer 1004 forms a quantum processor module. Quantum processor modules are bonded to a separate module integration plate 1008 that includes inter-module coupler devices 1006 for providing inter-chip coupling between different quantum processor chips in distinct quantum processor modules. The cap wafer 1004 may be implemented as the cap wafer 904 as shown in FIGS. 9A-9B; and the quantum processor chips 1002 are implemented as the quantum processor chips 902 as shown in FIGS. 9A-9B. The inter-module coupler device 1006 may be galvanically connected to the superconducting circuitry on the quantum processor chip 1002. The module integration plate 1008 may include other superconducting circuit elements that can provide inter-chip coupling between non-neighboring quantum processor chips or quantum processor chips on non-neighboring cap wafers.

As shown in FIG. 10B, the inter-module coupler device 1006 is configured to provide inter-module coupling between quantum processor chips 1002 on distinct quantum processor modules. In some implementations, the inter-module coupler device 1006 includes a planar microwave transmission line 1032, for example coplanar waveguides, substrate integrated waveguides, or another type of planar transmission line structure. Connections between the inter-module coupler device 1006 and quantum circuit devices can be galvanic, for example through superconductive contacts (e.g., indium bumps 1034 and contact electrodes 1036) or capacitive through parallel capacitor electrodes. Thus, the inter-module coupler device 1006 is galvanically or capacitively coupled to the quantum processor chips 1002 allowing microwave signals to propagate between the two quantum processor chips 1002 from distinct quantum processor modules. In some examples, the inter-module coupler device 1006 may include a quantum bus architecture, which can be used to selectively provide inter-module coupling between quantum processor chips on different quantum processor modules. In some implementations, the inter-module coupler device 1006 is implemented as the inter-chip coupler device 906 described above with reference to FIGS. 9A-9B or in another manner.

As shown in FIG. 10B, the superconducting QuIC with the qubit devices 1012 and the coupler devices 1014 reside on a first surface of the quantum processor chips 1002. The superconducting QuIC is galvanically connected to the inter-module coupler device 1006 on a second, opposite surface of the quantum processor chips 1002 via contact electrodes 1036 and through-hole conductive vias 1028. In some instances, the through-hole conductive vias 1022, 1028, the bonding bumps 1024, the contact electrodes 1036, the control lines 1026, the qubit devices 1012 and the coupler devices 1014 are implemented as the through-hole conductive vias 922, the bonding bumps 924, the contact electrodes 936, the control lines 926, the qubit devices 912 and the coupler devices 914 as shown in FIGS. 9A-9B, or in another manner.

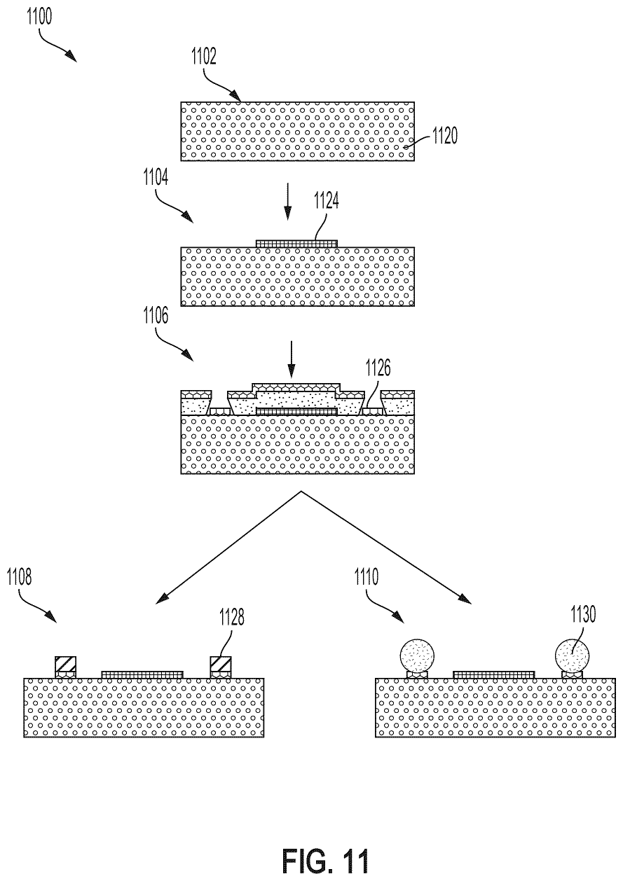

FIG. 11 is a flow chart showing aspects of an example manufacturing process 1100 of inter-module coupler devices on a module integration plate. The example process 1100 is used to fabricate inter-module coupler devices on a module integration plate (e.g., the inter-module coupler device 1006 on the module integration plate 1008 in the example modular quantum processing unit 1010 in FIG. 10B). The example process 1100 may include additional or different operations, including operations to fabricate additional or different components, and the operations may be performed in the order shown or in another order. In some cases, operations in the example process 1100 can be combined, iterated or otherwise repeated, or performed in another manner. As shown in FIG. 11, different structures can be produced according to different paths through the flow chart, and a path may include only a subset of the operations shown in FIG. 11. Accordingly, an instance of the process 1100 does not generally include all operations shown in FIG. 11.

In some implementations, inter-module coupler devices are fabricated on a silicon wafer or a PCB single redistribution layer (RDL) device with solder bumps or balls in order to accommodate quantum processor modules. A single-layer RDL includes a superconductive material and patterned to serve as an inter-module coupler device with a line-space resolution quite typical for silicon device optical lithography or PCB technology. Solder elements are made of superconductive metal or alloy compatible with pads on a backside of the quantum processor chips for providing a reliable and superconductive permanent joint contact between a module integration plate and the quantum processor module. Temperature hierarchy of substrate soldering must be respected such that the quantum processor module integrity is maintained by keeping the module integration plate to the quantum processor modules temperature to not exceed the quantum processor chip to the cap wafer packaging solder melting point temperature.

At 1102, a substrate is cleaned. The substrate 1120 can be a crystalline silicon substrate or another type of dielectric substrate. In some instances, the substrate 1120 may be a single crystal silicon wafer with intrinsic doping concentration or another doping concentration. In some instances, the single crystal silicon wafer may have an orientation in {100}, {110}, {111}, or another orientation. In some instances, the substrate 1120 may be implemented as the substrate 203, 213 in FIG. 2 or in another manner. In some instances, the substrate 1120 may be a PCB substrate.

At 1104, a superconducting structure is formed on the substrate. The superconducting structure 1124 includes a superconducting material. In some instances, the superconducting material may include a superconducting metal, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example quantum processing unit 200, or another superconducting metal. In some implementations, the superconducting material may include a superconducting metal alloy, such as molybdenum-rhenium (Mo/Re), niobium-tin (Nb/Sn), or another superconducting metal alloy. In some implementations, the superconducting material may include superconducting compound material, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting material may include multilayer superconductor-insulator heterostructures.

In some instances, the superconducting structure 1124 may be formed on the surface of the substrate 1120 by performing at least some of the following processing steps: using chemical vapor deposition (CVD), physical vapor deposition (PVD), atomic layer deposition (ALD), spin-on coating, and/or other suitable techniques; and performing one or more patterning processes (e.g., a lithography process, a dry/wet etching process, a soft/hard baking process, a cleaning process, etc.).

At 1106, an under-bump superconductive structure is formed. In some instances, the under-bump superconductive structure 1126 may be formed on the surface of the substrate 1120 by performing at least some of the following processing steps: using chemical vapor deposition (CVD), physical vapor deposition (PVD), atomic layer deposition (ALD), spin-on coating, and/or other suitable techniques; and performing one or more patterning processes (e.g., a lithography process, a dry/wet etching process, a soft/hard baking process, a cleaning process, etc.). In some instances, the under-bump superconductive structure includes a superconducting material, e.g., Mo/Re alloy.

Once the under-bump superconductive structures are formed, the example process 1100 continues with operation 1108 to form bumps or posts 1128 or operation 1110 to form solder balls 1130 over the under-bump superconductive structure. In some instances, the bumps, posts 1128 or the solder balls 1130 are fabricated by one or more of the following processes: placement, vacuum deposition and liftoff, electro or electroless plating through the mask, or another process.

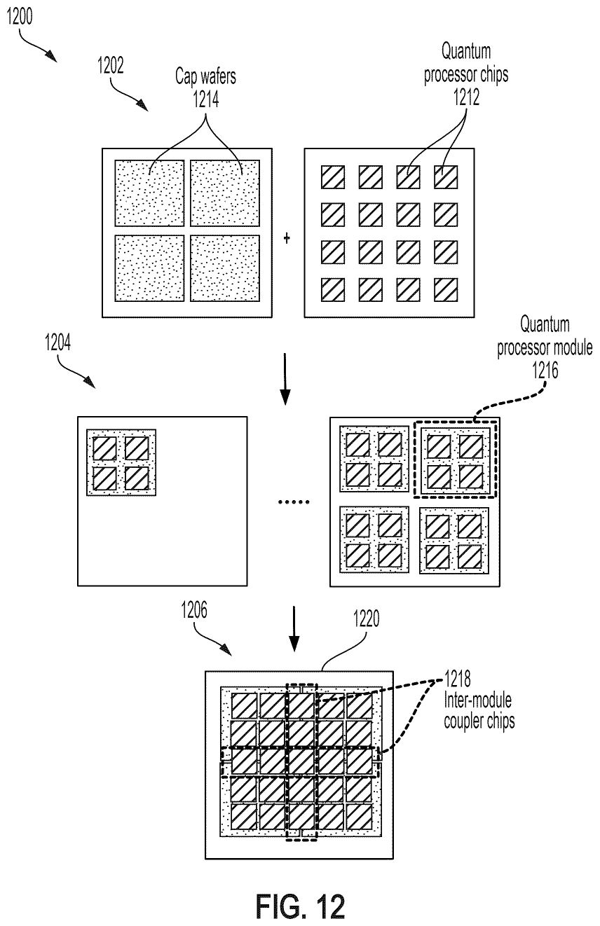

FIG. 12 is a flow chart showing aspects of an example fabrication process 1200 of assembling a modular quantum processing unit. As shown in FIG. 12, the example modular quantum processing unit 12220 includes an array of quantum processor chips 1212 and an array of cap wafers 1214. In some implementations, each of the cap wafers 1214 may be implemented as the example cap wafer 212, 304, 324, 404, 500, 604, 634, 674, 718, 904, 1004; and each of the quantum processor chips 1212 may be implemented as the example device wafers 202, 302A, 302B, 302C, 322A, 322B, 322C, 322D, 402, 602, 632, 672, 730, 902, 1002 as shown in FIGS. 2, 3A-3B, 4A-4B, 5, 6A-6C, 7A-7C, 9A-9B or 10A-10C.

In some instances, the quantum processor chips 1212 in the modular quantum processing unit 1220 may be square (e.g., the quantum processor chip 1902 in FIG. 19A), rectangular (e.g., the quantum processor chip 1906 in FIG. 19A), hexagonal (e.g., the quantum processor chip 1912 in FIG. 19A), or another shape. In some instances, the example cap wafer 1214 may have the same shape as the respective quantum processor chips 1212. In certain instances, the example cap wafer 1214 may have a shape different from the shape of the respective quantum processor chip 1212. In some instances, the quantum processor modules 1220 may be arranged in a square lattice (e.g., the square lattice 1926 in FIG. 19B), a triangular lattice (e.g., the triangular lattice 1932 in FIG. 19B), or another shape of lattice.

The example process 1200 is used for fabricating a modular quantum processing unit 1220. The modular quantum processing unit 1200 includes multiple quantum processor chips 1212; and each of the quantum processor chips includes a superconducting quantum integrated circuit with superconducting circuitry and quantum circuit devices. The modular quantum processing unit 1220 includes multiple cap wafers 1214. Each cap wafer 1214 is bonded to multiple quantum processor chips 1212, forming a quantum processor module 1216. The quantum processor modules 1216 are assembled on to a substrate, where the cap wafers 1214 are facing the substrate. The quantum processor modules 1216 can be organized on the substrate in an array. In some implementations, the quantum processor modules 1216 can be communicably coupled to each other through inter-module coupler chips 1218. In some implementations, the inter-module coupler chips 1218 function only to couple quantum processor chips 1212 from neighboring quantum processor modules 1216. In other embodiments, the inter-module coupler chips 1218 may function to both couple quantum processor chips 1212 from neighboring quantum processor modules 1216 and to provide quantum processing capabilities. Each of the inter-module coupler chips 1218 may include one or more inter-module coupler devices that are communicably coupled to the cap wafers 1214. In some instances, the inter-module coupler chip 1218 may be implemented as the quantum processor chip 1212. In some instances, the inter-module coupler chip 1218 may include superconducting circuitry with different design from that of the quantum processor chip 1212. In some instances, the inter-module coupler chip 1218 may reside at the edges of neighboring cap wafers 1214 for coupling quantum processor chips 1212 from two or more quantum processor modules 1216.

As shown in FIG. 12, a modular quantum processing unit 1220 includes 16 quantum processor chips in a 4×4 array with each of the four cap wafers 1214 bonded to four quantum processor chips 1212 forming four quantum processor modules 1216. In some instances, four quantum processor modules 1216 in a modular quantum processing unit 1220 may include different numbers of cap wafers 1214 or the same number of quantum processor chips 1212. For example, the 16 quantum processor chips 1212 may be bonded to three cap wafers including two cap wafers bonded to four quantum processor chips and one cap wafer bonded to eight quantum processor chips. The cap wafers 1214 do not need to be square, they may be rectangular (e.g., the cap wafer 324 in FIG. 3B), or can have a more complex shape, such as L-shape, etc.

In some implementations, a modular quantum processing unit 1220 may include a first multiplicity of cap wafers 1214 bonded to a second multiplicity of quantum processor chips 1212, where the first multiplicity is less than the second multiplicity. Each cap wafer 1214 is bonded to more than one quantum processor chips 1212. Each quantum processor chip 1212 may be bonded to one or more cap wafers 1214. Furthermore, all the cap wafers 1214 do not need to be the same size, the same shape, and/or all the quantum processor chips 1212 do not need to be the same size. The cap wafers 1214 may be square, rectangular, or any other shape that is convenient for the task of forming recesses and waveguides for the quantum circuit devices and superconducting circuitry on the quantum processor chips 1212, communicating control signals into or readout signals out of the quantum processor chips 1212, and providing inter-chip coupling as required.

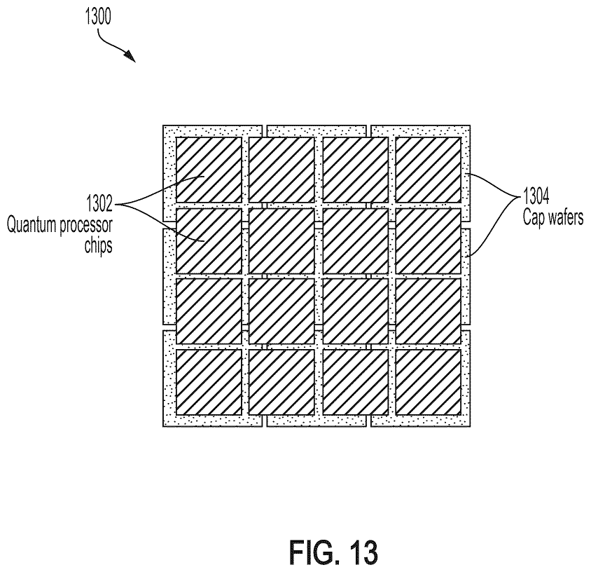

FIG. 13 is a schematic diagram showing aspects of an example modular quantum processing unit 1300. As shown in FIG. 13, the example modular quantum processing unit 1300 includes an array of quantum processor chips 1302 and an array of cap wafers 1304. In some implementations, each of the cap wafers 1304 may be implemented as the example cap wafer 212, 304, 324, 404, 500, 604, 634, 674, 718, 904, 1004, 1214; and each of the quantum processor chips 1302 may be implemented as the example device wafers 202, 302A, 302B, 302C, 322A, 322B, 322C, 322D, 402, 602, 632, 672, 730, 902, 1002, 1212 as shown in FIGS. 2, 3A-3B, 4A-4B, 5, 6A-6C, 7A-7C, 9A-9B, 10A-10B, or 12. In some instances, the array of quantum processor chips 1302 includes a first number of quantum processor chips 1302; and the array of cap wafers 1304 includes a second number of cap wafers 1304. In some implementations, the first number is greater than the second number. For example, as shown in FIG. 13, a 4×4 array of quantum processor chips 1302 are bonded to a 3×3 array of cap wafers 1304. 8 quantum processor chips 1302 that include inter-module coupler devices are bonded to more than one cap wafer 1304. In some instances, the quantum processor chips 1302 are bonded to two or more neighboring cap wafers 1304 which may include both quantum circuit devices, which provide quantum processing capabilities, and inter-module coupler devices. In certain instances, the cap wafer 1304 are bonded to two or more quantum processor chips 1302 which may also include inter-module coupler devices.

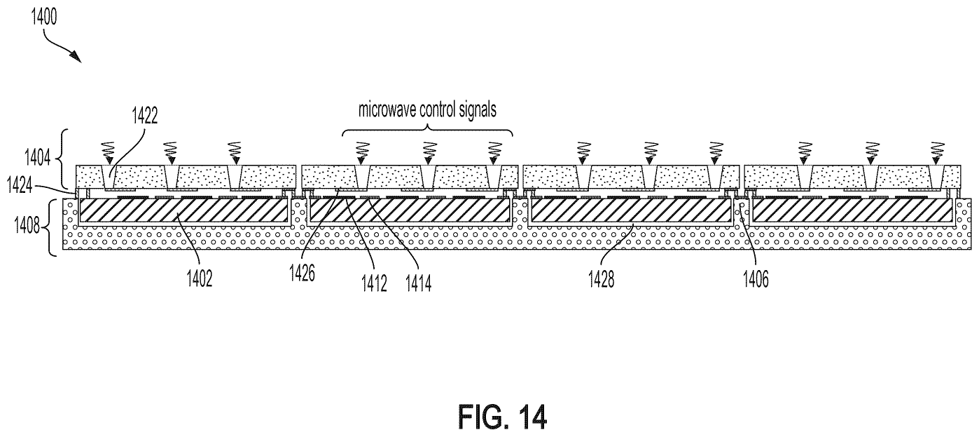

FIG. 14 is a schematic diagram showing aspects of an example modular quantum processing unit 1400. As shown in FIG. 14, the example modular quantum processing unit 1400 includes multiple quantum processor modules and a module integration plate 1408. Each quantum processor module includes a pair of a quantum processor chip 1402 and a cap wafer 1404 and is bonded to the module integration plate 1408. A quantum processing unit 1400 may include additional or different features, and the components of a computing environment may operate as described with respect to FIG. 1 or in another manner.

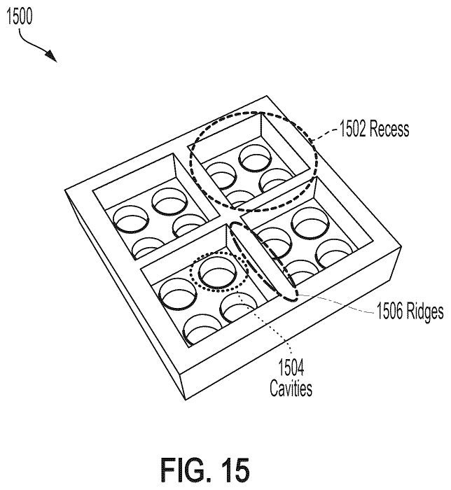

In some implementations, the module integration plate 1408 (e.g., waffle-shape carrier for quantum processor modules, or “waffle” carrier) includes recesses 1428 that house respective quantum processor chips 1402 of a quantum processor module. In some instances, the module integration plate 1408 may include multiple recessed surfaces with different depths and shapes (e.g., as shown in the example module integration plate 1500 in FIG. 15) for housing respective quantum processor chips and cap wafers. The recesses 1428 on the module integration plate 1408 may have different shapes and depths. Furthermore, all the recesses 1428 do not need to be the same size. In some implementations, the recesses 1428 on the module integration plate 1408 are configured according to the configurations of the quantum processor chips 1402, the cap wafers 1404 and the quantum processor modules. In some instances, the module integration plate 1408 has a monolithic structure configured for housing all quantum processor chips 1402 in the example quantum processing unit 1400. In some instances, the example modular quantum processing unit 1400 may include multiple module integration plates 1408; and each module integration plate 1408 is configured for housing a subset of the quantum processor chips 1402. The multiple module integration plates 1408 may be interconnected, supported, or otherwise integrated by a common plate or in another manner. In some implementations, the modular quantum processor 1400 includes multiple module integration plates 1408. Each of the module integration plates 1408 may bond to one or more quantum processor modules. In some implementations, the cap wafer 1404 and the quantum processor chips 1402 are implemented as the cap wafers 1004; and the quantum processor chips are implemented as the quantum processor chips 1002 in FIGS. 10A-10B. In some implementations, the module integration plate 1408 may be implemented as the module integration plate 1700 shown in FIG. 17 or in another manner.

As shown in FIG. 14, the example quantum processing unit 1400 includes inter-module coupler devices 1406 which allow electrical coupling between the module integration plate 1408 to the cap wafers 1404. In this case, inter-chip couplings between two quantum processor chips 1402 in the example quantum processing unit are through respective cap wafers 1404, the module integration plate 1408, and respective inter-chip coupler devices 1406.

In some implementations, the inter-module coupler devices 1406 are implemented as the inter-chip coupler devices 906 described above with reference to FIGS. 9A-9B. Each of the cap wafer 1404 includes through-hole conductive vias 1422, bonding bumps 1424, and control lines 1426; the quantum processor chip 1402 includes qubit devices 1412 and coupler devices 1414. In some instances, the through-hole conductive vias 1422, the bonding bumps 1424, the control lines 1426, the qubit devices 1412 and the coupler devices 1414 are implemented as the through-hole conductive vias 922, the bonding bumps 924, the control lines 926, the qubit devices 912 and the coupler devices 914 as shown in FIGS. 9A-9B, or in another manner.

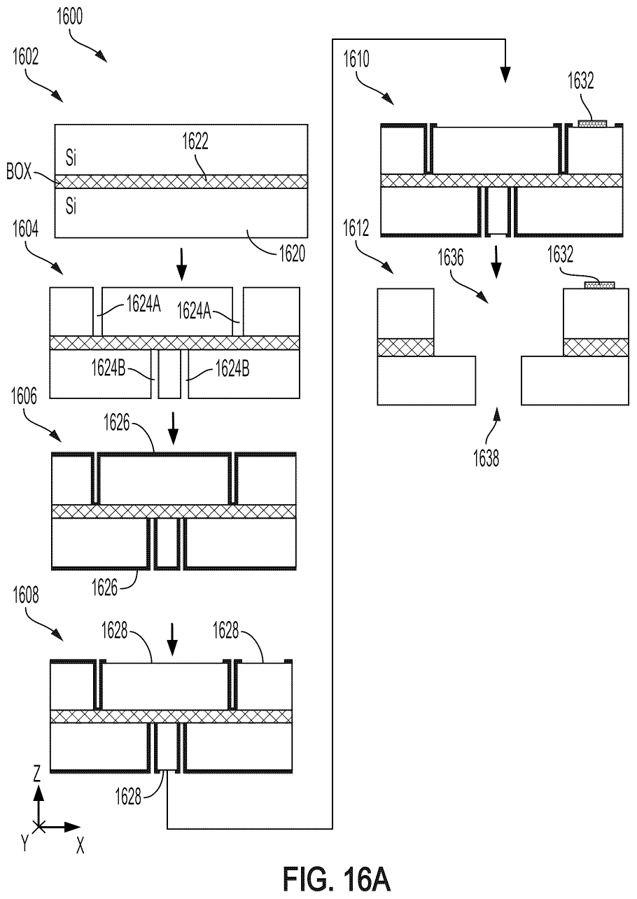

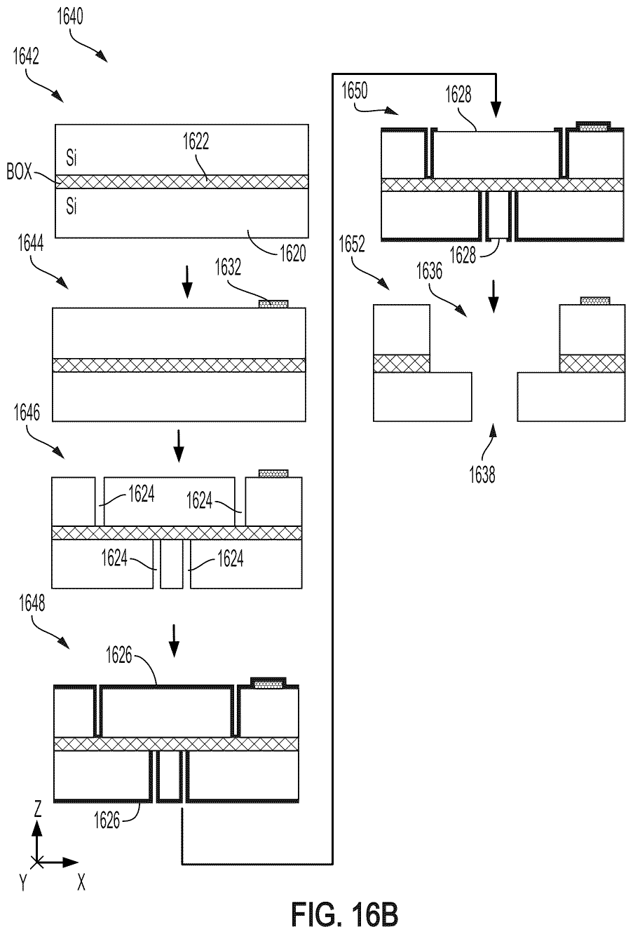

FIG. 15 is a schematic diagram showing a perspective view of an example module integration plate 1500. As shown in FIG. 15, the module integration plate 1500 includes multiple recesses 1502 and each of the recesses 1502 includes multiple cavities 1504. Each of the recesses 1502 resides on a first surface 1510 of the module integration plate 1500 and extends to a recessed surface 1512 at a depth from the first surface 1510. Each of the cavities 1504 resides on a recessed surface 1512 of a recess 1502 and extends to a second, opposite surface 1514 of the module integration plate 1500. In some implementations, a recess 1502 can house a quantum processor chip in a quantum processor module; and a cavity 1504 may be configured to mate with a thermalization structure (e.g., metal pillars) for dissipating heat generate by a quantum processor chip housed in a respective recess 1502. Areas between neighboring recesses 1502 define ridges 1506 on the first surface 1510 of the module integration plate 1500. In some instances, inter-module coupler devices (e.g., the inter-module coupler devices 1406 in FIG. 14) reside on the first surface at the ridges 1506 for coupling quantum processor chips (e.g., the quantum processor chips 1402 in FIG. 14) that are housed in distinct recesses 1504. In some instances, the module integration plate 1500 may include other superconducting circuitry that can carry signals at other surfaces (e.g., the second surface 1514 of the module integration plate 1500). In some instances, the module integration plate 1500 may be fabricated according to operations in the example processes 1600, 1640 shown in FIGS. 16A-16B, or in another manner.

FIG. 16A is a flow chart showing aspects of an example process 1600 of manufacturing a module integration plate. In some implementations, the example process 1600 is used for fabricating a module integration plate (e.g., the module integration plates 1408, 1500, 1700 as shown in FIGS. 14, 15, and 17), which includes recesses, through-hole vias, cavities, and contacts of inter-module coupler devices. The example process 1600 may include additional or different operations, including operations to fabricate additional or different components, and the operations may be performed in the order shown or in another order. In some cases, operations in the example process 1600 can be combined, iterated or otherwise repeated, or performed in another manner. As shown in FIG. 16A, different structures can be produced according to different paths through the flow chart, and a path may include only a subset of the operations shown in FIG. 16A. Accordingly, an instance of the process 1600 does not generally include all operations shown in FIG. 16A.

At 1602, a substrate is prepared. The substrate 1620 can be a crystalline silicon substrate or another type of dielectric substrate. In some instances, the substrate 1620 may be a single crystal silicon wafer with intrinsic doping concentration or another doping concentration. In some instances, the single crystal silicon wafer may have an orientation in {100}, {110}, {111}, or another orientation. In some instances, a surface of the substrate 1620, e.g., a polished surface, may be etched and cleaned to remove a native oxide layer, particles or organic contaminants. For example, the substrate 1620 can be etched in a buffered oxide etchant (BOE) containing an aqueous solution of ammonium fluoride and hydrofluoric acid, thoroughly rinsed with deionized (DI) water, and dried with a flow of nitrogen. In some instances, the substrate 1620 may be cleaned using different chemical solutions in another cleaning process.

In some implementations, the substrate 1620 includes a buried oxide layer 1622. In some instances, a buried oxide layer 1622 is a buried layer of silicon oxide in the substrate 1620. A buried oxide layer 1622 can be formed by directly introducing oxygen ions underneath the surface of the silicon substrate using an ion implantation process. In this case, the energy and dose of the oxygen ions can be determined according to the range and the profile of the implanted layer. In some other instances, after the ion implementation process, the substrate 1620 can be annealed to remove the degradation to the crystalline silicon layer caused by the implanted oxygen ions. In some instances, the buried oxide layer 1622 can be formed using another process. For example, the substrate 1620 with a buried oxide layer 1622 can be formed using a bonding and etch-back process. For example, two substrates can be cleaned and bonded by sandwiching a silicon oxide layer between two silicon wafers followed by thinning one substrate down to a desired thickness.

At 1604, trenches are formed in the substrate. As shown in FIG. 16A, the trenches 1624A, 1624B are formed on both surfaces of the substrate 1620. In some instances, each of the trenches 1624A, 1624B extends along the Z-direction and has a bottom terminated at the buried oxide layer 1622. In some implementations, depths of the trenches 1624A, 1624B in the Z-direction are defined by the thickness of each of the silicon layers on each side of the buried oxide layer 1622 in the substrate 1620. In some implementations, the trenches 1624A, 1624B also extend in the X-Y plane to define boundaries of recesses and through-hole vias. In particular, the trenches 1624A in the substrate 1620 on one side of the buried oxide layer 1622 define locations of sidewalls of the recesses in the substrate 1620; and the trenches 1624B in the substrate 1620 on the other side of the buried oxide layer 1622 define locations of sidewalls of the through-hole vias in the substrate 1620. In some instances, the trenches 1624A, 1624B may be formed on the substrate 1620 by performing at least some of the following processing steps on each side of the substrate 1620: performing one or more patterning processes (e.g., a lithography process, a dry/wet etching process, a soft/hard baking process, a cleaning process, etc.); and performing a wet/dry etching process.

At 1606, an oxidation layer is formed on the substrate. In some implementations, an oxidation layer 1626 is formed conformally on both of the surfaces of the substrate 1620 and sidewalls of the trenches 1624. In some instances, the oxidation layer 1626 can be formed by performing a thermal oxidation process, an atomic layer deposition (ALD) process, a chemical vapor deposition (CVD) process, a physical vapor deposition (PVD) process, or another process.

At 1608, the oxidation layer on the substrate is patterned. As shown in FIG. 16A, the oxide layer 1626 is patterned to form openings 1628 by removing the oxide layer in areas defined by the surrounding trenches 1624A, 1624B extending in the X-Y plane; the oxide layer 1626 is also patterned by removing the oxide layer in areas where the inter-module coupler devices are formed. The oxidation layer 1626 is patterned by performing at least some of the following processing steps: performing one or more patterning processes (e.g., a lithography process, a dry/wet etching process, a soft/hard baking process, a cleaning process, etc.); and using a dry/wet etching process.

At 1610, superconducting structures are formed on the substrate. In some instances, superconducting structures 1632 are formed on the surface of the substrate 1620 in at least a subset of the openings 1628. A superconducting structure 1632, which may include one or more contact pads with superconducting lines, is part of a respective inter-module coupler device (e.g., the inter-module coupler device 1406 as shown in FIG. 14) which are configured for enabling communication between quantum processor chips (e.g., quantum processor chips 1402) housed in the recesses (e.g., the recesses 1428) of the module integration plate (e.g., the module integration plate 1408) through respective cap wafers (e.g., the cap wafers 1404). In some instances, the superconducting structure 1632 may be formed on the surface of the substrate 1620 by performing at least some of the following processing steps: using chemical vapor deposition (CVD), physical vapor deposition (PVD), atomic layer deposition (ALD), spin-on coating, and/or other suitable techniques; and performing one or more patterning processes (e.g., a lithography process, a dry/wet etching process, a soft/hard baking process, a cleaning process, etc.).

In some implementations, the superconducting structure 1632 includes superconducting materials. In some instances, the superconducting materials may be superconducting metals, such as aluminum (Al), niobium (Nb), tantalum (Ta), vanadium (V), tungsten (W), indium (In), titanium (Ti), Lanthanum (La), lead (Pb), tin (Sn), and/or zirconium (Zr), that are superconducting at an operating temperature of the example quantum processing unit 200, or another superconducting metal. In some implementations, the superconducting materials may include superconducting metal alloys, such as molybdenum-rhenium (Mo/Re), niobium-tin (Nb/Sn), or another superconducting metal alloy. In some implementations, the superconducting materials may include superconducting compound materials, including superconducting metal nitrides and superconducting metal oxides, such as titanium-nitride (TiN), niobium-nitride (NbN), zirconium-nitride (ZrN), hafnium-nitride (HfN), vanadium-nitride (VN), tantalum-nitride (TaN), molybdenum-nitride (MoN), yttrium barium copper oxide (Y—Ba—Cu—O), or another superconducting compound material. In some instances, the superconducting materials may include multilayer superconductor-insulator heterostructures.

At 1612, recesses and through-hole vias are formed on the substrate. As shown in FIG. 16A, the silicon layer exposed by at least a subset of the openings 1628 on both of the surfaces of the substrate 1620 is removed by performing an etching process to form the recess 1636 and the through-hole via 1638. In some instances, the patterned oxide layer 1626 is compatible with the etching process; and the superconducting structure 1632 is protected, e.g., by a patterned photoresist layer, during the etching process. In other words, the etch rate of the silicon layer at the openings 1628 is great enough so that etch rates of the oxide layer and the superconducting material in the superconducting structure 1632 are negligible. In some instances, after the silicon layers are etched, portions of the buried oxide layer 122 exposed by the recess 1636 and the through-hole vias 1638 in the silicon layer are also removed after the silicon layer is removed, for example by performing an etching process. In other words, the through-hole vias 1638 connects the recessed surface of the recesses 1636 and one of the surfaces of the substrate 1620. In some implementations, the patterned oxidation layer 1626 is removed.

FIG. 16B is a flow chart showing aspects of an example process 1640 of manufacturing a module integration plate. In some implementations, the example process 1640 is used for fabricating a module integration plate (e.g., the module integration plates 1408, 1500, 1700 as shown in FIGS. 14, 15, and 17), which includes recesses, through-hole vias, cavities, and contacts of inter-module coupler devices. The example process 1640 may include additional or different operations, including operations to fabricate additional or different components, and the operations may be performed in the order shown or in another order. In some cases, operations in the example process 1640 can be combined, iterated or otherwise repeated, or performed in another manner. As shown in FIG. 16B, different structures can be produced according to different paths through the flow chart, and a path may include only a subset of the operations shown in FIG. 16B. Accordingly, an instance of the process 1640 does not generally include all operations shown in FIG. 16B.

In some implementations, operations 1642 and 1644 are performed with respect to operations 1602 and 1610; operations 1646 and 1648 are performed with respect to the operations 1604 and 1606; and operations 1650 and 1652 are performed with respect to the operations 1608 and 1612 in the example process 1600 as shown in FIG. 16A. In some instances, the operations 1642, 1644, 1646, 1648, 1650, and 1652 may be performed in another manner.

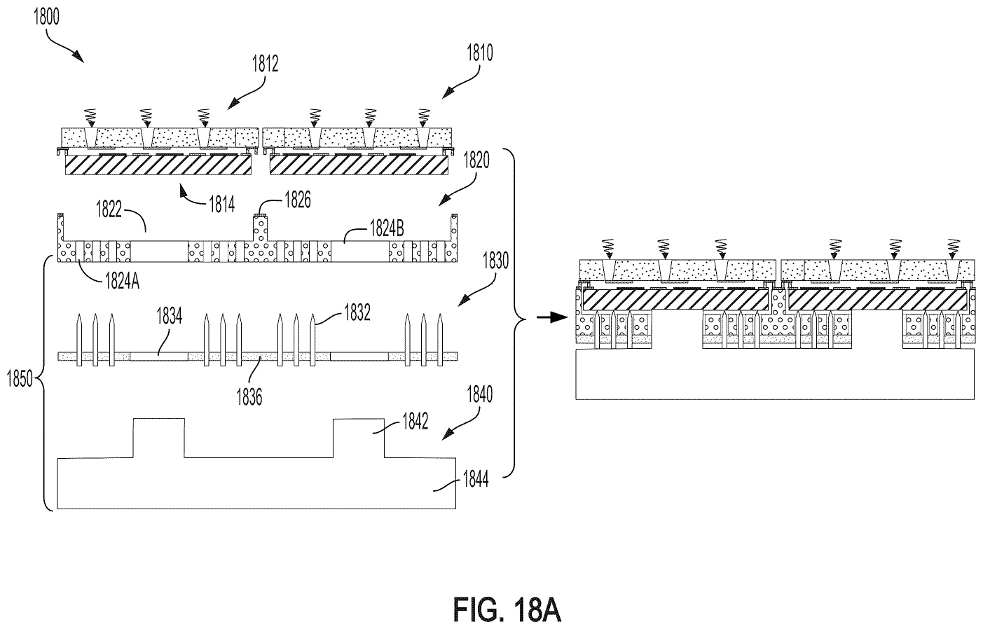

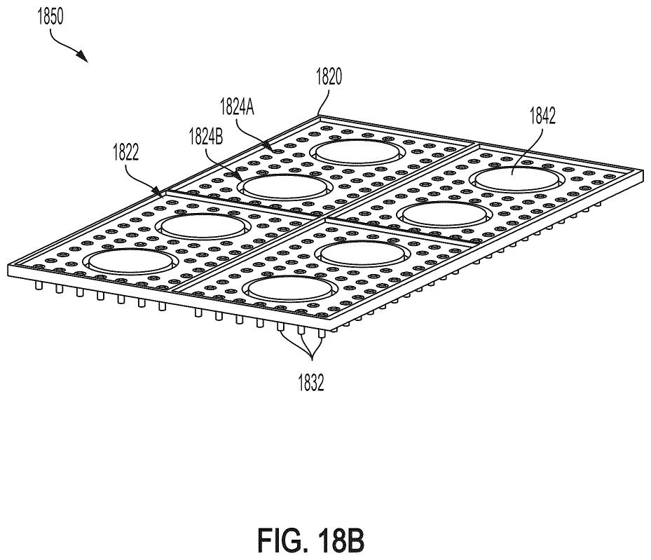

FIG. 17 shows perspective view and cross-section view (A-A′) of an example module integration plate 1700. In some implementations, the example module integration plate 1700 is fabricated in a substrate 1702 according to the operations in the example process 1600, 1640 in FIGS. 16A, 16B or in another manner. The module integration plate 1700 may be implemented as the module integration plate 1820 in the modular quantum processing unit 1800 in FIGS. 18A, 18B.

As shown in FIG. 17, the example module integration plate 1700 includes four recesses 1706, each of which is defined by sidewalls 1712 and a recessed surface 1714 which resides at a depth from a first surface 1704A of the substrate 1702. The example module integration plate 1700 further includes cavities 1708A and through-hole vias 1708B which connects the recessed surfaces 1714 at the four recesses 1706 to a second, opposite surface 1704B of the substrate 1702. Each of the recesses 1706 has a rectangular shape in the X-Y plane and the sidewalls 1712 are normal to the first surface 1704 and the recessed surface 1714; and each of the through-hole vias 1708B has a circular shape in the X-Y plane and respective sidewalls are normal to the second and recessed surfaces 1704B, 1714. In some instances, the recesses 1706, cavities 1708A, and through-hole vias 1708B may have different shapes in the X-Y plane and sidewalls may be non-perpendicular to the respective surfaces.

Each of the recesses 1706 is communicably connected with two cavities 1708A and an array of through-hole vias 1708B extending from the recessed surface 1714 to the second surface 1704B. In some instances, the cavities 1708A and the through-hole vias 1708B in the substrate 1702 may have different sizes. As shown in FIG. 17, the cavities 1708A have greater diameters in the X-Y plane than that of the through-hole vias 1708B. In some implementations, the cavities 1708A are configured to mate with a thermalization substrate (e.g., the thermalization substrate 1840 in FIG. 18A) so that when being assembled with a quantum processor chip, metal pillars (e.g., the metal pillars 1842 in FIG. 18A) of the thermalization structure are in mechanical contact with the quantum processor chip housed in the recess for dissipating heat generated. In some implementations, the through-hole vias 1708B are configured to mate with an interposer (e.g., the interposer 1830 in FIG. 18A), so that when being assembled with a quantum processor chip, spring-loaded pin contacts (e.g., the spring-loaded pin contacts 1832 in FIG. 18A) of the interposer are in electrical contact with the quantum processor chip (e.g., to ground).

As shown in FIG. 17, the module integration plate 1700 includes an inter-module coupler device 1710 on the first surface 1704A of the substrate 1702 at areas between two neighboring recesses 1706. The inter-module coupler device 1710 includes a superconducting structure which may be implemented as the superconducting structure 1632 as shown in FIGS. 16A, 16B or in another manner. The inter-module coupler device 1710, when being assembled with quantum processor modules in a modular quantum processing unit, forms electrical connections with the superconducting circuitry of the cap wafers and further to the respective quantum processor chips, which are housed by the recesses 1706 in the module integration plate 1700. In particular, each of the recesses 1706 of the module integration plate 1700 is configured to house two quantum processor chips which are capped by a common cap wafer in a quantum processor module. In some examples, each of the recesses 1706 may be configured to house more than two quantum processor chips. Each of the quantum processor chips housed in two distinct recesses 1706 are interconnected by respective inter-module coupler devices 1710 at the first surface 1704 between the two distinct recesses 1706. The inter-module coupler devices 1710 can provide electrical connections between quantum processor chips housed in distinct recesses 1706 of the module integration plate 1700. In some instances, the shape of the recesses 1706 may be designed and fabricated according to the shape of the quantum processor chip. For example, each of the recesses 1706 may be configured to house one rectangular quantum processor chip (e.g., the quantum processor chip 1906 in FIG. 19A. In some instances, the recesses 1706 may be arranged in a non-square array and have a different shape of lattice (e.g., the triangular lattice 1932 in FIG. 19B). In some instances, the recesses 1706 may be an irregular array or may be arranged in another manner in the module integration plate 1700.

As shown in FIG. 17, the module integration plate 1700 includes openings 1716 into the recesses 1706 defined at the first surface 1704. In some instances, after being assembled with the quantum processor modules, cap wafers of the quantum processor modules can be disposed over respective openings 1706 and over at least a portion of the first surface 1704 around the respective openings 1706; and quantum processor chips of the quantum processor modules are disposed at a depth between the first surface 1704 and the recessed surface 1714. In some implementations, a modular quantum processing unit includes multiple cap wafers and multiple cap wafers may disposed over respective openings 1716 of the respective recesses 1706. In some implementations, the module integration plate 1700 is fabricated on a silicon wafer, a PCB substrate, or another type of substrate. In some instances, each quantum processor module includes a cap wafer and two or more quantum processor chips. The cap wafer in a quantum processor module disposed over an opening 1716 is bonded to two or more quantum processor chips housed in the same recess. In this case, the cap wafer includes inter-chip coupler devices that provide communication between the two or more quantum processor chips bonded to the cap wafer. In some instances, the quantum processor module may be implemented as the quantum processor module 320, 910 in FIGS. 3 and 9B or in another manner.

FIG. 18A includes schematic diagrams of explode-view and assembled-view of an example modular quantum processing unit 1800. As shown in FIG. 18A, the modular quantum processing unit 1800 includes quantum processor modules 1810 which includes one or more quantum processor chips 1814 and one or more cap wafers 1812. Each of the quantum processor chips 1814 includes a superconducting integrated circuit with quantum circuit devices (e.g., qubit devices, coupler devices, readout devices, etc.). Each of the cap wafer 1812 includes superconducting circuitry with control lines and other circuit components. A cap wafer 1812 is mechanically bonded and electrically connected to at least one quantum processor chip 1814. The control lines are configured to communicate control signals between the quantum processor chips and a control system (e.g., the control system 105 in the quantum computing system 103 of FIG. 1). In some instances, the control lines include qubit drive lines, qubit flux bias lines, coupler flux bias lines, or other signal lines. The quantum processor module 1810 may be implemented as the quantum processor modules shown in FIGS. 2, 3A, 3B, 4B, 6A, 6B, 9A, 9B, 10A, 12, 13, or in another manner.

The superconducting circuitry of the cap wafer 1812 connects inter-module coupler devices 1826 through respective connections. In some implementations, the connections of each of the inter-module coupler devices 1826 include a conductive connection (e.g., a bonding bump), a capacitive connection (e.g., a pair of capacitive electrodes), or an inductive connection.

The modular quantum processing unit 1800 includes a module integration plate 1820 which includes recesses 1822, through-hole vias 1824A, cavities 1824B, and inter-module coupler devices 1826. The modular quantum processing unit 1800 may be implemented as the module integration plates 1408, 1500, 1700 shown in FIGS. 14, 15, 17 or in another manner. The module integration plate 1820 is configured to house the quantum processor chips 1814 in the recesses 1822, and to provide inter-chip coupling between the cap wafers 1812 and thus the respective quantum processor chips 1814 housed in distinct recesses 1822.

The modular quantum processing unit 1800 further includes an interposer 1830. As shown in FIG. 18A, the interposer 1830 includes a printed circuit board (PCB) substrate 1836. The PCB substrate 1836 includes through-holes 1834, when being assembled in the example modular quantum processing unit 1800, align with the cavities 1824B of the module integration plate 1820. The PCB substrate 1836 also includes the spring-loaded pin connections 1832, when being assembled in the example modular quantum processing unit 1800, are disposed in the respective through-hole vias 1824A of the module integration plate 1820. In some implementations, each of the quantum processor chips 1814 further includes superconducting circuitry on a second surface opposite to a first surface where the superconducting integrated circuit with quantum circuit devices resides. The superconducting circuitry on the second surface of the quantum processor chips 1814 are galvanically connected to the spring-loaded pin connections 1832 and further to ground. In some instances, the superconducting circuitry on the second surface is conductively connected to the superconducting integrated circuit on the first surface through conductive through-hole vias in the substrate of the quantum processor chips 1814.

The modular quantum processing unit 1800 further includes one or more thermalization substrate 1840. Each of the thermalization substrate 1840 includes heat sink materials such as aluminum, copper, and their alloys, which can provide favorable thermal and mechanical properties. For example, each thermalization substrate 1840 includes metal pillars 1842 on a metal base 1844. Each of the metal pillars 1842 of a thermalization substrate 1840, when being assembled in the example modular quantum processing unit 1800, is disposed in the cavities 1824B of the module integration plate 1820 and the through-holes 1834 of the interposer 1830 and is mechanically in contact with at least a subset of the quantum processor chips 1814 of the quantum processor modules 1810 housed in respective recesses 1822 of the module integration plate 1820. In some implementations, the thermalization substrate 1840 is a heat sink that dissipates the heat generated by each of the quantum processor chips 1814 to regulate the operating temperature of the quantum processor chips 1814.

In some instances, the metal base 1844 of the thermalization substrate 1840 may be used as the universal ground for the quantum processor modules 1810. As shown in FIG. 18A, the spring-loaded pin contacts 1832 are in electrical contact with the metal base 1844 of the thermalization substrate 1840. In some instances, the spring-loaded pin connections 1832 of the interposer 1830 are grounded in another manner.

In some instances, the module integration plate 1820, the interposer 1830 and the thermalization substrate 1840 may be assembled to form an assembly 1850 prior to integration with the quantum processor modules 1810. In some examples, the example modular quantum processing unit 1800 may be assembled in a different manner. In some implementations, the example modular quantum processing unit 1800 may include additional and different features or components and components of the example modular quantum processing unit 1800 may be implemented in another manner. For example, the example modular quantum processing unit 1800 may include multiple module integration plates 1820, which may be configured to house a subset of quantum processor models 1810. In some instances, the multiple substrates may be assembled with a common interposer 1830 and a common thermalization substrate 1840. In some instances, a subset of the multiple module integration plates 1820 is assembled with an interposer 1830 and a thermalization substrate 1840.

FIG. 18B is a schematic diagram showing a perspective view of the example assembly 1850 shown in FIG. 18A. The example assembly 1850, as part of the modular quantum processing unit 1800, includes the module integration plate 1820, the interposer 1830 and the thermalization substrate 1840. For clarity purposes, the PCB substrate for the interposer 1830 and the metal base of the thermalization substrate 1840 are not shown. In some implementations, the metal pillars 1842 of the thermalization substrate 1840 and the spring-loaded pin connections 1842 of the interposer 1830 are disposed through the respective cavities 1824B and the through-hole vias 1824A in the module integration plate 1820. The metal pillars 1842 and the spring-loaded pin connections 1832 terminate in the recesses 1822.

FIGS. 19A-19B includes top-view schematic diagrams showing layouts of quantum processor modules in example modular quantum processing units 1900, 1910, 1920, 1930. As shown in FIGS. 19A-19B, the example modular quantum processing unit 1900, 1910, 1920, 1930 includes an array of quantum processor chips and an array of cap wafers.

As shown in FIG. 19A, the example modular quantum processing unit 1900 includes multiple quantum processor modules with different shapes and sizes. In particular, the modular quantum processing unit 1900 includes two types of quantum processor modules, e.g., a first type including a quantum processor chip 1902 and a cap wafer 1904 each having a square shape; and a second type including a quantum processor chip 1906 and a cap wafer 1908 each having a rectangular shape. The example modular quantum processing unit 1910 includes two quantum processor modules. Each quantum processor module includes a cap wafer 1912 and a first set of quantum processor chips 1902 and a second set of quantum processor chips 1906. The first set of quantum processor chips 1902 have a square shape; and the second set of quantum processor chips 1906 have a rectangular shape.

As shown in FIG. 19B, the example modular quantum processing unit 1920 includes multiple quantum processor modules each including a quantum processor chip 1922 and a cap wafer 1924 with a hexagonal shape. The multiple quantum processor modules in the example modular quantum processing unit 1920 are arranged in a two-dimensional array with a square lattice 1926. The example modular quantum processing unit 1930 includes multiple quantum processor modules each including a quantum processor chip 1922 and a cap wafer 1924 with a hexagonal shape. The multiple quantum processor modules in the example modular quantum processing unit 1930 are arranged in a two-dimensional array with a triangular lattice 1932. In some instances, quantum processor chips and cap wafers of the quantum processor modules in the example quantum processing unit 1900, 1910, 1920, 1930 may have different shapes and sizes; and may be arranged in another manner.

In some implementations, each of the cap wafers 1904, 1912, 1924 may be implemented as the example cap wafer 212, 304, 324, 404, 500, 604, 634, 674, 718, 904, 1004; and each of the quantum processor chips 1902, 1906, 1922 may be implemented as the example device wafers 202, 302A, 302B, 302C, 322A, 322B, 322C, 322D, 402, 602, 632, 672, 730, 902, 1002 as shown in FIGS. 2, 3A-3B, 4A-4B, 5, 6A-6C, 7A-7C, 9A-9B or 10A-10C.

In some instances, the example modular quantum processing unit 1900, 1910, 1920, 1930 includes one or more module integration plates, one or more interposers, and a thermalization substrate. Components of the module integration plates (e.g., the openings of recesses, inter inter-module coupler devices, etc.), interposers (e.g., the openings), and the thermalization substrate (e.g., the metal pillars) in the example modular quantum processing unit 1900, 1910, 1920, 1930 are designed accordingly to accommodate the layouts of the quantum processor modules.

In a general aspect, a modular quantum processing unit (QPU) includes a module integration plate with recesses; and the module integration plate is configured for providing communication between quantum processor chips housed in distinct recesses.

In a first example, a quantum processing unit includes quantum processor chips, a module integration plate, and one or more caps. Each quantum processor chip includes a plurality of qubit devices. The quantum processor chips are disposed between the module integration plate and the one or more caps. The module integration plate includes recesses that house respective subsets of the quantum processor chips; and inter-module coupler devices that provide communication between the subsets of quantum processor chips housed in distinct recesses. The one or more cap wafers each includes signal lines that provide communication between at least one of the quantum processor chips and a control system.

Implementations of the first example may include one or more of the following features. The module integration plate is a silicon wafer. The module integration plate is a printed circuit board (PCB). Each of the one or more cap wafers includes control lines configured to communicate control signals between the quantum processor chips and the control system. Each of the inter-module coupler devices includes a conductive connection. Each of the inter-module coupler devices includes a capacitive connection. Each of the inter-module coupler devices includes an inductive connection.

Implementations of the first example may include one or more of the following features. The module integration plate includes a first surface and a second, opposite surface. The recesses each is defined by one or more sidewalls and a recessed surface. The recessed surface resides at a depth in the module integration plate relative to the first surface; and each of the inter-module coupler devices resides on the first surface. The depth is a first depth, and a portion of each quantum processor chip is disposed at a second depth between the recessed surface and the first surface. The quantum processing unit includes interposers in the respective recesses between the recessed surface of the recess and the subset of quantum processor chips housed in the recess. The module integration plate further includes through-hole vias extending from the recessed surface to the second surface. The plurality of qubit devices resides on first surfaces of the quantum processor chips. The quantum processor chips include superconducting circuitry residing on second, opposite surfaces.

Implementations of the first example may include one or more of the following features. The quantum processing unit includes an interposer with spring-loaded pin connections. The subsets of quantum processor chips, the module integration plate, and the interposer are arranged such that the spring-loaded pin connections of the interposer are disposed in the respective through-hole vias of the module integration plate galvanically connecting the superconducting circuitry of the subsets of quantum processor chips in the recesses of the module integration plate to ground. The module integration plate includes cavities, and subsets of the cavities reside in respective recesses and extend from the recessed surface to the second surface. The interposer includes through holes, and the quantum processing unit further includes a thermalization substrate comprising metal pillars. The quantum processor chips, the module integration plate, the interposer, and the thermalization substrate are arranged such that the metal pillars on the thermalization substrate are disposed through the respective through holes of the interposer and the respective cavities of the module integration plate, and mechanically in contact with the second surface of the subsets of quantum processor chips in the recesses.

Implementations of the first example may include one or more of the following features. The module integration plate is a first module integration plate comprising first recesses and first inter-module coupler devices. The quantum processor chips are first quantum processor chips. The one or more cap wafers are first cap wafers including first signal lines. The quantum processing unit includes second quantum processor chips disposed between a second module integration plate and one or more second caps. The second module integration plate includes second recesses that house respective subsets of the second quantum processor chips. The second module integration plate includes second inter-module coupler devices that provide communication between the subsets of the second quantum processor chips housed in distinct second recesses. The one or more second cap wafers each includes second signal lines that provide communication between at least one of the second quantum processor chips and the control system. Each of the inter-module coupler devices includes a first connection, the cap includes superconducting circuitry, the cap wafer and the quantum processor chip are communicably coupled through a second connection. The cap wafer, quantum processor chip and the module integration plate are arranged such that the qubit devices on the quantum processor chip are communicably connected to the module integration plate through the first and the second connection, and the superconducting circuitry.

Implementations of the first example may include one or more of the following features. The one or more cap wafers include a plurality of cap wafers, and each of the plurality of cap wafers is disposed over a respective one of the recesses. The module integration plate includes a first surface that defines openings into the respective recesses, and each of the plurality of cap wafers is disposed over: a respective one of the openings, and at least a portion of the first surface around the respective opening. Each of the plurality of cap wafers includes circuitry that contacts: a respective one of the inter-module coupler devices; and circuitry on a respective one of the quantum processor chips.

Implementations of the first example may include one or more of the following features. The openings into the respective recesses include a first subset having a first shape along the first surface and a second subset having a second, distinct shape along the first surface. The plurality of cap wafers includes a first subset that is disposed over the first subset of the openings and a second subset that is disposed over the second subset of the openings. The respective recesses with the first subset of the openings are configured to house a first subset of the quantum processor chips; and the respective recesses with the second subset of the openings are configured to house a second subset of the quantum processor chips. The first subset of the openings has a square shape; and the second subset of the openings has a rectangular shape. The openings defined on the first surface are arranged in one of the following: a square lattice, a rectangular lattice, and a triangular lattice. Each of the plurality of cap wafers includes inter-chip coupler devices that provide communication between two or more of the quantum processor chips disposed between the module integration plate and each of the plurality of cap wafers.

In a second example, a quantum information processing method includes processing quantum information by operation of the quantum processing unit of the first example. Processing quantum information includes coupling a first qubit device in a first quantum processor chip with a second qubit device in a second quantum processor chip through a first inter-module coupler device of the module integration plate. Coupling the first qubit device with the second qubit device includes applying a two-qubit quantum logic gate to a pair of qubits defined by the first and second qubit devices.

In a third example, a quantum processing unit includes quantum processor chips, a module integration plate, and one or more cap wafers. The quantum processor chips are disposed between a module integration plate and one or more cap wafers. Each quantum processor chip includes a plurality of qubit devices. The module integration plate includes inter-module coupler devices that provide communication between subsets of quantum processor chips. The one or more cap wafers each includes signal lines that provide communication between at least one of the quantum processor chips and a control system.

In a fourth example, a method of assembling a modular quantum processor unit includes providing quantum processor chips, each quantum processor chip including a plurality of qubit devices; providing a module integration plate, the module integration plate including recesses that house respective subsets of the quantum processor chips; and inter-module coupler devices that provide communication between the subsets of quantum processor chips housed in distinct recesses; providing one or more cap wafers each comprising signal lines that provide communication between at least one of the quantum processor chips and a control system; and disposing the quantum processor chips between the module integration plate and the one or more cap wafers.

Implementations of the fourth example may include one or more of the following features. The module integration plate includes a first surface and a second, opposite surface. The recesses each is defined by one or more sidewalls and a recessed surface. The recessed surface resides at a depth in the module integration plate relative to the first surface. Each of the inter-module coupler devices resides on the first surface. The module integration plate further includes through-hole vias extending from the recessed surface to the second surface. The quantum processor chips include superconducting circuitry residing on second, opposite surfaces. The method further includes providing interposers, each interposer comprising spring-loaded pin connections; and connecting the interposer to the quantum processing chips and the module integration plate such that the spring-loaded pin connections of the interposer are disposed in the respective through-hole vias of the module integration plate galvanically connecting the superconducting circuitry of the subsets of quantum processor chips in the recesses of the module integration plate to ground.

Implementations of the fourth example may include one or more of the following features. The module integration plate includes cavities. Subsets of the cavities reside in respective recesses and extend from the recessed surface to the second surface. The interposer includes through holes. The method further includes providing a thermalization substrate comprising metal pillars; and connecting the quantum processor chips, the module integration plate, the interposer, and the thermalization substrate such that the metal pillars on the thermalization substrate are disposed through the respective through holes of the interposer and the respective cavities of the module integration plate, and mechanically in contact with the second surface of the subsets of quantum processor chips in the recesses.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple implementations separately or in any suitable sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of embodiments have been described. Nevertheless, it will be understood that various modifications can be made. Accordingly, other embodiments are within the scope of the following claims.

What is claimed is:

1. A quantum processing unit comprising:
quantum processor chips disposed between a module integration plate and one or more cap wafers, each quantum processor chip comprising a plurality of qubit devices;
the module integration plate comprising:
recesses that house respective subsets of the quantum processor chips; and
inter-module coupler devices that provide communication between the subsets of quantum processor chips housed in distinct recesses; and
the one or more cap wafers each comprising signal lines that provide communication between at least one of the quantum processor chips and a control system.

2. The quantum processing unit of claim 1, wherein the module integration plate is a silicon wafer.

3. The quantum processing unit of claim 1, wherein the module integration plate is a printed circuit board (PCB).

4. The quantum processing unit of claim 1, wherein each of the one or more cap wafers comprises control lines configured to communicate control signals between the quantum processor chips and the control system.

5. The quantum processing unit of claim 1, wherein each of the inter-module coupler devices comprises a conductive connection.

6. The quantum processing unit of claim 1, wherein each of the inter-module coupler devices comprises a capacitive connection.

7. The quantum processing unit of claim 1, wherein each of the inter-module coupler devices comprises an inductive connection.

8. The quantum processing unit of claim 1, wherein the module integration plate comprises a first surface and a second, opposite surface, the recesses each being defined by one or more sidewalls and a recessed surface, the recessed surface residing at a depth in the module integration plate relative to the first surface, and each of the inter-module coupler devices resides on the first surface.

9. The quantum processing unit of claim 8, wherein the depth is a first depth, and a portion of each quantum processor chip is disposed at a second depth between the recessed surface and the first surface.

10. The quantum processor chip of claim 9, further comprising interposers in the respective recesses between the recessed surface of the recess and the subset of quantum processor chips housed in the recess.

11. The quantum processing unit of claim 8, wherein the module integration plate further comprises through-hole vias extending from the recessed surface to the second surface.

12. The quantum processing unit of claim 11, wherein the plurality of qubit devices reside on first surfaces of the quantum processor chips, the quantum processor chips comprises superconducting circuitry residing on second, opposite surfaces, and the quantum processing unit comprises:
an interposer comprising spring-loaded pin connections, the subsets of quantum processor chips, the module integration plate, and the interposer being arranged such that the spring-loaded pin connections of the interposer are disposed in the respective through-hole vias of the module integration plate galvanically connecting the superconducting circuitry of the subsets of quantum processor chips in the recesses of the module integration plate to ground.

13. The quantum processing unit of claim 12, wherein the module integration plate comprises cavities, wherein subsets of the cavities reside in respective recesses and extend from the recessed surface to the second surface, the interposer comprises through holes, and the quantum processing unit further comprises:
a thermalization substrate comprising metal pillars, the quantum processor chips, the module integration plate, the interposer, and the thermalization substrate being arranged such that the metal pillars on the thermalization substrate are disposed through the respective through holes of the interposer and the respective cavities of the module integration plate, and mechanically in contact with the second surface of the subsets of quantum processor chips in the recesses.

14. The quantum processing unit of claim 1, wherein the module integration plate is a first module integration plate comprising first recesses and first inter-module coupler devices, the quantum processor chips are first quantum processor chips, the one or more cap wafers are first cap wafers comprising first signal lines, and the quantum processing unit comprises:
second quantum processor chips disposed between a second module integration plate and one or more second cap wafers;
the second module integration plate comprising:
second recesses that house respective subsets of the second quantum processor chips; and
second inter-module coupler devices that provide communication between the subsets of the second quantum processor chips housed in distinct second recesses; and
the one or more second cap wafers each comprising second signal lines that provide communication between at least one of the second quantum processor chips and the control system.

15. The quantum processing unit of claim 1, wherein:
each of the inter-module coupler devices comprises a first connection,
the cap wafer comprises superconducting circuitry,
the cap wafer and the quantum processor chip are communicably coupled through a second connection, and
the cap wafer, quantum processor chip and the module integration plate are arranged such that the qubit devices on the quantum processor chip are communicably connected to the module integration plate through the first and the second connections, and the superconducting circuitry.

16. The quantum processing unit of claim 1, wherein the one or more cap wafers comprises a plurality of cap wafers, and each of the plurality of cap wafers is disposed over a respective one of the recesses.

17. The quantum processing unit of claim 16, wherein the module integration plate comprises a first surface that defines openings into the respective recesses, and each of the plurality of cap wafers is disposed over:
a respective one of the openings, and
at least a portion of the first surface around the respective opening.

18. The quantum processing unit of claim 17, wherein each of the plurality of cap wafers comprises circuitry that contacts:
a respective one of the inter-module coupler devices; and
circuitry on a respective one of the quantum processor chips.

19. The quantum processing unit of claim 17, wherein the openings into the respective recesses comprise a first subset having a first shape along the first surface and a second subset having a second, distinct shape along the first surface, the plurality of cap wafers comprises a first subset that is disposed over the first subset of the openings and a second subset that is disposed over the second subset of the openings, and the respective recesses with the first subset of the openings are configured to house a first subset of the quantum processor chips and the respective recesses with the second subset of the openings are configured to house a second subset of the quantum processor chips.

20. The quantum processing unit of claim 19, wherein the first subset of the openings has a square shape, and the second subset of the openings has a rectangular shape.

21. The quantum processing unit of claim 17, wherein the openings defined on the first surface are arranged in one of the following:
a square lattice,
a rectangular lattice, and
a triangular lattice.

22. The quantum processing unit of claim 17, wherein each of the plurality of cap wafers comprises inter-chip coupler devices that provide communication between two or more of the quantum processor chips disposed between the module integration plate and each of the plurality of cap wafers.

23. A quantum information processing method comprising:
processing quantum information by operation of the quantum processing unit of any one of the previous claims.

24. The quantum information processing method of claim 23, wherein processing quantum information comprises coupling a first qubit device in a first quantum processor chip with a second qubit device in a second quantum processor chip through a first inter-module coupler device of the module integration plate.

25. The quantum information processing method of claim 24, wherein coupling the first qubit device with the second qubit device comprises applying a two-qubit quantum logic gate to a pair of qubits defined by the first and second qubit devices.

26. A quantum processing unit comprising:
quantum processor chips disposed between a module integration plate and one or more cap wafers, each quantum processor chip comprising a plurality of qubit devices;
the module integration plate comprising inter-module coupler devices that provide communication between subsets of quantum processor chips; and
the one or more cap wafers each comprising signal lines that provide communication between at least one of the quantum processor chips and a control system.

27. A method of assembling a modular quantum processor unit, comprising:
providing quantum processor chips, each quantum processor chip comprising a plurality of qubit devices;
providing a module integration plate, the module integration plate comprising:
recesses that house respective subsets of the quantum processor chips; and
inter-module coupler devices that provide communication between the subsets of quantum processor chips housed in distinct recesses;
providing one or more cap wafers each comprising signal lines that provide communication between at least one of the quantum processor chips and a control system; and
disposing the quantum processor chips between the module integration plate and the one or more cap wafers.

28. The method of claim 27, wherein the module integration plate comprises a first surface and a second, opposite surface, the recesses each being defined by one or more sidewalls and a recessed surface, the recessed surface residing at a depth in the module integration plate relative to the first surface, each of the inter-module coupler devices resides on the first surface, the module integration plate further comprises through-hole vias extending from the recessed surface to the second surface, the quantum processor chips comprise superconducting circuitry residing on second, opposite surfaces, and the method comprises:
providing interposers, each interposer comprising spring-loaded pin connections; and
connecting the interposer to the quantum processing chips and the module integration plate such that the spring-loaded pin connections of the interposer are disposed in the respective through-hole vias of the module integration plate galvanically connecting the superconducting circuitry of the subsets of quantum processor chips in the recesses of the module integration plate to ground.

29. The method of claim 28, wherein the module integration plate comprises cavities, wherein subsets of the cavities reside in respective recesses and extend from the recessed surface to the second surface, the interposer comprises through holes, and the method comprises:
providing a thermalization substrate comprising metal pillars; and
connecting the quantum processor chips, the module integration plate, the interposer, and the thermalization substrate such that the metal pillars on the thermalization substrate are disposed through the respective through holes of the interposer and the respective cavities of the module integration plate, and mechanically in contact with the second surface of the subsets of quantum processor chips in the recesses.
